(19) United States
(12) Patent Application Publication
(10) Pub. No.: US 2026/0011984 A1
(43) Pub. Date: Jan. 8, 2026

(54) SEMICONDUCTOR LIGHT-EMITTING DEVICE

(71) Applicant: ROHM CO., LTD., Kyoto (JP)

(72) Inventors: Satohiro KIGOSHI, Kyoto-shi (JP); Yusuke NAKAKOHARA, Kyoto-shi (JP)

(73) Assignee: ROHM CO., LTD., Kyoto (JP)

(21) Appl. No.: 19/326,451

(22) Filed: Sep. 11, 2025

Related U.S. Application Data
(63) Continuation of application No. PCT/JP2024/009702, filed on Mar. 13, 2024.

(30) Foreign Application Priority Data
Mar. 20, 2023 (JP) 2023-044153

(51) Int. Cl. H01S 5/40; H01S 5/02345; H01S 5/042

(52) U.S. Cl. CPC H01S 5/4031; H01S 5/02345; H01S 5/04256

(57) ABSTRACT

A semiconductor light emitting device includes an edge-emitting element including emitters, a first front-surface electrode, a second front-surface electrode, first wires, and second wires. The emitters include a first emitter including a first element electrode, and a second emitter including a second element electrode. The first front-surface electrode is electrically connected to the first element electrode. The second front-surface electrode is electrically connected to the second element electrode. The first wires are electrically connecting the first element electrode to the first front-surface electrode. The second wires are electrically connecting the second element electrode to the second front-surface electrode. In plan view, a largest distance between adjacent ones of the second wires in the first direction is greater than a largest distance between adjacent ones of the first wires in the first direction.

### CROSS-REFERENCE TO RELATED APPLICATIONS

This application is a continuation of, and claims the benefit of priority from International Application No. PCT/JP2024/009702, filed on Mar. 13, 2024, which claims the benefit of priority from Japanese Patent Application No. 2023-044153, filed on Mar. 20, 2023, the entire contents of each are incorporated herein by reference.

### BACKGROUND

### 1. Field

The following description relates to a semiconductor light emitting device.

### 2. Description of Related Art

A typical semiconductor light emitting device uses an edge-emitting semiconductor laser as a light source (e.g., refer to JP2008-141039A).

### BRIEF DESCRIPTION OF DRAWINGS

FIG. 1 is a perspective view of a semiconductor light emitting device in accordance with a first embodiment.

FIG. 2 is a schematic plan view of the internal structure of the semiconductor light emitting device shown in FIG. 1.

FIG. 3 is a bottom view of the semiconductor light emitting device shown in FIG. 1.

FIG. 4 is a schematic cross-sectional view of the cross-sectional structure of the semiconductor light emitting device taken along line F4-F4 shown in FIG. 2.

FIG. 5 is a schematic cross-sectional view of the cross-sectional structure of the semiconductor light emitting device taken along line F5-F5 shown in FIG. 2.

FIG. 6 is a schematic cross-sectional view of the semiconductor light emitting device shown in FIG. 1.

FIG. 7 is an enlarged view of some of front-surface electrodes in a state in which wires are omitted from the semiconductor light emitting device shown in FIG. 2.

FIG. 8 is an enlarged view of some of the front-surface electrodes on the semiconductor light emitting device shown in FIG. 2.

FIG. 9 is a schematic plan view of the internal structure of a semiconductor light emitting device of a comparative example.

FIG. 10 is a schematic plan view of the internal structure of a semiconductor light emitting device in accordance with a second embodiment.

FIG. 11 is a schematic plan view of the internal structure of a semiconductor light emitting device in accordance with a third embodiment.

FIG. 12 is an enlarged view of some of front-surface electrodes on the semiconductor light emitting device shown in FIG. 11.

FIG. 13 is an enlarged plan view of some of front-surface electrodes on a semiconductor light emitting device of a modified example.

FIG. 14 is an enlarged plan view of some of front-surface electrodes on a semiconductor light emitting device of a modified example.

FIG. 15 is an enlarged plan view of some of front-surface electrodes on a semiconductor light emitting device of a modified example.

FIG. 16 is a schematic plan view of the internal structure of a semiconductor light emitting device of a modified example.

FIG. 17 is a schematic plan view of the internal structure of a semiconductor light emitting device of a modified example.

FIG. 18 is a schematic plan view of the internal structure of a semiconductor light emitting device of a modified example.

FIG. 19 is a schematic plan view of the internal structure of a semiconductor light emitting device of a modified example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

Embodiments of a semiconductor light emitting device according to the present disclosure will now be described with reference to the drawings. Elements in the drawings are illustrated for simplicity and clarity and have not necessarily been drawn to scale. To facilitate understanding, hatching lines may not be shown in the cross-sectional drawings. The accompanying drawings merely illustrate exemplary embodiments of the present disclosure and are not intended to limit the present disclosure.

This detailed description provides exemplary embodiments of methods, apparatuses, and/or systems in accordance with the present disclosure. Further, this detailed description is illustrative and is not intended to limit embodiments of the present disclosure or the application and use of the embodiments.

### First Embodiment

### Overall Configuration of Semiconductor Light Emitting Device

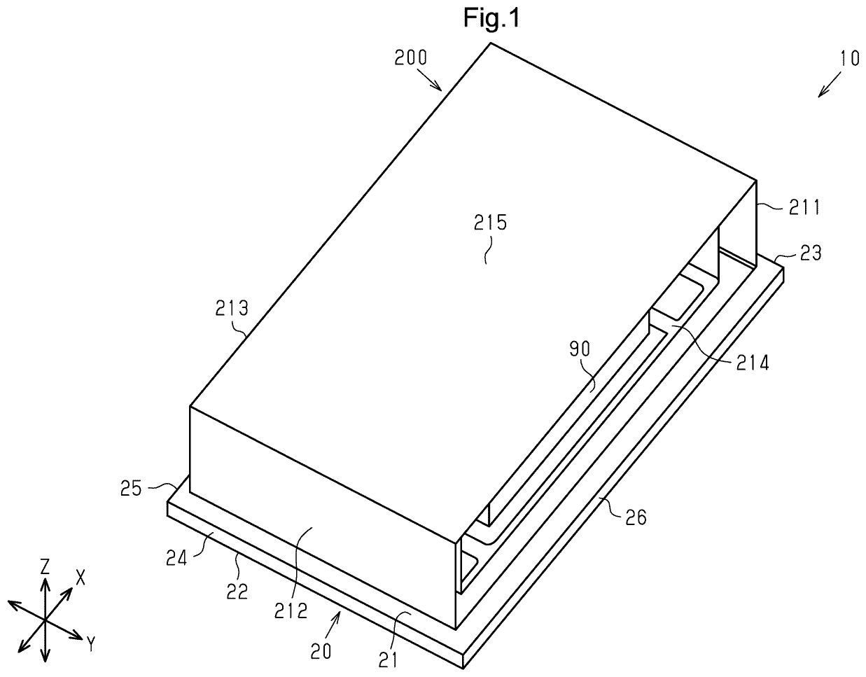

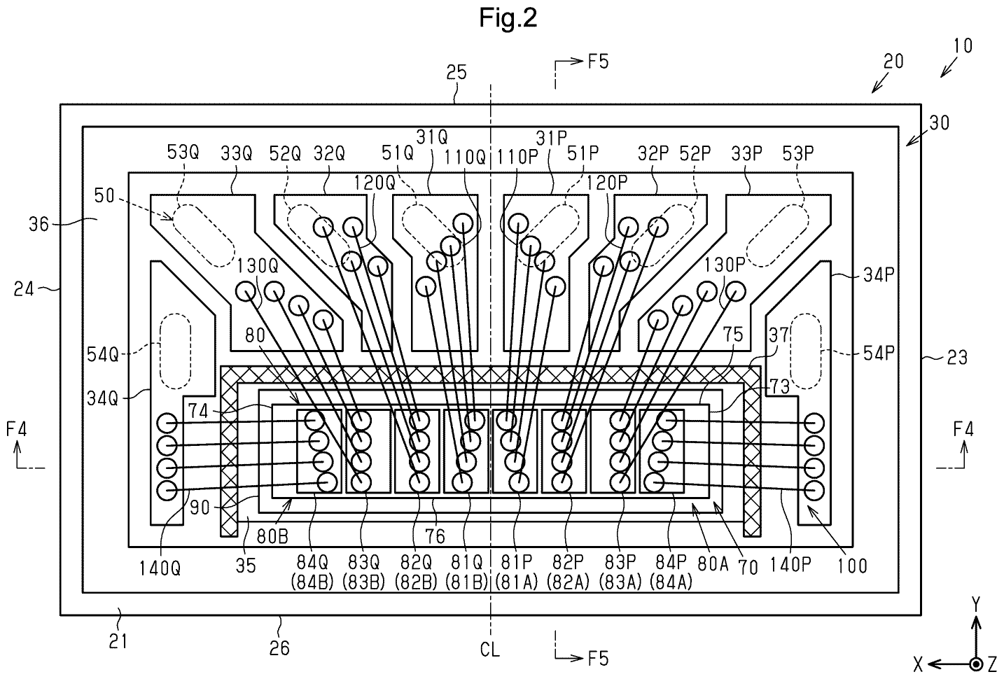

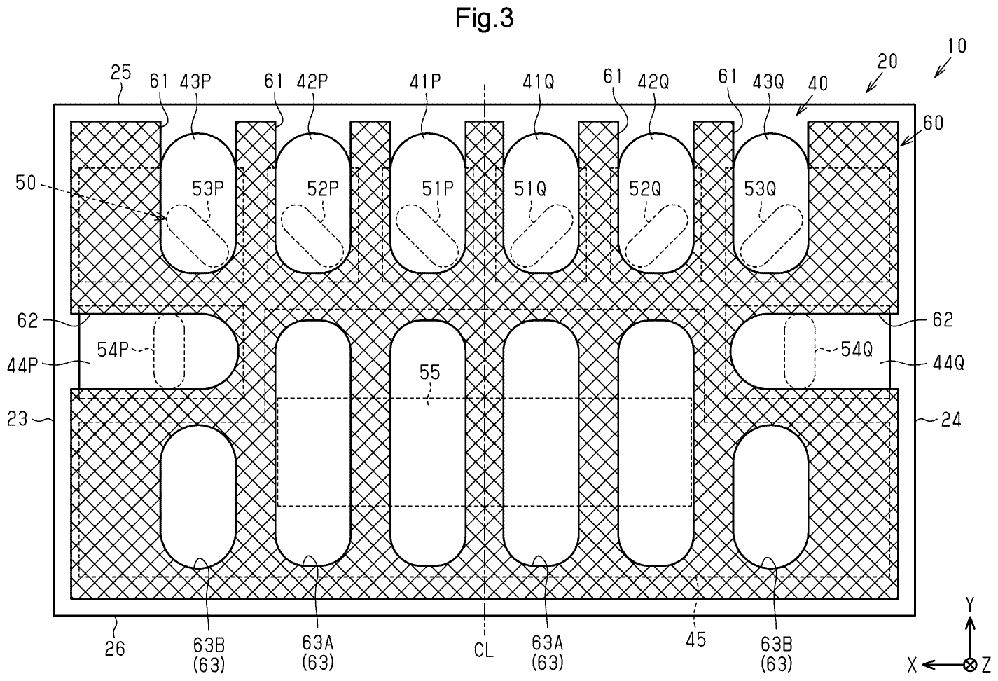

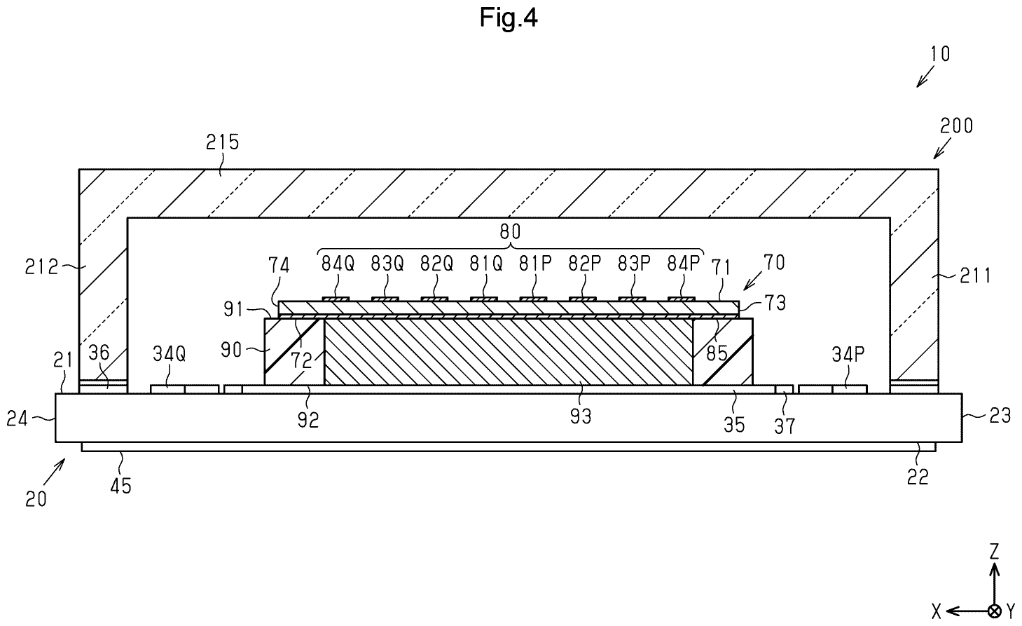

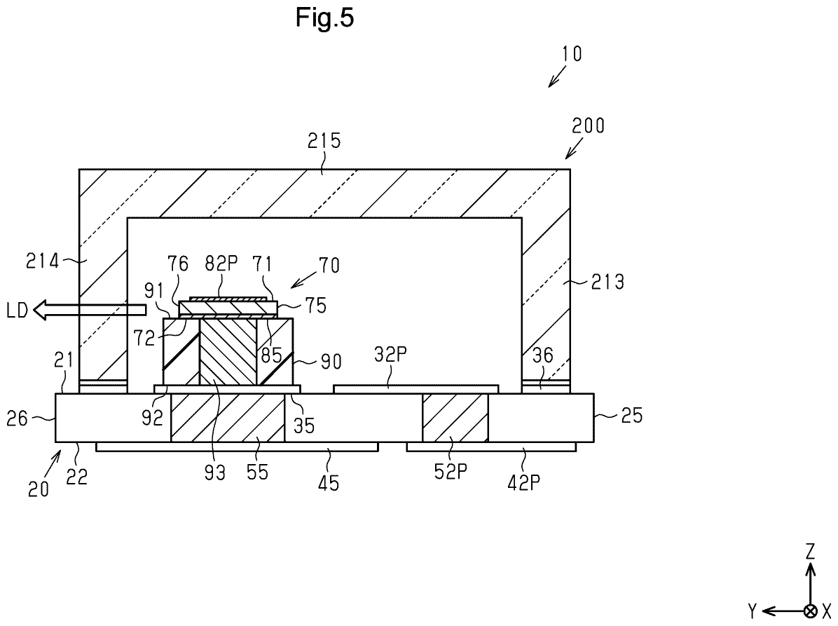

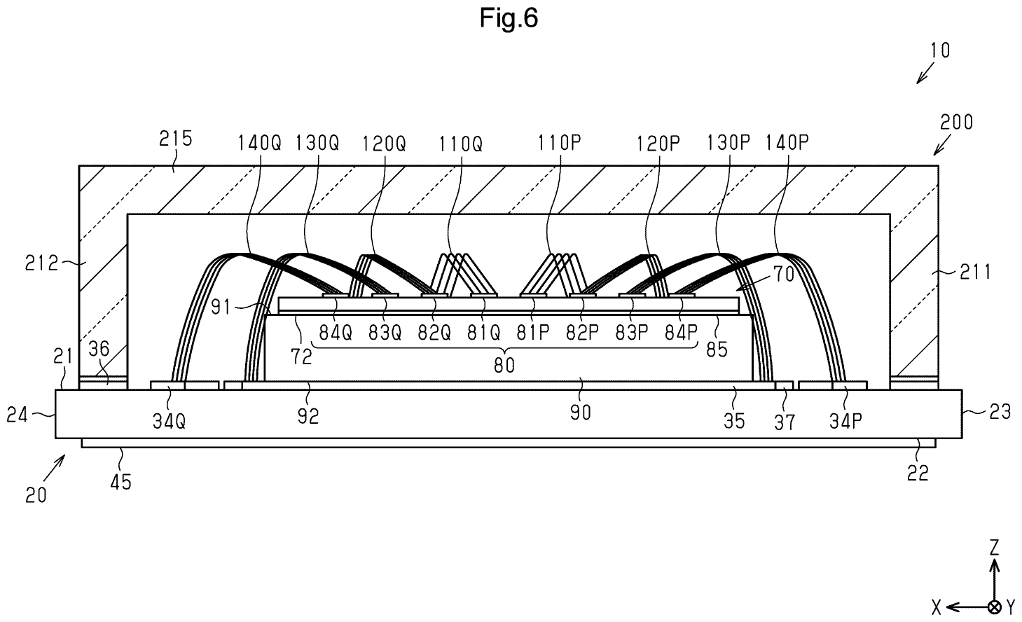

The overall configuration of a semiconductor light emitting device 10 in accordance with a first embodiment will now be described with reference to FIGS. 1 to 6. FIG. 1 is a perspective view of the semiconductor light emitting device 10. FIG. 2 is a plan view showing the internal structure of the semiconductor light emitting device 10. FIG. 3 is a bottom view of the semiconductor light emitting device 10. FIG. 4 is a cross-sectional view of the semiconductor light emitting device 10 taken along line F4-F4 shown in FIG. 2. FIG. 5 is a cross-sectional view of the semiconductor light emitting device 10 taken along line F5-F5 shown in FIG. 2. FIG. 6 is a cross-sectional view of the semiconductor light emitting device 10 as viewed from the side of a light emitting surface. To facilitate understanding of the drawings, wires 100, which will be described later, are not shown in FIGS. 4 and 5.

As shown in FIG. 1, the semiconductor light emitting device 10 includes a substrate 20, an edge-emitting element 70 (refer to FIG. 2), and a case 200. The substrate 20 has a shape of a rectangular plate. The edge-emitting element 70 is arranged on the substrate 20. The case 200 is arranged on the substrate 20 and accommodates the edge-emitting element 70. The thickness-wise direction of the substrate 20 will be referred to as “Z-direction”. Two orthogonal directions that are also orthogonal to the Z-direction will be referred to as “X-direction” and “Y-direction”, respectively. In this specification, “plan view” refers to a view of the semiconductor light emitting device 10 as viewed in the thickness-wise direction of the substrate 20 (Z-direction). In the first embodiment, the substrate 20 is rectangular in plan view, with long sides extending in the X-direction and short sides extending in the Y-direction.

The substrate 20 includes a substrate front surface 21, a substrate back surface 22, and first to fourth substrate side surfaces 23 to 26. The substrate front surface 21 and the substrate back surface 22 face away from each other with respect to the Z-direction. The first to fourth substrate side surfaces 23 to 26 intersect the substrate front surface 21 and the substrate back surface 22. In the first embodiment, the substrate front surface 21 and the substrate back surface 22 are both flat and orthogonal to the Z-direction. In an example, the first to fourth substrate side surfaces 23 to 26 are each flat and orthogonal to the substrate front surface 21 and the substrate back surface 22. The first substrate side surface 23 and the second substrate side surface 24 are two opposite end surfaces of the substrate 20 in the X-direction. The third substrate side surface 25 and the fourth substrate side surface 26 are two opposite end surfaces of the substrate 20 in the Y-direction.

The substrate 20 is formed from, for example, a glass epoxy resin. The substrate 20 may be formed from a material containing ceramic. Examples of a material containing ceramic may include aluminum nitride (AlN), alumina (Al₂O₃), and the like. When the substrate 20 is formed from the material containing ceramic, the substrate 20 has improved heat dissipation performance so that the temperature of the edge-emitting element 70 will not become excessively high.

As shown in FIG. 2, the edge-emitting element 70 serves as a light source of the semiconductor light emitting device 10. The edge-emitting element 70 may be, for example, a laser diode that emits light within a predetermined wavelength band. The edge-emitting element 70 includes an edge-emitting laser element. The edge-emitting element 70 may be an edge-emitting laser element having any configuration. In the first embodiment, the edge-emitting element 70 includes a Fabry-Perot laser diode element. As indicated by the hollow arrow LD shown in FIG. 5, the edge-emitting element 70 is configured to emit light toward the fourth substrate side surface 26 in plan view.

As shown in FIG. 1, the case 200 is box-shaped and includes an opening that is open toward the substrate 20 in the Z-direction. The case 200 includes first to fourth side walls 211 to 214 and an upper wall 215. In plan view, the first to fourth side walls 211 to 214 form a rectangular frame. The upper wall 215 closes an open end formed by the first to fourth side walls 211 to 214 in the Z-direction. In an example, the upper wall 215 is formed integrally with the first to fourth side walls 211 to 214. The first side wall 211 and the second side wall 212 are two opposite side walls of the case 200 in the X-direction. The third side wall 213 and the fourth side wall 214 are two opposite side walls of the case 200 in the Y-direction. The first side wall 211 is one of the two opposite side walls of the case 200 in the X-direction located closer to the first substrate side surface 23 of the substrate 20. The second side wall 212 is the other one of the two opposite side walls of the case 200 located closer to the second substrate side surface 24 of the substrate 20. The third side wall 213 is one of the two opposite side walls of the case 200 in the Y-direction located closer to the third substrate side surface 25 of the substrate 20. The fourth side wall 214 is the other one of the two opposite side walls of the case 200 located closer to the fourth substrate side surface 26 of the substrate 20. In an example, the first to third side walls 211 to 213 and the upper wall 215 are translucent, and the fourth side wall 214 is transparent. The fourth side wall 214 is the side surface of the case 200 located at a position corresponding to an emission direction of the edge-emitting element 70. The case 200 may be transparent at least at a part corresponding to the emission direction of the edge-emitting element 70. Therefore, at least one of the first to third side walls 211 to 213 and the upper wall 215 may be transparent in the same manner as the fourth side wall 214.

The case 200 is formed from, for example, a glass material. Instead of the glass material, the case 200 may be formed from a resin material that is translucent or transparent. Examples of such a resin material may include an acrylic resin and an epoxy resin.

As shown in FIG. 2, the semiconductor light emitting device 10 includes a plurality of (in the first embodiment, ten) front-surface electrodes 30 formed on the substrate front surface 21 of the substrate 20. The front-surface electrodes 30 are spaced apart from each other. The front-surface electrodes 30 are formed from, for example, a copper foil. The material of the front-surface electrodes 30 is not limited to copper (Cu), and may contain at least one of aluminum (Al), nickel (Ni), palladium (Pd), silver (Ag), and gold (Au).

The front-surface electrodes 30 include first inner front-surface electrodes 31P and 31Q, second inner front-surface electrodes 32P and 32Q, outer front-surface electrodes 33P and 33Q, and end front-surface electrodes 34P and 34Q. The first inner front-surface electrodes 31P and 31Q, the second inner front-surface electrodes 32P and 32Q, the outer front-surface electrodes 33P and 33Q, and the end front-surface electrodes 34P and 34Q are electrically connected to the edge-emitting element 70.

The first inner front-surface electrode 31P, the second inner front-surface electrode 32P, the outer front-surface electrode 33P, and the end front-surface electrode 34P are formed in a region of the substrate front surface 21 located closer to the first substrate side surface 23 than an imaginary center line CL (double-dashed line) is. The imaginary center line CL is parallel to the Y-direction and extends through the center of the substrate 20 with respect to the X-direction. The first inner front-surface electrode 31Q, the second inner front-surface electrode 32Q, the outer front-surface electrode 33Q, and the end front-surface electrode 34Q are formed in a region of the substrate front surface 21 located closer to the second substrate side surface 24 than the imaginary center line CL is. In plan view, the first inner front-surface electrode 31P, the second inner front-surface electrode 32P, the outer front-surface electrode 33P, and the end front-surface electrode 34P are symmetric to the first inner front-surface electrode 31Q, the second inner front-surface electrode 32Q, the outer front-surface electrode 33Q, and the end front-surface electrode 34Q with respect to the imaginary center line CL.

The first inner front-surface electrode 31P, the second inner front-surface electrode 32P, and the outer front-surface electrode 33P are spaced apart from each other in the X-direction in a state aligned in the same position in the Y-direction. The first inner front-surface electrode 31P is located closer to the imaginary center line CL (center of substrate front surface 21 in X-direction) than the second inner front-surface electrode 32P and the outer front-surface electrode 33P are. The outer front-surface electrode 33P is located closer to the first substrate side surface 23 than the first inner front-surface electrode 31P and the second inner front-surface electrode 32P are. In other words, the outer front-surface electrode 33P is located closer to an end of the substrate front surface 21 than the first inner front-surface electrode 31P and the second inner front-surface electrode 32P are.

In plan view, the end front-surface electrode 34P is located closer to the first substrate side surface 23 than the edge-emitting element 70 is. The end front-surface electrode 34P is separated from the first inner front-surface electrode 31P, the second inner front-surface electrode 32P, and the outer front-surface electrode 33P toward the fourth substrate side surface 26. As viewed in the X-direction, the end front-surface electrode 34P includes a portion that overlaps the outer front-surface electrode 33P, and a portion that extends beyond the outer front-surface electrode 33P toward the fourth substrate side surface 26.

The first inner front-surface electrode 31Q, the second inner front-surface electrode 32Q, and the outer front-surface electrode 33Q are spaced apart from each other in the X-direction in a state aligned in the same position in the Y-direction. The first inner front-surface electrode 31Q is located closer to the imaginary center line CL (center of substrate front surface 21 in X-direction) than the second inner front-surface electrode 32Q and the outer front-surface electrode 33Q are. The outer front-surface electrode 33Q is located closer to the second substrate side surface 24 than the first inner front-surface electrode 31Q and the second inner front-surface electrode 32Q are. The first inner front-surface electrodes 31P and 31Q are adjacent to each other at opposite sides of the imaginary center line CL.

In plan view, the end front-surface electrode 34Q is located closer to the second substrate side surface 24 than the edge-emitting element 70 is. The end front-surface electrode 34Q is separated from the first inner front-surface electrode 31Q, the second inner front-surface electrode 32Q, and the outer front-surface electrode 33Q toward the fourth substrate side surface 26. As viewed in the X-direction, the end front-surface electrode 34Q includes a portion that overlaps the outer front-surface electrode 33Q, and a portion that extends beyond the outer front-surface electrode 33Q toward the fourth substrate side surface 26.

As described above, in the direction in which the first inner front-surface electrodes 31P and 31Q, the second inner front-surface electrodes 32P and 32Q, and the outer front-surface electrodes 33P and 33Q are arranged (X-direction), “inner” means “toward the imaginary center line CL (center of substrate front surface 21 in X-direction)”, and “outer” means “toward the first substrate side surface 23 or the second substrate side surface 24”.

The shapes of the first inner front-surface electrodes 31P and 31Q, the second inner front-surface electrodes 32P and 32Q, the outer front-surface electrodes 33P and 33Q, and the end front-surface electrodes 34P and 34Q will be described in detail later.

The front-surface electrodes 30 include a mounting pattern 35 and an adhering pattern 36 that are formed on the substrate front surface 21 of the substrate 20.

The mounting pattern 35 is arranged on the substrate front surface 21 at a position closer to the fourth substrate side surface 26 than the first inner front-surface electrodes 31P and 31Q, the second inner front-surface electrodes 32P and 32Q, and the outer front-surface electrodes 33P and 33Q are. The mounting pattern 35 is arranged on the substrate front surface 21 at a position between the end front-surface electrodes 34P and 34Q in the X-direction. The mounting pattern 35 is rectangular in plan view, with long sides extending in the X-direction and short sides extending in the Y-direction. As viewed in the Y-direction, the mounting pattern 35 extends in the X-direction and overlaps the first inner front-surface electrodes 31P and 31Q, the second inner front-surface electrodes 32P and 32Q, and the outer front-surface electrodes 33P and 33Q.

The adhering pattern 36 is frame-shaped and surrounds the first inner front-surface electrodes 31P and 31Q, the second inner front-surface electrodes 32P and 32Q, the outer front-surface electrodes 33P and 33Q, the end front-surface electrodes 34P and 34Q, and the mounting pattern 35. In the first embodiment, the adhering pattern 36 has a shape of a rectangular frame, with long sides extending in the X-direction and short sides extending in the Y-direction. An adhesive for the case 200 is applied to the adhering pattern 36. The adhering pattern 36 is not electrically connected to the edge-emitting element 70. Hence, the adhering pattern 36 is electrically floating. The adhering pattern 36 may be formed from a material differing from that of the other front-surface electrodes 30. In an example, the adhering pattern 36 may be formed from an insulative material. That is, the front-surface electrodes 30 do not include the adhering pattern 36. In other words, the semiconductor light emitting device 10 includes the front-surface electrodes 30 and the adhering pattern 36. In this case, the adhering pattern 36 surrounds the front-surface electrodes 30 in plan view.

The substrate front surface 21 includes a front-surface resist 37. In plan view, the front-surface resist 37 is U-shaped and extends along two opposite sides of the mounting pattern 35 in the X-direction and a side of the mounting pattern 35 located toward the third substrate side surface 25 in the Y-direction. The front-surface resist 37 is formed between the mounting pattern 35 and the first inner front-surface electrodes 31P and 31Q, the second inner front-surface electrodes 32P and 32Q, the outer front-surface electrodes 33P and 33Q, and the end front-surface electrodes 34P and 34Q. The front-surface resist 37 is in contact with the side surfaces of the mounting pattern 35. The front-surface resist 37 is separated from the first inner front-surface electrodes 31P and 31Q, the second inner front-surface electrodes 32P and 32Q, the outer front-surface electrodes 33P and 33Q, and the end front-surface electrodes 34P and 34Q. The front-surface resist 37 is a solder resist and is formed from, for example, an insulative material. The insulative material may be, for example, an epoxy resin.

The semiconductor light emitting device 10 includes a sub-mount substrate 90 that supports the edge-emitting element 70. The sub-mount substrate 90 is mounted on the mounting pattern 35. In an example, the sub-mount substrate 90 is die-bonded onto the mounting pattern 35. The mounting pattern 35 may be integrated with the sub-mount substrate 90.

Due to the front-surface resist 37, a die-bonding material (not shown) for die-bonding the sub-mount substrate 90 to the mounting pattern 35 is likely to remain on the mounting pattern 35. This avoids electrical connection through a conductive bonding material between the mounting pattern 35 and the first inner front-surface electrodes 31P and 31Q, the second inner front-surface electrodes 32P and 32Q, the outer front-surface electrodes 33P and 33Q, and the end front-surface electrodes 34P and 34Q. Examples of the die-bonding material may include solder paste, silver paste, gold paste, and copper paste.

The sub-mount substrate 90 has a shape of a rectangular plate. In the first embodiment, the sub-mount substrate 90 is rectangular in plan view, with long sides extending in the X-direction and short sides extending in the Y-direction. In an example, the sub-mount substrate 90 is slightly smaller than the mounting pattern 35 in plan view.

The sub-mount substrate 90 is formed from a material containing, for example, silicon (Si). The sub-mount substrate 90 may be formed from a material containing ceramic. Examples of the material containing ceramic may include AlN, Al₂O₃, and the like. Alternatively, the sub-mount substrate 90 may be formed from a material containing Cu. When the sub-mount substrate 90 is formed from the material containing ceramic or the material containing Cu, the sub-mount substrate 90 has improved heat dissipation performance so that the sub-mount substrate 90 readily transfers the heat of the edge-emitting element 70 to the substrate 20. Thus, the temperature of the edge-emitting element 70 will not become excessively high.

As shown in FIGS. 4 and 5, the sub-mount substrate 90 is thicker than the substrate 20. The thickness of the sub-mount substrate 90 may be changed. For example, the thickness of the sub-mount substrate 90 may be less than or equal to the thickness of the substrate 20.

The sub-mount substrate 90 includes a front surface 91 and a back surface 92 facing away from each other with respect to the Z-direction. In the first embodiment, the front surface 91 and the back surface 92 are both flat and orthogonal to the Z-direction. The front surface 91 faces the same direction as the substrate front surface 21. The back surface 92 faces the same direction as the substrate back surface 22. The edge-emitting element 70 is mounted on the front surface 91 of the sub-mount substrate 90. In an example, the edge-emitting element 70 is die-bonded onto the front surface 91 of the sub-mount substrate 90.

The sub-mount substrate 90 includes a through-interconnect 93 extending through the sub-mount substrate 90 in the thickness-wise direction. The through-interconnect 93 is formed from a material containing, for example, Cu. The material of the through-interconnect 93 is not limited to Cu, and may contain at least one of titanium (Ti), tungsten (W), and Al. The number of through-interconnects 93 may be changed. In an example, there may be more than one through-interconnect 93. In an example, the number of through-interconnects 93 may be the same as the number (in the present embodiment, eight) of element electrodes 80 of the edge-emitting element 70, which will be described later. In a case in which the sub-mount substrate 90 is formed from a material containing Cu, the sub-mount substrate 90 is entirely formed by a conductor. In this case, the through-interconnect 93 may be omitted.

As shown in FIGS. 2, 4, and 5, the edge-emitting element 70 arranged on the sub-mount substrate 90 has a shape of a rectangular plate. The edge-emitting element 70 is rectangular in plan view, with long sides extending in the X-direction and short sides extending in the Y-direction. In an example, in plan view, the edge-emitting element 70 is slightly smaller than the sub-mount substrate 90. In plan view, the edge-emitting element 70 is located at the center of the substrate 20 in the X-direction. In other words, the imaginary center line CL is also located at the center of the edge-emitting element 70 in the X-direction.

The edge-emitting element 70 is thinner than the sub-mount substrate 90. The edge-emitting element 70 is also thinner than the substrate 20. The thickness of the edge-emitting element 70 may be changed. For example, the thickness of the edge-emitting element 70 may be greater than or equal to the thickness of the substrate 20.

The edge-emitting element 70 includes an element front surface 71, an element back surface 72, and first to fourth element side surfaces 73 to 76. The element front surface 71 and the element back surface 72 face away from each other with respect to the Z-direction. The first to fourth element side surfaces 73 to 76 intersect the element front surface 71 and the element back surface 72. In the first embodiment, the element front surface 71 and the element back surface 72 are both flat and orthogonal to the Z-direction. In an example, the first to fourth element side surfaces 73 to 76 are each flat and orthogonal to the element front surface 71 and the element back surface 72. The first element side surface 73 and the second element side surface 74 are two opposite end surfaces of the edge-emitting element 70 in the X-direction. The third element side surface 75 and the fourth element side surface 76 are two opposite end surfaces of the edge-emitting element 70 in the Y-direction. The first element side surface 73 is one of the two opposite end surfaces of the edge-emitting element 70 in the X-direction located closer to the first substrate side surface 23. The second element side surface 74 is the other one of the two opposite end surfaces of the edge-emitting element 70 in the X-direction located closer to the second substrate side surface 24. The third element side surface 75 is one of the two opposite end surfaces of the edge-emitting element 70 in the Y-direction located closer to the third substrate side surface 25. The fourth element side surface 76 is the other one of the two opposite end surfaces of the edge-emitting element 70 in the Y-direction located closer to the fourth substrate side surface 26. In an example, the fourth element side surface 76 is a light emitting end surface through which the edge-emitting element 70 emits light.

The edge-emitting element 70 includes a plurality of (in the first embodiment, eight) element electrodes 80 formed on the element front surface 71. The edge-emitting element 70 includes an emitter 80A (80B) for each of the element electrodes 80. That is, the edge-emitting element 70 includes a plurality of (in the first embodiment, eight) emitters 80A (80B). In plan view, the emitters 80A (80B) are arranged next to each other in the X-direction. For the sake of convenience, four of the eight emitters of the edge-emitting element 70 located closer to the first substrate side surface 23 than the imaginary center line CL will be referred to as “emitters 80A”, and four of the eight emitters of the edge-emitting element 70 located closer to the second substrate side surface 24 than the imaginary center line CL will be referred to as “emitters 80B”. The X-direction corresponds to “first direction”. The Y-direction corresponds to “second direction”.

More specifically, the emitters 80A (80B) include a first inner emitter 81A (81B), a second inner emitter 82A (82B), an outer emitter 83A (83B), and an end emitter 84A (84B).

The first inner emitter 81A includes a first inner element electrode 81P, which will be described later. The first inner emitter 81B includes a first inner element electrode 81Q. More specifically, the first inner emitter 81A is an emitter that emits light when voltage is applied to the first inner element electrode 81P. The first inner emitter 81B is an emitter that emits light when voltage is applied to the first inner element electrode 81Q.

The second inner emitter 82A includes a second inner element electrode 82P, which will be described later. The second inner emitter 82B includes a second inner element electrode 82Q. More specifically, the second inner emitter 82A is an emitter that emits light when voltage is applied to the second inner element electrode 82P. The second inner emitter 82B is an emitter that emits light when voltage is applied to the second inner element electrode 82Q.

The outer emitter 83A includes an outer element electrode 83P, which will be described later. The outer emitter 83B includes an outer element electrode 83Q. More specifically, the outer emitter 83A is an emitter that emits light when voltage is applied to the outer element electrode 83P. The outer emitter 83B is an emitter that emits light when voltage is applied to the outer element electrode 83Q.

The end emitter 84A includes an end element electrode 84P, which will be described later. The end emitter 84B includes an end element electrode 84Q. More specifically, the end emitter 84A is an emitter that emits light when voltage is applied to the end element electrode 84P. The end emitter 84B is an emitter that emits light when voltage is applied to the end element electrode 84Q.

In the first embodiment, the first inner element electrode 81P (81Q) corresponds to “first element electrode”, and the first inner emitter 81A (81B) corresponds to “first emitter”. The second inner element electrode 82P (82Q) may correspond to “first element electrode”, and the second inner emitter 82A (82B) may correspond to “first emitter”. The outer element electrode 83P (83Q) corresponds to “second element electrode”, and the outer emitter 83A (83B) corresponds to “second emitter”.

In plan view, the element electrodes 80 are spaced apart from each other in the X-direction. In other words, in plan view, the emitters 80A (80B) are spaced apart from each other in the X-direction. The element electrodes 80 are each rectangular in plan view, with long sides extending in the Y-direction and short sides extending in the X-direction. The element electrodes 80 are formed from, for example, Au. The material of the element electrodes 80 is not limited to Au, and may contain at least one of Al, Ni, Pd, Ag, and Cu.

The element electrodes 80 include the first inner element electrodes 81P and 81Q, the second inner element electrodes 82P and 82Q, the outer element electrodes 83P and 83Q, and the end element electrodes 84P and 84Q.

The first inner element electrode 81P, the second inner element electrode 82P, the outer element electrode 83P, and the end element electrode 84P are formed in a region of the element front surface 71 located closer to the first element side surface 73 than the imaginary center line CL is. The first inner element electrode 81Q, the second inner element electrode 82Q, the outer element electrode 83Q, and the end element electrode 84Q are formed in a region of the element front surface 71 located closer to the second element side surface 74 than the imaginary center line CL is.

The first inner element electrode 81P is located closer to the imaginary center line CL (center of edge-emitting element 70 in X-direction) than the second inner element electrode 82P, the outer element electrode 83P, and the end element electrode 84P are. The end element electrode 84P is located closer to the first element side surface 73 than the first inner element electrode 81P, the second inner element electrode 82P, and the outer element electrode 83P are. In other words, the end element electrode 84P is arranged on one of two ends of the element front surface 71 in the X-direction located closer to the first element side surface 73. The outer element electrode 83P is located closer to the end element electrode 84P than the first inner element electrode 81P and the second inner element electrode 82P are.

The first inner element electrode 81Q is located closer to the imaginary center line CL (center of edge-emitting element 70 in X-direction) than the second inner element electrode 82Q, the outer element electrode 83Q, and the end element electrode 84Q are. The end element electrode 84Q is located closer to the second element side surface 74 than the first inner element electrode 81Q, the second inner element electrode 82Q, and the outer element electrode 83Q are. In other words, the end element electrode 84Q is arranged on one of two ends of the element front surface 71 in the X-direction located closer to the second element side surface 74. The outer element electrode 83Q is located closer to the end element electrode 84Q than the first inner element electrode 81Q and the second inner element electrode 82Q are. As described above, in the direction in which the first inner element electrodes 81P and 81Q, the second inner element electrodes 82P and 82Q, the outer element electrodes 83P and 83Q, and the end element electrodes 84P and 84Q are arranged (X-direction), “inner” means “toward the imaginary center line CL (center of edge-emitting element 70 in X-direction)”, and “outer” means “toward the first element side surfaces 73 or the second element side surfaces 74”.

As shown in FIGS. 4 and 5, the edge-emitting element 70 includes a back-surface electrode 85. In an example, the back-surface electrode 85 forms the element back surface 72 of the edge-emitting element 70. In an example, the back-surface electrode 85 is formed on the entire element back surface 72 of the edge-emitting element 70. The back-surface electrode 85 is formed from, for example, Au. The material of the back-surface electrode 85 is not limited to Au, and may contain at least one of Al, Ni, Pd, Ag, and Cu.

The edge-emitting element 70 is mounted on the sub-mount substrate 90 by a conductive bonding material (not shown). Therefore, the back-surface electrode 85 is electrically connected to the sub-mount substrate 90 (through-interconnect 93) by the conductive bonding material. Examples of the conductive bonding material may include solder paste, silver paste, gold paste, and copper paste.

As shown in FIG. 2, the semiconductor light emitting device 10 includes wires 100 that separately electrically connect the emitters 80A (80B) to the front-surface electrodes 30. The wires 100 are, for example, bonding wires. The wires 100 are formed from a material containing, for example, Au. Instead of Au, the wires 100 may be formed from a material containing at least one of Cu, Ag, and Al.

The wires 100 include first inner wires 110P and 110Q, second inner wires 120P and 120Q, outer wires 130P and 130Q, and end wires 140P and 140Q. In the first embodiment, the first inner wires 110P (110Q) correspond to “first wires”. The second inner wires 120P (120Q) may correspond to “first wires”. The outer wires 130P (130Q) correspond to “second wires”.

The diameter of the wires 100 and the planar size of the element electrodes 80 determine the number of wires 100. In the first embodiment, there are four of each of the first inner wire 110P, the first inner wire 110Q, the second inner wire 120P, the second inner wire 120Q, the outer wire 130P, the outer wire 130Q, the end wire 140P, and the end wire 140Q. In other words, the first inner wires 110P, the first inner wires 110Q, the second inner wires 120P, the second inner wires 120Q, the outer wires 130P, the outer wires 130Q, the end wires 140P, and the end wires 140Q are equal in number. In the first embodiment, four is the maximum number of each of the first inner wires 110P, the maximum number of each of the first inner wire 110Q, the second inner wire 120P, the second inner wire 120Q, the outer wire 130P, the outer wire 130Q, the end wire 140P, and the end wire 140Q. The number of first inner wires 110P, first inner wires 110Q, second inner wires 120P, second inner wires 120Q, outer wires 130P, outer wires 130Q, end wires 140P, and end wires 140Q may be, for example, three or five.

The first inner wires 110P are each bonded to both the first inner element electrode 81P of the edge-emitting element 70 and the first inner front-surface electrode 31P. The first inner wires 110P electrically connect the first inner element electrode 81P to the first inner front-surface electrode 31P. The first inner wires 110Q are each bonded to both the first inner element electrode 81Q and the first inner front-surface electrode 31Q. The first inner wires 110Q electrically connect the first inner element electrode 81Q to the first inner front-surface electrode 31Q.

The second inner wires 120P are each bonded to both the second inner element electrode 82P of the edge-emitting element 70 and the second inner front-surface electrode 32P. The second inner wires 120P electrically connect the second inner element electrode 82P to the second inner front-surface electrode 32P. The second inner wires 120Q are each bonded to both the second inner element electrode 82Q and the second inner front-surface electrode 32Q. The second inner wires 120P electrically connect the second inner element electrode 82Q to the second inner front-surface electrode 32Q.

The outer wires 130P are each bonded to both the outer element electrode 83P of the edge-emitting element 70 and the outer front-surface electrode 33P. The outer wires 130P electrically connect the outer element electrode 83P to the outer front-surface electrode 33P. The outer wires 130Q are each bonded to both the outer element electrode 83Q and the outer front-surface electrode 33Q. The outer wires 130Q electrically connect the outer element electrode 83Q to the outer front-surface electrode 33Q.

The end wires 140P are each bonded to both the end element electrode 84P of the edge-emitting element 70 and the end front-surface electrode 34P. The end wires 140P electrically connect the end element electrode 84P to the end front-surface electrode 34P. The end wires 140Q are each bonded to both the end element electrode 84Q of the edge-emitting element 70 and the end front-surface electrode 34Q. The end wires 140Q electrically connect the end element electrode 84Q to the end front-surface electrode 34Q.

As shown in FIG. 6, the first inner wires 110P and 110Q, the second inner wires 120P and 120Q, the outer wires 130P and 130Q, and the end wires 140P and 140Q have the same wire height. The wire height may be defined by a distance from the substrate front surface 21 to a position (top) of the wires 100 located farthest from the substrate front surface 21 in the Z-direction.

In the example shown in FIG. 6, the first inner wires 110P have the same wire height, and the first inner wires 110Q have the same wire height. The second inner wires 120P have the same wire height, and the second inner wires 120Q have the same wire height. The outer wires 130P have the same wire height, and the outer wires 130Q have the same wire height. The end wires 140P have the same wire height, and the end wires 140Q have the same wire height.

The first inner wires 110P may have different wire heights, and the first inner wires 110Q may have different wire heights. The second inner wires 120P may have different wire heights, and the second inner wires 120Q may have different wire heights. The outer wires 130P may have different wire heights, and the outer wires 130Q may have different wire heights. The end wires 140P may have different wire heights, and the end wires 140Q may have different wire heights.

As shown in FIG. 3, the semiconductor light emitting device 10 includes a plurality of (in the first embodiment, nine) back-surface electrodes 40 formed on the substrate back surface 22 of the substrate 20. The back-surface electrodes 40 are spaced apart from each other. The back-surface electrodes 40 are formed from, for example, a copper foil. The material of the back-surface electrodes 40 is not limited to Cu, and may contain at least one of Al, Ni, Pd, Ag, and Au.

The back-surface electrodes 40 include first inner back-surface electrodes 41P and 41Q, second inner back-surface electrodes 42P and 42Q, outer back-surface electrodes 43P and 43Q, and end back-surface electrodes 44P and 44Q. The first inner back-surface electrodes 41P and 41Q, the second inner back-surface electrodes 42P and 42Q, the outer back-surface electrodes 43P and 43Q, and the end back-surface electrodes 44P and 44Q are electrically connected to the front-surface electrodes 30, and serve as external electrodes of the semiconductor light emitting device 10.

The first inner back-surface electrode 41P, the second inner back-surface electrode 42P, the outer back-surface electrode 43P, and the end back-surface electrode 44P are formed in a region of the substrate back surface 22 located closer to the first substrate side surface 23 than the imaginary center line CL is. The first inner back-surface electrode 41Q, the second inner back-surface electrode 42Q, the outer back-surface electrode 43Q, and the end back-surface electrode 44Q are formed in a region of the substrate back surface 22 located closer to the second substrate side surface 24 than the imaginary center line CL is. In plan view, the first inner back-surface electrode 41P, the second inner back-surface electrode 42P, the outer back-surface electrode 43P, and the end back-surface electrode 44P are symmetric to the first inner back-surface electrode 41Q, the second inner back-surface electrode 42Q, the outer back-surface electrode 43Q, and the end back-surface electrode 44Q with respect to the imaginary center line CL.

The first inner back-surface electrode 41P, the second inner back-surface electrode 42P, and the outer back-surface electrode 43P are spaced apart from each other in the X-direction in a state aligned in the same position in the Y-direction. The first inner back-surface electrode 41P is located closer to the imaginary center line CL (center of substrate 20 in X-direction) than the second inner back-surface electrode 42P and the outer back-surface electrode 43P are. The outer back-surface electrode 43P is located closer to the first substrate side surface 23 than the first inner back-surface electrode 41P and the second inner back-surface electrode 42P are.

The end back-surface electrode 44P is separated from the first inner back-surface electrode 41P, the second inner back-surface electrode 42P, and the outer back-surface electrode 43P toward the fourth substrate side surface 26. As viewed in the Y-direction, the end back-surface electrode 44P overlaps the outer back-surface electrode 43P.

The first inner back-surface electrode 41Q, the second inner back-surface electrode 42Q, and the outer back-surface electrode 43Q are spaced apart from each other in the X-direction in a state aligned in the same position in the Y-direction. The first inner back-surface electrode 41Q is located closer to the imaginary center line CL (center of substrate 20 in X-direction) than the second inner back-surface electrode 42Q and the outer back-surface electrode 43Q are. The outer back-surface electrode 43Q is located closer to the second substrate side surface 24 than the first inner back-surface electrode 41Q and the second inner back-surface electrode 42Q are. The first inner back-surface electrodes 41P and 41Q are adjacent to each other at opposite sides of the imaginary center line CL.

The end back-surface electrode 44Q is separated from the first inner back-surface electrode 41Q, the second inner back-surface electrode 42Q, and the outer back-surface electrode 43Q toward the fourth substrate side surface 26. As viewed in the Y-direction, the end back-surface electrode 44Q overlaps the outer back-surface electrode 43Q. As viewed in the X-direction, the end back-surface electrode 44Q overlaps the end back-surface electrode 44P.

As described above, in the direction in which the first inner back-surface electrodes 41P and 41Q, the second inner back-surface electrodes 42P and 42Q, and the outer back-surface electrodes 43P and 43Q are arranged (X-direction), “inner” means “toward the imaginary center line CL (center of substrate 20 in X-direction)”, and “outer” means “toward the first substrate side surface 23 or the second substrate side surface 24”.

In plan view, the first inner back-surface electrodes 41P and 41Q and the second inner back-surface electrodes 42P and 42Q are identical in size and shape. In an example, the first inner back-surface electrodes 41P and 41Q and the second inner back-surface electrodes 42P and 42Q each include a main body and a projection. The main body is rectangular in plan view. The projection projects from the main body toward the third substrate side surface 25. The main body is rectangular, with long sides extending in the Y-direction and short sides extending in the X-direction. The projection is curved in plan view. The planar shape of the projection may be changed. In an example, the projection may have a flat distal end surface that extends in the X-direction in plan view. That is, the projection may be rectangular in plan view.

In plan view, the outer back-surface electrodes 43P and 43Q are symmetric with respect to the imaginary center line CL. In plan view, the outer back-surface electrodes 43P and 43Q each have a greater area than each of the first inner back-surface electrodes 41P and 41Q or each of the second inner back-surface electrodes 42P and 42Q. In an example, the outer back-surface electrodes 43P and 43Q each include a main body and a projection. The main body is rectangular in plan view. The projection projects from the main body toward the third substrate side surface 25. The main body is rectangular, with long sides extending in the X-direction and short sides extending in the Y-direction. The projection is curved in plan view. The projection of the outer back-surface electrode 43P is formed on its main body at a position located toward the second inner back-surface electrode 42P. The projection of the outer back-surface electrode 43Q is formed on its main body at a position located toward the second inner back-surface electrode 42Q. The projections of the outer back-surface electrodes 43P and 43Q are identical in size and shape to the projections of the first inner back-surface electrodes 41P and 41Q or the projections of the second inner back-surface electrodes 42P and 42Q.

The end back-surface electrodes 44P and 44Q are identical in size and shape. In an example, the end back-surface electrodes 44P and 44Q are rectangular, with long sides extending in the X-direction and short sides extending in the Y-direction.

The back-surface electrodes 40 include an element back-surface electrode 45. The element back-surface electrode 45 is spaced apart from the first inner back-surface electrodes 41P and 41Q, the second inner back-surface electrodes 42P and 42Q, and the end back-surface electrodes 44P and 44Q. The element back-surface electrode 45 is located closer to the fourth substrate side surface 26 than the first inner back-surface electrodes 41P and 41Q and the second inner back-surface electrodes 42P and 42Q are.

In an example, in plan view, the element back-surface electrode 45 is symmetric with respect to the imaginary center line CL. In plan view, the element back-surface electrode 45 includes a projection having a form of a step. More specifically, the element back-surface electrode 45 includes a belt-shaped main body extending in the X-direction, and a projection projecting from the center of the main body with respect to the X-direction toward the third substrate side surface 25. The projection is rectangular in plan view, with long sides extending in the X-direction and short sides extending in the Y-direction. The end back-surface electrodes 44P and 44Q are respectively arranged at two opposite sides of the projection in the X-direction.

As shown in FIGS. 2 and 3, the semiconductor light emitting device 10 includes through-interconnects 50 extending through the substrate 20 in the thickness-wise direction (Z-direction). The through-interconnects 50 are separately connected to the front-surface electrodes 30. Also, the through-interconnects 50 are separately connected to the back-surface electrodes 40. Thus, the through-interconnects 50 separately electrically connect the front-surface electrodes 30 to the back-surface electrodes 40. The through-interconnects 50 are formed from a material containing, for example, Cu. The material of the through-interconnects 50 is not limited to Cu, and may contain at least one of Ti, W, and Al.

In the example shown in FIGS. 2 and 3, the through-interconnects 50 are rod-shaped, and through-holes formed in the substrate 20 for the through-interconnects 50 are filled with the through-interconnects 50. The shape of the through-interconnects 50 may be changed. In an example, the through-interconnects 50 may be tubular, and the side walls of the through-holes formed in the substrate 20 for the through-interconnects 50 may be in contact with the through-interconnects 50. In this case, the insides of the tubular through-interconnects 50 may be hollow or may be filled with an insulative material, such as an epoxy resin or the like.

The through-interconnects 50 include first inner through-interconnects 51P and 51Q, second inner through-interconnects 52P and 52Q, outer through-interconnects 53P and 53Q, and end through-interconnects 54P and 54Q. In an example, the first inner through-interconnects 51P and 51Q, the second inner through-interconnects 52P and 52Q, the outer through-interconnects 53P and 53Q, and the end through-interconnects 54P and 54Q are identical in size and shape. The first inner through-interconnects 51P and 51Q, the second inner through-interconnects 52P and 52Q, the outer through-interconnects 53P and 53Q, and the end through-interconnects 54P and 54Q are, for example, elliptic in plan view. The planar shapes of the first inner through-interconnects 51P and 51Q, the second inner through-interconnects 52P and 52Q, the outer through-interconnects 53P and 53Q, and the end through-interconnects 54P and 54Q may be changed. In an example, the first inner through-interconnects 51P and 51Q, the second inner through-interconnects 52P and 52Q, the outer through-interconnects 53P and 53Q, and the end through-interconnects 54P and 54Q may be, for example, circular, oval, or polygonal in plan view.

In plan view, the first inner through-interconnect 51P overlaps both the first inner front-surface electrode 31P and the first inner back-surface electrode 41P. In plan view, the longitudinal direction of the elliptic first inner through-interconnect 51P intersects both the X-direction and the Y-direction. In an example, in plan view, the longitudinal direction of the first inner through-interconnect 51P is inclined toward the third substrate side surface 25 as the first inner through-interconnect 51P becomes closer to the first substrate side surface 23.

As shown in FIG. 2, in plan view, the first inner through-interconnect 51P is connected to a part of the first inner front-surface electrode 31P located toward the third substrate side surface 25. As shown in FIG. 3, in plan view, the first inner through-interconnect 51P is connected to a part of the first inner back-surface electrode 41P located toward the fourth substrate side surface 26.

In plan view, the second inner through-interconnect 52P overlaps both the second inner front-surface electrode 32P and the second inner back-surface electrode 42P. In plan view, the longitudinal direction of the elliptic second inner through-interconnect 52P intersects both the X-direction and the Y-direction. In an example, in plan view, the longitudinal direction of the second inner through-interconnect 52P is parallel to the longitudinal direction of the first inner through-interconnect 51P.

As shown in FIG. 2, in plan view, the second inner through-interconnect 52P is connected to a part of the second inner front-surface electrode 32P located toward the first substrate side surface 23 and the third substrate side surface 25. As shown in FIG. 3, in plan view, the second inner through-interconnect 52P is connected to a part of the second inner back-surface electrode 42P located toward the fourth substrate side surface 26.

In plan view, the outer through-interconnect 53P overlaps both the outer front-surface electrode 33P and the outer back-surface electrode 43P. In plan view, the longitudinal direction of the elliptic outer through-interconnect 53P intersects both the X-direction and the Y-direction. In an example, in plan view, the longitudinal direction of the outer through-interconnect 53P is parallel to the longitudinal direction of the first inner through-interconnect 51P.

As shown in FIG. 2, in plan view, the outer through-interconnect 53P is connected to a part of the outer front-surface electrode 33P located toward the first substrate side surface 23 and the third substrate side surface 25. As shown in FIG. 3, in plan view, the outer through-interconnect 53P is connected to a part of the outer back-surface electrode 43P located toward the second substrate side surface 24 and the fourth substrate side surface 26.

In plan view, the end through-interconnect 54P overlaps both the end front-surface electrode 34P and the end back-surface electrode 44P. In plan view, the longitudinal direction of the elliptic end through-interconnect 54P coincides with the Y-direction. In other words, the longitudinal direction of the end through-interconnect 54P differs from the longitudinal direction of the first inner through-interconnect 51P.

The first inner through-interconnect 51Q, the second inner through-interconnect 52Q, the outer through-interconnect 53Q, and the end through-interconnect 54Q are symmetric to the first inner through-interconnect 51P, the second inner through-interconnect 52P, the outer through-interconnect 53P, and the end through-interconnect 54P with respect to the imaginary center line CL. Therefore, the longitudinal direction of the first inner through-interconnect 51Q, the second inner through-interconnect 52Q, and the outer through-interconnect 53Q, which are elliptic, is inclined toward the third substrate side surface 25 as long sides become closer to the second substrate side surface 24.

The first inner through-interconnect 51Q overlaps both the first inner front-surface electrode 31Q and the first inner back-surface electrode 41Q. As shown in FIG. 2, in plan view, the first inner through-interconnect 51Q is connected to a part of the first inner front-surface electrode 31Q located toward the third substrate side surface 25. As shown in FIG. 3, in plan view, the first inner through-interconnect 51Q is connected to a part of the first inner back-surface electrode 41Q located toward the fourth substrate side surface 26.

The second inner through-interconnect 52Q overlaps both the second inner front-surface electrode 32Q and the second inner back-surface electrode 42Q. As shown in FIG. 2, in plan view, the second inner through-interconnect 52Q is connected to a part of the second inner front-surface electrode 32Q located toward the second substrate side surface 24 and the third substrate side surface 25. As shown in FIG. 3, in plan view, the second inner through-interconnect 52Q is connected to a part of the second inner back-surface electrode 42Q located toward the fourth substrate side surface 26.

The outer through-interconnect 53Q overlaps both the outer front-surface electrode 33Q and the outer back-surface electrode 43Q. As shown in FIG. 2, in plan view, the outer through-interconnect 53Q is connected to a part of the outer front-surface electrode 33Q located toward the second substrate side surface 24 and the third substrate side surface 25. As shown in FIG. 3, in plan view, the outer through-interconnect 53Q is connected to a part of the outer back-surface electrode 43Q located toward the first substrate side surface 23 and the fourth substrate side surface 26.

The through-interconnects 50 include an element through-interconnect 55. The element through-interconnect 55 is arranged at the center of the substrate 20 in the X-direction. In plan view, the element through-interconnect 55 overlaps both the edge-emitting element 70 and the sub-mount substrate 90. The element through-interconnect 55 is rectangular in plan view, with long sides extending in the X-direction and short sides extending in the Y-direction.

The element through-interconnect 55 may be formed by a plurality of through-interconnects. In an example, the element through-interconnect 55 may be formed by a plurality of through-interconnects having the same configuration as the through-interconnects 50.

As shown in FIG. 3, the semiconductor light emitting device 10 includes a back-surface resist 60 that covers the back-surface electrodes 40. The back-surface resist 60 is a solder resist and is formed from, for example, an insulative material. The insulative material may be, for example, an epoxy resin. In FIG. 3, portions of the first inner back-surface electrodes 41P and 41Q, the second inner back-surface electrodes 42P and 42Q, the outer back-surface electrodes 43P and 43Q, and the end back-surface electrodes 44P and 44Q that overlap the back-surface resist 60 are indicated by broken lines.

The back-surface resist 60 covers most of the substrate back surface 22. The back-surface resist 60 includes openings in correspondence with the back-surface electrodes 40. The openings of the back-surface resist 60 include a plurality of (in the first embodiment, six) first openings 61, a plurality of (in the first embodiment, two) second openings 62, and a plurality of (in the first embodiment, six) third openings 63.

The first openings 61 separately expose the first inner back-surface electrodes 41P and 41Q, the second inner back-surface electrodes 42P and 42Q, and the outer back-surface electrodes 43P and 43Q. The first openings 61 each extend in the Y-direction and expose the projections of the first inner back-surface electrodes 41P and 41Q, the second inner back-surface electrodes 42P and 42Q, and the outer back-surface electrodes 43P and 43Q.

The second openings 62 separately expose the end back-surface electrodes 44P and 44Q. The second openings 62 are arranged at two opposite ends of the back-surface resist 60 in the X-direction. In plan view, the second openings 62 each extend in the X-direction.

The third openings 63 expose the element back-surface electrode 45. In plan view, the third openings 63 are each elliptic and elongated in the Y-direction. The third openings 63 are spaced apart from each other in the X-direction.

The third openings 63 include four third openings 63A and two third openings 63B. The four third openings 63A are elliptic and relatively long in the Y-direction. The two third openings 63B are elliptic and relatively short in the Y-direction. The four third openings 63A expose the projection of the element back-surface electrode 45. The two third openings 63B are respectively arranged at two opposite sides of the four third openings 63A in the X-direction.

### Detailed Shapes and Positional Relationship of Inner Front-Surface Electrodes, Outer Front-Surface Electrodes, and End Front-Surface Electrodes

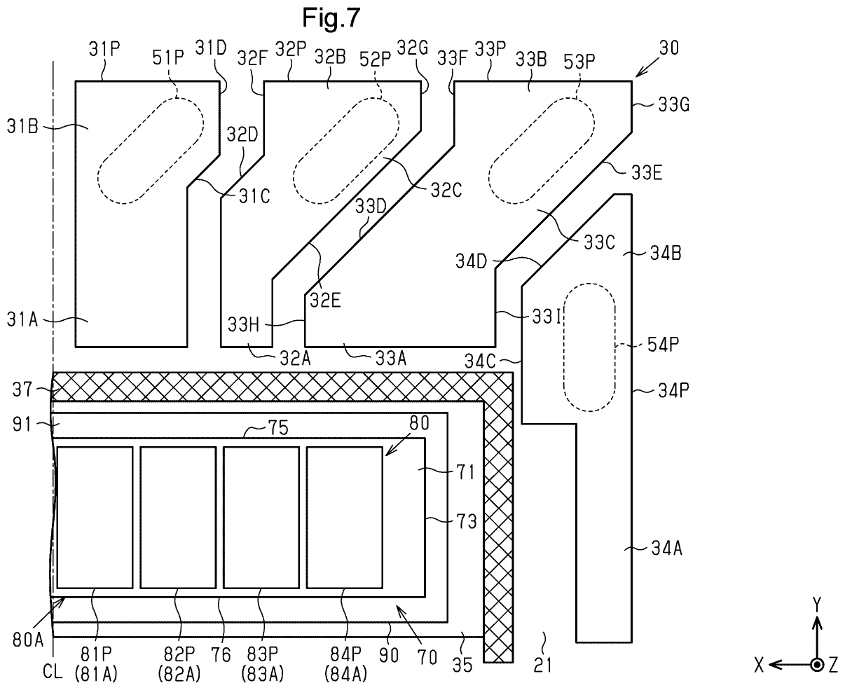

The detailed shapes and the positional relationship of the first inner front-surface electrodes 31P and 31Q, the second inner front-surface electrodes 32P and 32Q, the outer front-surface electrodes 33P and 33Q, and the end front-surface electrodes 34P and 34Q will now be described. FIG. 7 is an enlarged plan view of the first inner front-surface electrode 31P, the second inner front-surface electrode 32P, the outer front-surface electrode 33P, and the end front-surface electrode 34P. As described above, the first inner front-surface electrode 31Q, the second inner front-surface electrode 32Q, the outer front-surface electrode 33Q, and the end front-surface electrode 34Q are symmetric to the first inner front-surface electrode 31P, the second inner front-surface electrode 32P, the outer front-surface electrode 33P, and the end front-surface electrode 34P with respect to the imaginary center line CL. Thus, these components will not be described in detail.

As shown in FIG. 7, the first inner front-surface electrode 31P is substantially rectangular, with long sides extending in the Y-direction and short sides extending in the X-direction. The first inner front-surface electrode 31P extends in the Y-direction. In plan view, the first inner front-surface electrode 31P overlaps both the first inner element electrode 81P and the second inner element electrode 82P of the edge-emitting element 70 with respect to the X-direction.

The first inner front-surface electrode 31P includes a first inner narrow portion 31A, and a first inner wide portion 31B having a greater width (dimension in X-direction) than the first inner narrow portion 31A.

The first inner narrow portion 31A is a part of the first inner front-surface electrode 31P located toward the edge-emitting element 70 in the Y-direction. The first inner narrow portion 31A has a greater width (dimension in X-direction) than the first inner element electrodes 81P.

The first inner wide portion 31B is a part of the first inner front-surface electrode 31P located away from the edge-emitting element 70 in the Y-direction. In other words, the first inner wide portion 31B is an end of the first inner front-surface electrode 31P located toward the third substrate side surface 25 (refer to FIG. 2). The first inner wide portion 31B includes a projection that projects from the first inner narrow portion 31A toward the first substrate side surface 23 (refer to FIG. 2). The first inner through-interconnect 51P is connected to the first inner wide portion 31B.

In plan view, the first inner wide portion 31B includes an inclined side 31C. The inclined side 31C is formed on the projection of the first inner wide portion 31B projecting from the first inner narrow portion 31A, and the inclined side 31C forms an end of the projection located toward the edge-emitting element 70 in the Y-direction. The inclined side 31C is inclined toward the third substrate side surface 25 as the inclined side 31C becomes closer to the first substrate side surface 23 (second inner front-surface electrode 32P). In other words, the inclined side 31C is inclined toward the first inner emitter 81A of the edge-emitting element 70 as the inclined side 31C extends from an end side 31D of the first inner wide portion 31B toward the center of the substrate front surface 21 (imaginary center line CL) in the X-direction. The end side 31D is one of two opposite end sides of the first inner wide portion 31B in the X-direction located closer to the second inner front-surface electrode 32P. In plan view, the end side 31D extends in the Y-direction.

In plan view, the second inner front-surface electrode 32P is located closer to the first substrate side surface 23 than the second inner element electrode 82P of the edge-emitting element 70 is. In plan view, the second inner front-surface electrode 32P opposes the outer element electrode 83P of the edge-emitting element 70 in the Y-direction.

The second inner front-surface electrode 32P includes a second inner narrow portion 32A, a second inner wide portion 32B, and a second inner inclined portion 32C. The second inner wide portion 32B has a greater width (dimension in X-direction) than the second inner narrow portion 32A. The second inner inclined portion 32C connects the second inner narrow portion 32A and the second inner wide portion 32B.

The second inner narrow portion 32A is a part of the second inner front-surface electrode 32P located toward the edge-emitting element 70 in the Y-direction. In an example, the second inner narrow portion 32A is an end of the second inner front-surface electrode 32P located toward the edge-emitting element 70. In plan view, the second inner narrow portion 32A opposes the outer element electrode 83P of the edge-emitting element 70 in the Y-direction. More specifically, in plan view, the second inner narrow portion 32A opposes a part of the outer element electrode 83P located toward the second inner element electrode 82P. As viewed in the Y-direction, the second inner narrow portion 32A is located closer to the first inner front-surface electrode 31P than the outer front-surface electrode 33P is.

The second inner narrow portion 32A has a smaller width than the first inner narrow portion 31A of the first inner front-surface electrode 31P. The second inner narrow portion 32A has a smaller width (dimension in X-direction) than the element electrode 80 of the edge-emitting element 70.

The second inner wide portion 32B is a part of the second inner front-surface electrode 32P located away from the edge-emitting element 70. In an example, the second inner wide portion 32B is one of two opposite ends of the second inner front-surface electrode 32P in the Y-direction located farther away from the edge-emitting element 70. As viewed in the Y-direction, the second inner wide portion 32B is shifted from the second inner narrow portion 32A toward the first substrate side surface 23 (outer front-surface electrode 33P). In plan view, the second inner wide portion 32B opposes both the outer element electrode 83P and the end element electrode 84P of the edge-emitting element 70 in the Y-direction. In plan view, in the Y-direction, the second inner wide portion 32B opposes a part of the outer element electrode 83P located toward the end element electrode 84P. The second inner wide portion 32B is adjacent to the first inner wide portion 31B in the X-direction.

The width (dimension in X-direction) of the second inner wide portion 32B is at least two times greater than the width of the second inner narrow portion 32A. In an example, the width of the second inner wide portion 32B is approximately three times greater than the width of the second inner narrow portion 32A. The second inner wide portion 32B has a greater width than the first inner narrow portion 31A. The second inner wide portion 32B has a greater width than the first inner wide portion 31B. The second inner wide portion 32B includes end sides 32F and 32G. The end side 32F is one of two opposite end sides of the second inner wide portion 32B in the X-direction located closer to the first inner front-surface electrode 31P. The end side 32G is the other one of the two opposite end sides of the second inner wide portion 32B in the X-direction located closer to the outer front-surface electrode 33P. In plan view, the end sides 32F and 32G each extend in the Y-direction.

The second inner inclined portion 32C is inclined toward the third substrate side surface 25 as the second inner inclined portion 32C becomes closer to the first substrate side surface 23. In other words, the second inner inclined portion 32C is inclined away from the edge-emitting element 70 as the second inner inclined portion 32C extends toward the outer front-surface electrode 33P. The second inner inclined portion 32C has a greater width (dimension in a direction orthogonal to inclination direction of second inner inclined portion 32C in plan view) than the second inner narrow portion 32A. The second inner inclined portion 32C has a greater width than the second inner wide portion 32B.

In plan view, the second inner inclined portion 32C includes an inclined side 32D located toward the first inner front-surface electrode 31P, and an inclined side 32E located toward the outer front-surface electrode 33P.

The inclined side 32D is adjacent to the inclined side 31C of the first inner front-surface electrode 31P in the X-direction. The inclined side 32D is inclined toward the emitter 80A, which corresponds to the second inner element electrode 82P of the edge-emitting element 70, as the inclined side 32D extends from the end side 32F toward the center of the substrate front surface 21 in the X-direction. The inclined side 32D is inclined in the same direction as the inclined side 31C. In plan view, the inclined side 32D is parallel to the inclined side 31C. In an example, the inclined side 32D has the same length as the inclined side 31C.

The inclined side 32E is inclined toward the second inner emitter 82A as the inclined side 32E extends from the end side 32G toward the center of the substrate front surface 21 (imaginary center line CL) in the X-direction. The inclined side 32E is inclined in the same direction as the inclined side 32D. In plan view, the inclined side 32E is parallel to the inclined side 32D. The inclined side 32E is longer than the inclined side 32D.

As described above, the second inner inclined portion 32C is formed as an inclined region including the inclined side 32D, which extends from the end side 32F toward the center of the substrate front surface 21, and the inclined side 32E, which extends from the end side 32G toward the center of the substrate front surface 21.

The second inner through-interconnect 52P overlaps both the second inner wide portion 32B and the second inner inclined portion 32C. In an example, the longitudinal direction of the elliptic second inner through-interconnect 52P is parallel to the direction in which the second inner inclined portion 32C extends.

In plan view, the outer front-surface electrode 33P is located closer to the first substrate side surface 23 than the outer element electrode 83P of the edge-emitting element 70 is. In plan view, the outer front-surface electrode 33P opposes the end element electrode 84P of the edge-emitting element 70 in the Y-direction.

The outer front-surface electrode 33P includes a first outer end portion 33A located toward the edge-emitting element 70, a second outer end portion 33B located away from the edge-emitting element 70, and an outer inclined portion 33C connecting the first outer end portion 33A and the second outer end portion 33B.

The first outer end portion 33A is adjacent to the second inner narrow portion 32A of the second inner front-surface electrode 32P in the X-direction. The first outer end portion 33A is located closer to the first substrate side surface 23 than the outer element electrode 83P of the edge-emitting element 70 is in the X-direction. In plan view, the first outer end portion 33A opposes the end element electrode 84P of the edge-emitting element 70 in the Y-direction. As viewed in the Y-direction, the first outer end portion 33A overlaps both the second inner wide portion 32B and the second inner inclined portion 32C of the second inner front-surface electrode 32P.

The first outer end portion 33A includes end sides 33H and 331 each extending in the Y-direction in plan view. The end side 33H is one of two opposite end sides of the first outer end portion 33A in the X-direction located closer to the second inner front-surface electrode 32P. The end side 33I is the other one of the two opposite end sides of the first outer end portion 33A in the X-direction located closer to the first substrate side surface 23. The end side 33H is located closer to the center of the substrate front surface 21 in the X-direction than the end side 32G of the second inner front-surface electrode 32P is. The end side 33H is located closer to the first substrate side surface 23 than the end side 32F of the second inner front-surface electrode 32P is. The end side 33H is located closer to the end side 32F than the center of the second inner front-surface electrode 32P between the end side 32F and the end side 32G in the X-direction is. The end side 33I is located closer to the first substrate side surface 23 than the end side 32G of the second inner front-surface electrode 32P is.

The first outer end portion 33A has a greater width (dimension in X-direction) than the first inner narrow portion 31A of the first inner front-surface electrode 31P. The first outer end portion 33A has a greater width than the first inner wide portion 31B of the first inner front-surface electrode 31P. The first outer end portion 33A has a greater width than the second inner wide portion 32B of the second inner front-surface electrode 32P.

The second outer end portion 33B is adjacent to the second inner wide portion 32B of the second inner front-surface electrode 32P in the X-direction. The second outer end portion 33B is located closer to the first substrate side surface 23 than the edge-emitting element 70 is in the X-direction. In an example, the second outer end portion 33B is located closer to the first substrate side surface 23 than the sub-mount substrate 90 is in the X-direction.

The second outer end portion 33B includes end sides 33F and 33G each extending in the Y-direction in plan view. The end side 33F is one of two opposite end sides of the second outer end portion 33B in the X-direction located closer to the second inner front-surface electrode 32P. The end side 33G is the other one of the two opposite end sides of the second outer end portion 33B in the X-direction located closer to the first substrate side surface 23. The end side 33F is located closer to the center of the substrate front surface 21 than the end side 33I of the first outer end portion 33A in the X-direction is. The end side 33F is located closer to the end side 33I than the center of the first outer end portion 33A between the end side 33H and the end side 33I in the X-direction is. The end side 33G is located closer to the first substrate side surface 23 than the end side 33I of the first outer end portion 33A is.

The second outer end portion 33B has a greater width (dimension in X-direction) than the first inner narrow portion 31A of the first inner front-surface electrode 31P. The second outer end portion 33B has a greater width than the first inner wide portion 31B of the first inner front-surface electrode 31P. The second outer end portion 33B has the same width as the second inner wide portion 32B of the second inner front-surface electrode 32P. Accordingly, the second outer end portion 33B has a smaller width than the first outer end portion 33A.

The outer inclined portion 33C is inclined toward the third substrate side surface 25 as the outer inclined portion 33C becomes closer to the first substrate side surface 23. In other words, the outer inclined portion 33C is inclined away from the edge-emitting element 70 as the outer inclined portion 33C becomes closer to the first substrate side surface 23. The outer inclined portion 33C has a smaller width (dimension in a direction orthogonal to inclination direction of the outer inclined portion 33C in plan view) than the first outer end portion 33A. The outer inclined portion 33C has a smaller width than the second outer end portion 33B. The outer inclined portion 33C has a greater width than the second inner inclined portion 32C of the second inner front-surface electrode 32P.

In plan view, the outer inclined portion 33C includes an inclined side 33D located toward the second inner front-surface electrode 32P, and an inclined side 33E located toward the first substrate side surface 23.

The inclined side 33D is adjacent to the inclined side 32D of the second inner front-surface electrode 32P in the X-direction. The inclined side 33D is inclined toward the outer emitter 83A of the edge-emitting element 70 as the inclined side 33D extends from the end side 33F toward the center of the substrate front surface 21 in the X-direction. The inclined side 33D is inclined in the same direction as the inclined side 32D. In plan view, the inclined side 33D is parallel to the inclined side 32D. In an example, the inclined side 33D has the same length as the inclined side 32D.

The inclined side 33E is inclined toward the outer emitter 83A as the inclined side 33E extends from the end side 33G toward the center of the substrate front surface 21 in the X-direction. The inclined side 33E is inclined in the same direction as the inclined side 33D. In plan view, the inclined side 33E is parallel to the inclined side 33D. The inclined side 33E is shorter than the inclined side 33D.

As described above, the outer inclined portion 33C is formed as an inclined region including the inclined side 33D, which extends from the end side 33F toward the center of the substrate front surface 21, and the inclined side 33E, which extends from the end side 33G toward the center of the substrate front surface 21.

In plan view, the outer through-interconnect 53P overlaps both the second outer end portion 33B and the outer inclined portion 33C. In an example, the longitudinal direction of the elliptic outer through-interconnect 53P is parallel to the direction in which the outer inclined portion 33C extends.

In plan view, the end front-surface electrode 34P extends in the Y-direction. As viewed in the Y-direction, the end front-surface electrode 34P overlaps the second outer end portion 33B and the outer inclined portion 33C of the outer front-surface electrode 33P. The end front-surface electrode 34P includes an end narrow portion 34A and an end wide portion 34B having a greater width than the end narrow portion 34A.

In plan view, the end narrow portion 34A opposes the edge-emitting element 70 in the Y-direction. The end narrow portion 34A has a fixed width and extends in the Y-direction. The end narrow portion 34A has a smaller width than the first inner narrow portion 31A of the first inner front-surface electrode 31P. The end narrow portion 34A has a smaller width than the second inner inclined portion 32C of the second inner front-surface electrode 32P. The end narrow portion 34A has the same width as the second inner narrow portion 32A of the second inner front-surface electrode 32P. The length (dimension in Y-direction) of the end narrow portion 34A is greater than the width (dimension in Y-direction) of the edge-emitting element 70.

The end wide portion 34B is located closer to the third substrate side surface 25 than the edge-emitting element 70 is. As viewed in the X-direction, a part of the end wide portion 34B overlaps the outer element electrode 83P.

The end wide portion 34B includes an end side 34C extending in the Y-direction, and an inclined side 34D inclined away from the end emitter 84A of the edge-emitting element 70 as the inclined side 34D extends from the end side 34C toward the first substrate side surface 23.

The end side 34C is adjacent to the end side 33I of the first outer end portion 33A of the outer front-surface electrode 33P in the X-direction. The end side 34C is longer than the end side 33I. As viewed in the Y-direction, the end side 34C is located closer to the first substrate side surface 23 than the end side 33F of the second outer end portion 33B of the outer front-surface electrode 33P is. As viewed in the Y-direction, the end side 34C is located closer to the center of the substrate front surface 21 than the end side 33G of the second outer end portion 33B in the X-direction is.

The inclined side 34D is inclined toward the emitter 80A, which corresponds to the end element electrode 84P, as the inclined side 34D becomes closer to the center of the substrate front surface 21 in the X-direction. The inclined side 34D is adjacent to the inclined side 33E of the outer inclined portion 33C of the outer front-surface electrode 33P in the X-direction. The inclined side 34D is shorter than the inclined side 33E.

In plan view, the end through-interconnect 54P overlaps the end wide portion 34B. In an example, the end through-interconnect 54P is arranged on the end wide portion 34B at a position located toward the first substrate side surface 23.

### Detailed Wire Connection Configuration

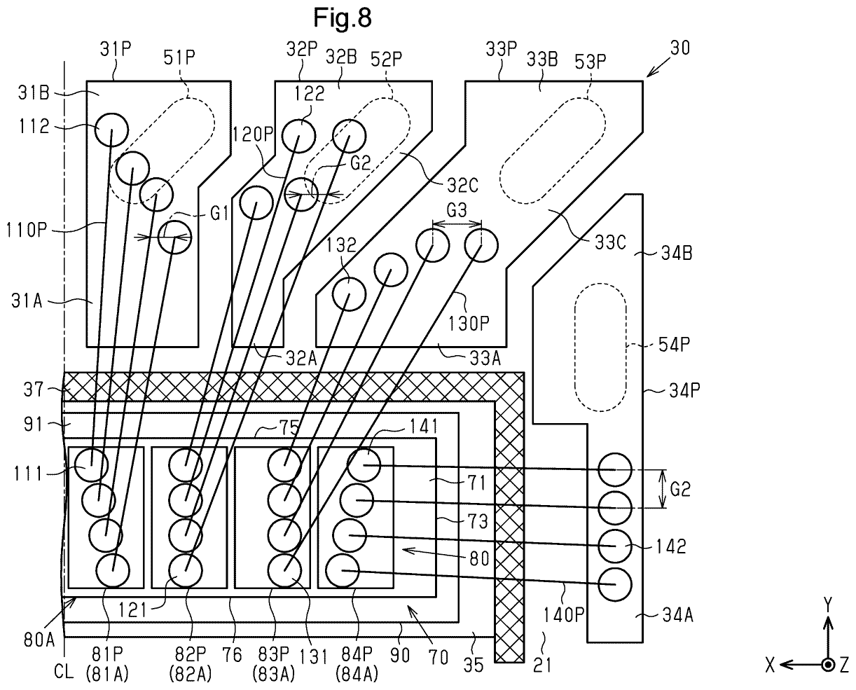

The detailed connection configuration of the first inner front-surface electrodes 31P and 31Q and the first inner wires 110P and 110Q, the second inner front-surface electrodes 32P and 32Q and the second inner wires 120P and 120Q, the outer front-surface electrodes 33P and 33Q and the outer wires 130P and 130Q, and the end front-surface electrodes 34P and 34Q and the ends wires 140P and 140Q will now be described. FIG. 8 is an enlarged plan view of the first inner wires 110P, the second inner wires 120P, the outer wires 130P, and the end wires 140P. As described above, the first inner wires 110Q, the second inner wires 120Q, the outer wires 130Q, and the end wires 140Q are symmetric to the first inner wires 110P, the second inner wires 120P, the outer wires 130P, and the end wires 140P with respect to the imaginary center line CL. Thus, these components will not be described in detail.

As shown in FIG. 8, in plan view, the first inner wires 110P are spaced apart from each other in the X-direction. Each of the first inner wires 110P includes an element-side bonding point 111 bonded to the first inner element electrode 81P of the edge-emitting element 70, and a substrate-side bonding point 112 bonded to the first inner front-surface electrode 31P. In FIG. 8, to simplify illustration, the element-side bonding points 111 and the substrate-side bonding points 112 of the first inner wires 110P are both depicted as circles. The same applies to the other drawings and the other wires described hereafter.

The element-side bonding points 111 are arranged on the first inner element electrode 81P in the Y-direction. As viewed in the Y-direction, the element-side bonding points 111 overlap each other. As viewed in the Y-direction, the element-side bonding points 111 are partially offset from each other. One of the element-side bonding points 111 located closest to the third substrate side surface 25 (first inner front-surface electrode 31P) is arranged on the first inner element electrode 81P at a position closest to the imaginary center line CL (center of substrate front surface 21 in X-direction). One of the element-side bonding points 111 located farthest from the third substrate side surface 25 (first inner front-surface electrode 31P) is arranged on the first inner element electrode 81P at a position farthest from the imaginary center line CL (center of substrate front surface 21 in X-direction). In this manner, in plan view, the element-side bonding points 111 are inclined toward the third substrate side surface 25 (first inner front-surface electrode 31P) as the element-side bonding points 111 become closer to the imaginary center line CL (center of substrate front surface 21 in X-direction). The arrangement of the element-side bonding points 111 on the first inner element electrode 81P may be changed.

In plan view, the substrate-side bonding points 112 are arranged on the first inner front-surface electrode 31P in a direction intersecting both the X-direction and the Y-direction. The substrate-side bonding points 112 are inclined away from the edge-emitting element 70 as the substrate-side bonding points 112 become closer to the imaginary center line CL (center of substrate front surface 21 in X-direction). As viewed in the Y-direction, two adjacent ones of the substrate-side bonding points 112 partially overlap each other. Two of the substrate-side bonding points 112 located toward the first substrate side surface 23 are located closer to the first substrate side surface 23 than the first inner element electrode 81P is in the X-direction. Thus, in plan view, a distance between adjacent ones of the first inner wires 110P in the X-direction increases as the first inner wires 110P become farther away from the first inner element electrode 81P. The distance between adjacent ones of the first inner wires 110P in the X-direction may be defined by an interval between adjacent ones of the first inner wires 110P in the X-direction.

Two of the substrate-side bonding points 112 located toward the imaginary center line CL are formed in the first inner wide portion 31B of the first inner front-surface electrode 31P. Two of the substrate-side bonding points 112 located toward the first substrate side surface 23 are formed in the first inner narrow portion 31A. More specifically, the two of the substrate-side bonding points 112 located toward the first substrate side surface 23 are located closer to the first substrate side surface 23 (second inner front-surface electrode 32P) than the center of the first inner narrow portion 31A in the X-direction is. Further, the two of the substrate-side bonding points 112 located toward the first substrate side surface 23 are located closer to the first inner wide portion 31B than the center of the first inner narrow portion 31A in the Y-direction is. The arrangement of the substrate-side bonding points 112 on the first inner front-surface electrode 31P may be changed.

In an example, in plan view, the first inner wires 110P have the same length. It is considered that the first inner wires 110P have the same length as long as a difference in length between the first inner wires 110P is, for example, within 10% of the length of a predetermined first inner wire 110P. The predetermined first inner wire 110P may be, for example, the first inner wire 110P located closest to the imaginary center line CL.

In plan view, the second inner wires 120P are spaced apart from each other in the X-direction. In plan view, the second inner wires 120P are substantially parallel to each other. Each of the second inner wires 120P includes an element-side bonding point 121 bonded to the second inner element electrode 82P of the edge-emitting element 70, and a substrate-side bonding point 122 bonded to the second inner front-surface electrode 32P.

The element-side bonding points 121 are arranged next to each other in the Y-direction in a state aligned in the same position in the X-direction. In an example, the element-side bonding points 121 are located at the center of the second inner element electrode 82P in the X-direction. The arrangement of the element-side bonding points 121 on the second inner element electrode 82P may be changed.

The substrate-side bonding points 122 are formed on a part of the second inner front-surface electrode 32P located farther from the edge-emitting element 70 (second inner emitter 82A) than the center of the second inner front-surface electrode 32P in the Y-direction is. Two of the substrate-side bonding points 122 are arranged on the second inner inclined portion 32C, and the remaining two of the substrate-side bonding points 122 are arranged on the second inner wide portion 32B. Two adjacent ones of the substrate-side bonding points 122 are arranged on the second inner inclined portion 32C and the second inner wide portion 32B, respectively. That is, the substrate-side bonding points 122 are alternately arranged on the second inner inclined portion 32C and the second inner wide portion 32B. In an example, a distance between the two substrate-side bonding points 122 arranged on the second inner inclined portion 32C in the X-direction is less than the diameter of the substrate-side bonding points 122. In an example, a distance between the two substrate-side bonding points 122 arranged on the second inner wide portion 32B in the X-direction is less than the diameter of the substrate-side bonding points 122.

Also, the substrate-side bonding points 122 are located closer to the first substrate side surface 23 than the element-side bonding points 121 are in the X-direction. The substrate-side bonding points 122 are located closer to the first substrate side surface 23 than the second inner element electrode 82P is in the X-direction.

In this manner, two adjacent ones of the substrate-side bonding points 122 in the X-direction are located at different positions in the Y-direction. Accordingly, in plan view, the two adjacent ones of the second inner wires 120P in the X-direction have different lengths. In plan view, the second inner wires 120P may all have different lengths. In plan view, an angle at which the second inner wires 120P are inclined with respect to the Y-direction is greater than that of the first inner wires 110P with respect to the Y-direction. The arrangement of the substrate-side bonding points 122 on the second inner front-surface electrode 32P may be changed.

In plan view, the outer wires 130P are spaced apart from each other in the X-direction. Each of the outer wires 130P includes an element-side bonding point 131 bonded to the outer element electrode 83P of the edge-emitting element 70, and a substrate-side bonding point 132 bonded to the outer front-surface electrode 33P.

The element-side bonding points 131 are arranged next to each other in the Y-direction in a state aligned in the same position in the X-direction. In an example, the element-side bonding points 131 are arranged on the outer element electrode 83P at a position located toward the end element electrode 84P. In other words, in plan view, the element-side bonding points 131 are located toward the outer front-surface electrode 33P. The arrangement of the element-side bonding points 131 on the outer element electrode 83P may be changed.

The substrate-side bonding points 132 are located closer to the edge-emitting element 70 (outer emitter 83A) than the center of the outer front-surface electrode 33P in the Y-direction is. Also, the substrate-side bonding points 132 are located closer to the first substrate side surface 23 than the element-side bonding points 131 are. The substrate-side bonding points 132 are located closer to the first substrate side surface 23 than the outer element electrode 83P is.

Two of the substrate-side bonding points 132 located toward the imaginary center line CL (center of substrate front surface 21 in X-direction) in the X-direction are located closer to the edge-emitting element 70 than the remaining two of the substrate-side bonding points 132 are in the Y-direction. As viewed in the Y-direction, the two of the substrate-side bonding points 132 located toward the imaginary center line CL (center of substrate front surface 21 in X-direction) in the X-direction partially overlap each other. Furthermore, as viewed in the X-direction, the two of the substrate-side bonding points 132 located toward the imaginary center line CL (center of substrate front surface 21 in X-direction) in the X-direction partially overlap each other. One of the substrate-side bonding points 132 located closest to the imaginary center line CL is located closer to the edge-emitting element 70 than the remaining three of the substrate-side bonding points 132 are in the Y-direction.

Two of the substrate-side bonding points 132 located toward the first substrate side surface 23 in the X-direction are spaced apart from each other in the X-direction in a state aligned in the same position in the Y-direction. The two of the substrate-side bonding points 132 located toward the first substrate side surface 23 in the X-direction are arranged on the outer inclined portion 33C. The two of the substrate-side bonding points 132 located toward the first substrate side surface 23 in the X-direction are separated from each other by a greater distance than that of the two middle ones of the substrate-side bonding points 132 in the X-direction.

With this arrangement of the substrate-side bonding points 132, in plan view, the length of the outer wires 130P increases from the imaginary center line CL toward the first substrate side surface 23. That is, the outer wires 130P include wires having different lengths. In other words, the outer wires 130P have different lengths.

In plan view, the shortest one of the outer wires 130P is shorter than the shortest one of the first inner wires 110P. In plan view, the second shortest one of the outer wires 130P is shorter than the shortest one of the first inner wires 110P. In plan view, the third shortest one of the outer wires 130P has the same length as the shortest one of the first inner wires 110P. In plan view, the longest one of the outer wires 130P is longer than the shortest one of the first inner wires 110P. In plan view, the longest one of the outer wires 130P is longer than the longest one of the first inner wires 110P. In an example, the total length of the outer wires 130P in plan view is less than the total length of the first inner wires 110P in plan view. The outer wires 130P and the first inner wires 110P are equal in number. Therefore, the average length of the outer wires 130P in plan view is less than the average length of the first inner wires 110P in plan view.

The relationship between the average length of the outer wires 130P in plan view and the average length of the first inner wires 110P in plan view may be changed. For example, the arrangement of the substrate-side bonding points 112 of the first inner wires 110P may be adjusted so that the average length of the outer wires 130P in plan view is substantially the same as the average length of the first inner wires 110P in plan view.

In plan view, the shortest one of the outer wires 130P is shorter than the shortest one of the second inner wires 120P. In plan view, the second shortest one of the outer wires 130P is shorter than the shortest one of the second inner wires 120P. In plan view, the third shortest one of the outer wires 130P is longer than the shortest one of the second inner wires 120P. In contrast, in plan view, the third shortest one of the outer wires 130P is shorter than the second shortest one of the second inner wires 120P. In plan view, the longest one of the outer wires 130P is longer than the second shortest one of the second inner wires 120P. In plan view, the longest one of the outer wires 130P has the same length as the third shortest one of the second inner wires 120P. Accordingly, in plan view, the longest one of the outer wires 130P is shorter than the longest one of the second inner wires 120P. In an example, the total length of the outer wires 130P in plan view is less than the total length of the second inner wires 120P in plan view. The outer wires 130P and the second inner wires 120P are equal in number. Therefore, the average length of the outer wires 130P in plan view is less than the average length of the second inner wires 120P in plan view.

The relationship between the average length of the outer wires 130P in plan view and the average length of the second inner wires 120P in plan view may be changed. For example, the arrangement of the substrate-side bonding points 122 of the second inner wires 120P may be adjusted so that the average length of the outer wires 130P in plan view is substantially the same as the average length of the second inner wires 120P in plan view.

The element-side bonding points 131 are aligned with each other at the same position in the X-direction, and the substrate-side bonding points 132 are spaced apart from each other in the X-direction. Therefore, in plan view, the distance between adjacent ones of the outer wires 130P increases from the element-side bonding points 131 toward the substrate-side bonding points 132.

In plan view, a largest distance G3 between adjacent ones of the outer wires 130P is greater than a largest distance G1 between adjacent ones of the first inner wires 110P. In plan view, the largest distance G3 is greater than a largest distance G2 between adjacent ones of the second inner wires 120P. In plan view, the largest distance G3 is greater than a largest distance G4 between adjacent ones of the end wires 140P.

The largest distance G3 may be defined by a largest value of a distance between two adjacent ones of the outer wires 130P in the X-direction. In the example shown in FIG. 8, in plan view, the largest distance G3 is the distance between the centers of the substrate-side bonding points 132 of two of the outer wires 130P located toward the first substrate side surface 23.

The largest distance G1 may be defined by a largest value of a distance between two adjacent ones of the first inner wires 110P in the X-direction. In the example shown in FIG. 8, in plan view, the largest distance G1 is the largest value of the distance between two of the second inner wires 120P located toward the first substrate side surface 23 in the X-direction.

The largest distance G2 may be defined by a largest value of a distance between two adjacent ones of the second inner wires 120P in the X-direction. In the example shown in FIG. 8, in plan view, the largest distance G2 is the largest value of the distance between the two middle ones of the second inner wires 120P in the X-direction.

The largest distance G4 may be defined by a largest value of a distance between two adjacent ones of the end wires 140P in the Y-direction. In the example shown in FIG. 8, the distance between two adjacent ones of the end wires 140P in the Y-direction is uniform. Therefore, the largest distance G4 may be the distance between any two adjacent ones of the end wires 140P in the Y-direction.

In plan view, the end wires 140P are spaced apart from each other in the Y-direction. In plan view, the end wires 140P are substantially parallel to each other. Each of the end wires 140P includes an element-side bonding point 141 bonded to the end element electrode 84P of the edge-emitting element 70, and a substrate-side bonding point 142 bonded to the end front-surface electrode 34P.

The element-side bonding points 141 are arranged on the end element electrode 84P in the Y-direction. As viewed in the Y-direction, the element-side bonding points 141 overlap each other. As viewed in the Y-direction, the element-side bonding points 141 are partially offset from each other. One of the element-side bonding points 141 located closest to the third substrate side surface 25 is arranged on the end element electrode 84P at a position located farthest from the imaginary center line CL (center of substrate front surface 21 in X-direction). One of the element-side bonding points 141 located farthest from the third substrate side surface 25 is arranged on the end element electrode 84P at a position located closest to the imaginary center line CL (center of substrate front surface 21 in X-direction). In this manner, in plan view, the element-side bonding points 141 are inclined toward the fourth substrate side surface 26 as the element-side bonding points 141 become closer to the imaginary center line CL (center of substrate front surface 21 in X-direction). The arrangement of the element-side bonding points 141 on the end element electrode 84P may be changed.

The substrate-side bonding points 142 are bonded to the end narrow portion 34A of the end front-surface electrode 34P. The substrate-side bonding points 142 are arranged next to each other in the Y-direction in a state aligned in the same position in the X-direction. The width of the end narrow portion 34A is slightly greater than the diameter of the substrate-side bonding points 142. In an example, the width of the end narrow portion 34A is greater than the diameter of the substrate-side bonding points 142 and is less than or equal to twice the diameter of the substrate-side bonding points 142.

The element-side bonding points 141 are located at different positions in the X-direction. Accordingly, in plan view, the end wires 140P have different lengths. The lengths of the end wires 140P may be changed. For example, the end wires 140P may have the same length.

In plan view, the shortest one of the outer wires 130P is shorter than the shortest one of the end wires 140P. In plan view, the second shortest one of the outer wires 130P has the same length as the shortest one of the end wires 140P. In plan view, the second shortest one of the outer wires 130P is shorter than the second shortest one of the end wires 140P. In plan view, the third shortest one of the outer wires 130P is longer than the longest one of the end wires 140P. Accordingly, in plan view, the longest one of the outer wires 130P is longer than the longest one of the end wires 140P. In an example, the total length of the outer wires 130P in plan view is greater than the total length of the end wires 140P in plan view. The outer wires 130P and the end wires 140P are equal in number. Therefore, the average length of the outer wires 130P in plan view is greater than the average length of the end wires 140P in plan view. In other words, the average length of the end wires 140P in plan view is less than the average length of the first inner wires 110P in plan view or the average length of the second inner wires 120P in plan view.

### Operation

The operation of the semiconductor light emitting device 10 of the present embodiment will now be described.

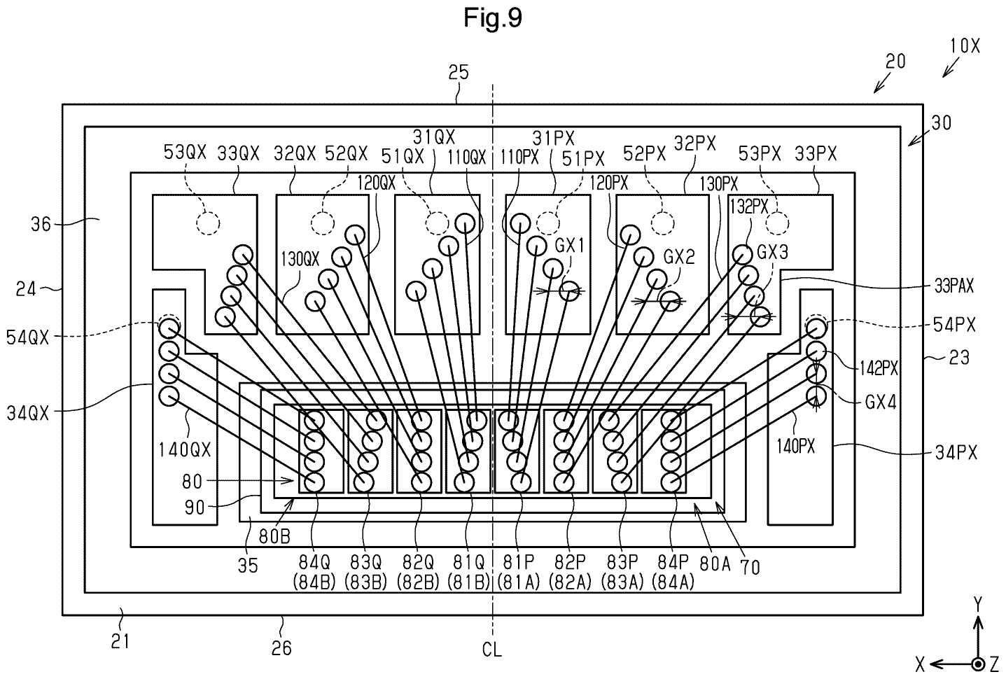

FIG. 9 is a schematic plan view showing the internal structure of a semiconductor light emitting device 10X of a comparative example. The semiconductor light emitting device 10X of the comparative example includes the substrate 20, the edge-emitting element 70, and the sub-mount substrate 90 that are the same as those of the first embodiment. The semiconductor light emitting device 10X differs from the first embodiment in the configurations of the front-surface electrodes and the wires. Hereafter, the front-surface electrodes of the semiconductor light emitting device 10X of the comparative example will be referred to as “first inner front-surface electrodes 31PX and 31QX”, “second inner front-surface electrodes 32PX and 32QX”, “outer front-surface electrodes 33PX and 33QX”, and “end front-surface electrodes 34PX and 34QX”. Also, the wires of the semiconductor light emitting device 10X of the comparative example will be referred to as “first inner wires 110PX and 110QX”, “second inner wires 120PX and 120QX”, “outer wires 130PX and 130QX”, and “end wires 140PX and 140QX”.

In the semiconductor light emitting device 10X of the comparative example, the front-surface electrodes and the wires are symmetric with respect to the imaginary center line CL, in the same manner as the first embodiment. Accordingly, the first inner front-surface electrode 31PX, the second inner front-surface electrode 32PX, the outer front-surface electrode 33PX, the end front-surface electrode 34PX, the first inner wires 110PX, the second inner wires 120PX, the outer wires 130PX, and the end wires 140PX will be described, and the first inner front-surface electrode 31QX, the second inner front-surface electrode 32QX, the outer front-surface electrode 33QX, the end front-surface electrode 34QX, the first inner wires 110QX, the second inner wires 120QX, the outer wires 130QX, and the end wires 140QX will not be described.

In the semiconductor light emitting device 10X of the comparative example, the through-interconnects are circular in plan view. The through-interconnects of the semiconductor light emitting device 10X of the comparative example will be referred to as “first inner through-interconnects 51PX and 51QX”, “second inner through-interconnects 52PX and 52QX”, “outer through-interconnects 53PX and 53QX”, and “end through-interconnects 54PX and 54QX”. These through-interconnects will not be described in detail.

As shown in FIG. 9, the first inner front-surface electrode 31PX, the second inner front-surface electrode 32PX, and the outer front-surface electrode 33PX are arranged in this order in the X-direction from the center of the substrate front surface 21 toward the first substrate side surface 23. The first inner front-surface electrode 31PX and the second inner front-surface electrode 32PX are both rectangular in plan view, with long sides extending in the Y-direction and short sides extending in the X-direction. In plan view, the first inner front-surface electrode 31PX overlaps the first inner element electrode 81P and the second inner element electrode 82P of the edge-emitting element 70 with respect to the X-direction. The second inner front-surface electrode 32PX overlaps the outer element electrode 83P and the end element electrode 84P of the edge-emitting element 70 with respect to the X-direction. The outer front-surface electrode 33PX is located closer to the first substrate side surface 23 than the edge-emitting element 70 is.

Accordingly, the distance from the outer element electrode 83P to the outer front-surface electrode 33PX is greater than the distance from the first inner element electrode 81P to the first inner front-surface electrodes 31PX or the distance from the second inner element electrode 82P to the second inner front-surface electrode 32PX. That is, in plan view, the outer wires 130PX are likely to be longer than the first inner wires 110PX or the second inner wires 120PX. Furthermore, the outer front-surface electrode 33PX includes the outer narrow portion 33PAX. Some of the substrate-side bonding points 132PX of the outer wires 130PX are arranged on the outer narrow portion 33PAX. In this manner, the relatively long outer wires 130PX are bonded to the relatively narrow portion of the outer front-surface electrode 33PX. This increases the resistance component of the conductive path between the outer element electrode 83P and the outer through-interconnect 53PX.

The substrate-side bonding points 142PX of the end wires 140PX are arranged on the relatively wide portion of the end front-surface electrode 34PX that is located toward the end through-interconnect 54PX. This decreases the resistance component of the conductive path between the end element electrode 84P and the end through-interconnect 54PX.

In plan view, the largest distance GX3 between adjacent ones of the outer wires 130PX in the X-direction is less than or equal to the largest distance GX1 between adjacent ones of the first inner wires 110PX in the X-direction. The largest distance GX3 is less than or equal to the largest distance GX2 between adjacent ones of the second inner wires 120PX in the X-direction. The largest distance GX3 is less than or equal to the largest distance GX4 between adjacent ones of the end wires 140PX in the X-direction.

In plan view, the largest distance GX1 is the largest value of the distance between one of the first inner wires 110PX located closest to the first substrate side surface 23 and one of the first inner wires 110PX located second closest to the first substrate side surface 23 in the X-direction. In plan view, the largest distance GX2 is the largest value of the distance between one of the second inner wires 120PX located closest to the first substrate side surface 23 and one of the second inner wires 120PX located second closest to the first substrate side surface 23 in the X-direction. In plan view, the largest distance GX3 is the largest value of the distance between one of the outer wires 130P located closest to the center of the substrate front surface 21 and one of the outer wires 130P located second closest to the center of the substrate front surface 21 in the X-direction. In plan view, the largest distance GX4 is the largest value of the distance between one of the end wires 140PX located closest to the third substrate side surface 25 and one of the end wires 140P located second closest to the third substrate side surface 25 in the Y-direction.

As described above, the semiconductor light emitting device 10X of the comparative example has relatively large differences in the resistance components of the conductive path between the outer element electrode 83P and the outer through-interconnect 53PX (“comparative outer conductive path”), the conductive path between the first inner element electrode 81P and the first inner through-interconnect 51PX (“comparative first inner conductive path”), the conductive path between the second inner element electrode 82P and the second inner through-interconnect 52PX (“comparative second inner conductive path”), and the conductive path between the end element electrode 84P and the end through-interconnect 54PX (“comparative end conductive path”).

An example of simulated resistance components of the conductive paths will now be described. In this simulation example, the semiconductor light emitting device 10X of the comparative example was driven at 10 MHz and 100 MHz.

In a case in which the resistance component of the comparative outer conductive path when the semiconductor light emitting device 10X of the comparative example was driven at 10 MHz is defined as 100%, the resistance component of the comparative first inner conductive path was 81%, the resistance component of the comparative second inner conductive path was 87%, and the resistance component of the comparative end conductive path was 80%. When the semiconductor light emitting device 10X of the comparative example was driven at 100 MHz, the resistance components of the conductive paths were the same as those when the semiconductor light emitting device 10X of the comparative example was driven at 10 MHz. That is, the difference in the resistance components of the comparative outer conductive path, the comparative first inner conductive path, the comparative second inner conductive path, and the comparative end conductive path was 20%, at most.

A resistance component of a conductive path includes a resistance of the conductive path and a resistance component of the conductive path resulting from inductance. The resistance components of the conductive paths, including the wires 100, may be adjusted by the number of wires 100, the lengths of the wires 100, the distance between two adjacent wires 100, or the like. Typically, when the number of wires 100 is decreased, the resistance of the conductive path increases. When the number of wires 100 is increased, the resistance of the conductive path decreases. Also, when the length of the wires 100 is increased, the resistance component of the conductive path increases. When the length of the wires 100 is decreased, the resistance component of the conductive path decreases. The length of the wires 100 may be adjusted by the wire height, the bonding position, or the like. When the distance between two adjacent wires 100 is increased, the mutual inductance of the wires 100 decreases. Accordingly, the resistance component of the conductive path is reduced. When the distance between two adjacent wires 100 is decreased, the mutual inductance of the wires 100 increases. Accordingly, the resistance component of the conductive path is increased. In this manner, the differences in the resistance components of the conductive paths may be reduced by adjusting the number of wires 100, the length of the wires 100, the distance between wires 100, or a combination of the above.

In the semiconductor light emitting device 10 of the first embodiment, in plan view, the largest distance G3 between adjacent ones of the outer wires 130P is greater than each of the largest distance G1 between adjacent ones of the first inner wires 110P, the largest distance G2 between adjacent ones of the second inner wires 120P, and the largest distance G4 between adjacent ones of the end wires 140P.

The outer front-surface electrode 33P includes the first outer end portion 33A having a greater width (dimension in X-direction) than the second inner narrow portion 32A of the second inner front-surface electrode 32P, and the substrate-side bonding point 142 of the outer wires 130P are arranged on the first outer end portion 33A. The first outer end portion 33A is located closer to the outer element electrode 83P, as compared to the outer front-surface electrode 33PX of the semiconductor light emitting device 10X of the comparative example. As a result, the conductive path extending from the outer element electrode 83P to the outer through-interconnect 53P (“outer conductive path of the first embodiment”) is likely to have a smaller resistance component than the semiconductor light emitting device 10X of the comparative example.

The substrate-side bonding points 112 of two of the first inner wires 110P are arranged on the first inner narrow portion 31A of the first inner front-surface electrode 31P. Three of the first inner wires 110P are arranged on the first inner front-surface electrode 31P at a position located farther from the edge-emitting element 70 (toward third substrate side surface 25) than the center of the first inner front-surface electrode 31P in the Y-direction is. Thus, the first inner wires 110P are increased in length, and some of the first inner wires 110P are bonded to the relatively narrow portion of the first inner front-surface electrode 31P. As a result, the conductive path extending from the first inner element electrode 81P to the first inner through-interconnect 51P (“first inner conductive path of the first embodiment”) is likely to have a greater resistance component than the semiconductor light emitting device 10X of the comparative example.

The second inner wires 120P are arranged on the second inner front-surface electrode 32P at a position located away from the edge-emitting element 70 (toward third substrate side surface 25) than the center of the second inner front-surface electrode 32P in the Y-direction is. The largest distance G2 between adjacent ones of the second inner wires 120P is smaller than the largest distance GX2 between adjacent ones of the second inner wires 120PX in the semiconductor light emitting device 10X of the comparative example. As a result, the conductive path extending from the second inner element electrode 82P to the second inner through-interconnect 52P (“second inner conductive path of the first embodiment”) is likely to have a greater resistance component than the semiconductor light emitting device 10X of the comparative example.

The substrate-side bonding points 142 of the end wires 140P are arranged on the end narrow portion 34A of the end front-surface electrode 34P. This increases the lengths of the end wires 140P and the resistance of the end narrow portion 34A, as compared to the end wires 140PX of the semiconductor light emitting device 10X of the comparative example. As a result, the conductive path extending from the end element electrode 84P to the end through-interconnect 54P (“end conductive path of the first embodiment”) is likely to have a greater resistance component than the semiconductor light emitting device 10X of the comparative example.

In this manner, the resistance component of the outer conductive path of the first embodiment is decreased, and the resistance components of the first inner conductive path, the second inner conductive path, and the end conductive path of the first embodiment are increased. This reduces the differences in resistance components of the outer conductive path, the first inner conductive path, the second inner conductive path, and the end conductive path of the first embodiment.

Another example of simulated resistance components of the conductive paths will now be described. In this simulation example, the semiconductor light emitting device 10 of the first embodiment was driven at 10 MHz and 100 MHz.

In a case in which the resistance component of the outer conductive path of the first embodiment when the semiconductor light emitting device 10 of the first embodiment was driven at 10 MHz is defined as 100%, the resistance component of the first inner conductive path of the first embodiment was 95%, the resistance component of the second inner conductive path of the first embodiment was 99%, and the resistance component of the end conductive path of the first embodiment was 92%. In a case in which the resistance component of the outer conductive path of the first embodiment when the semiconductor light emitting device 10 of the first embodiment was driven at 100 MHz is defined as 100%, the resistance component of the first inner conductive path of the first embodiment was 94%, the resistance component of the second inner conductive path of the first embodiment was 98%, and the resistance component of the end conductive path of the first embodiment was 91%. In this manner, the difference in the resistance components of the outer conductive path, the first inner conductive path, the second inner conductive path, and the end conductive path of the first embodiment may be less than 10%.

### Advantages

The semiconductor light emitting device 10 of the present embodiment has the following advantages. The advantages will be described using the first inner element electrode 81P, the second inner element electrode 82P, the outer element electrode 83P, and the end element electrode 84P of the edge-emitting element 70, the first inner front-surface electrode 31P, the second inner front-surface electrode 32P, the outer front-surface electrode 33P, the end front-surface electrode 34P, the first inner wires 110P, the second inner wires 120P, the outer wires 130P, and the end wires 140P. Nonetheless, the same advantages may also be obtained by the first inner element electrode 81Q, the second inner element electrode 82Q, the outer element electrode 83Q, and the end element electrode 84Q of the edge-emitting element 70, the first inner front-surface electrode 31Q, the second inner front-surface electrode 32Q, the outer front-surface electrode 33Q, the end front-surface electrode 34Q, the first inner wires 110Q, the second inner wires 120Q, the outer wires 130Q, and the end wires 140Q.

(1-1) The semiconductor light emitting device 10 includes the substrate 20, the edge-emitting element 70, the front-surface electrodes 30, and the wires 100. The substrate 20 includes the substrate front surface 21 and the substrate back surface 22. The edge-emitting element 70 is disposed on the substrate 20 and includes the emitters 80A arranged next to each other in the X-direction (first direction) in plan view. The front-surface electrodes 30 are formed on the substrate front surface 21 and are spaced apart from each other. The wires 100 electrically connect the emitters 80A to the front-surface electrodes 30. The emitters 80A include the first inner emitter 81A including the first inner element electrode 81P, and the outer emitter 83A including the outer element electrode 83P. The front-surface electrodes 30 include the first inner front-surface electrode 31P electrically connected to the first inner element electrode 81P, and the outer front-surface electrode 33P electrically connected to the outer element electrode 83P. The wires 100 include the first inner wires 110P electrically connecting the first inner element electrode 81P to the first inner front-surface electrode 31P, and the outer wires 130P electrically connecting the outer element electrode 83P to the outer front-surface electrode 33P. In plan view, the largest distance G3 between adjacent ones of the outer wires 130P in the X-direction is greater than the largest distance G1 between adjacent ones of the first inner wires 110P in the X-direction.

With this configuration, the largest distance G3 between adjacent ones of the outer wires 130P in the X-direction is relatively large so that the resistance component of the outer wires 130P may be relatively small. This reduces the difference in the resistance components between the conductive path extending from the outer element electrode 83P through the outer wires 130P to the outer front-surface electrode 33P and the conductive path extending from the first inner element electrode 81P through the first inner wires 110P to the first inner front-surface electrode 31P. As a result, when voltage is applied to the edge-emitting element 70, light emitted from the edge-emitting element 70 has reduced pulse width variation.

(1-2) The semiconductor light emitting device 10 includes the substrate 20, the edge-emitting element 70, the front-surface electrodes 30, and the wires 100. The substrate 20 includes the substrate front surface 21 and the substrate back surface 22. The edge-emitting element 70 is disposed on the substrate 20 and includes the emitters 80A arranged next to each other in the X-direction (first direction) in plan view. The front-surface electrodes 30 are formed on the substrate front surface 21 and are spaced apart from each other. The wires 100 electrically connect the emitters 80A to the front-surface electrodes 30. The emitters 80A include the second inner emitter 82A including the second inner element electrode 82P, and the outer emitter 83A including the outer element electrode 83P. The front-surface electrodes 30 include the second inner front-surface electrode 32P electrically connected to the second inner element electrode 82P, and the outer front-surface electrode 33P electrically connected to the outer element electrode 83P. The wires 100 include the second inner wires 120P electrically connecting the second inner element electrode 82P to the second inner front-surface electrode 32P, and the outer wires 130P electrically connecting the outer element electrode 83P to the outer front-surface electrode 33P. In plan view, the largest distance G3 between adjacent ones of the outer wires 130P in the X-direction is greater than the largest distance G2 between adjacent ones of the second inner wires 120P in the X-direction. This configuration also obtains the above-described advantage (1-1).

(1-3) The outer front-surface electrode 33P includes the end sides 33F and 33G, the inclined sides 33D and 33E, and the outer inclined portion 33C. The end sides 33F and 33G extend in the Y-direction (second direction). The inclined sides 33D and 33E are inclined toward the outer emitter 83A as the inclined sides 33D and 33E respectively extend from the end sides 33F and 33G toward the center of the substrate front surface 21 in the X-direction. The outer inclined portion 33C includes the inclined sides 33D and 33E. The outer inclined portion 33C extends from the end sides 33F and 33G toward the center of the substrate front surface 21. The outer wires 130P are bonded to the outer inclined portion 33C.

With this configuration, the outer inclined portion 33C is located toward the outer emitter 83A so that the outer wires 130P bonded to the outer inclined portion 33C may be located toward the outer element electrode 83P in the X-direction. This decreases the lengths of the outer wires 130P bonded to the outer inclined portion 33C, thereby reducing the resistance component resulting from the lengths of the outer wires 130P.

(1-4) The outer wires 130P are joined to a part of the outer inclined portion 33C located toward the outer emitter 83A. Some of the first inner wires 110P are bonded to a part of the first inner front-surface electrode 31P located farther from the first inner emitter 81A than the center of the first inner front-surface electrode 31P in the Y-direction is.

This configuration decreases the lengths of the outer wires 130P, thereby reducing the resistance component resulting from the lengths of the outer wires 130P. In contrast, the lengths of the first inner wires 110P are increased, thereby increasing the resistance component resulting from the lengths of the first inner wires 110P. This reduces the difference in the resistance components of the outer wires 130P and the first inner wires 110P.

Some of the second inner wires 120P are bonded to a part of the second inner front-surface electrode 32P located farther from the second inner emitter 82A than the center of the second inner front-surface electrode 32P in the Y-direction is. This increases the lengths of the second inner wires 120P, thereby increasing the resistance component (inductance) resulting from the lengths of the second inner wires 120P. As a result, the difference in the resistance components of the outer wires 130P and the second inner wires 120P is reduced.

(1-5) The outer front-surface electrode 33P includes the first outer end portion 33A having a greater width in the X-direction than the outer inclined portion 33C. The first outer end portion 33A is an end of the outer front-surface electrode 33P located closer to the outer emitter 83A than the outer inclined portion 33C is. One or more of the outer wires 130P are joined to the first outer end portion 33A. This configuration decreases the lengths of the outer wires 130P bonded to the first outer end portion 33A, thereby reducing the resistance component resulting from the lengths of the outer wires 130P.

(1-6) The outer front-surface electrode 33P is located closer to the end of the substrate front surface 21 than the first inner front-surface electrode 31P is in the X-direction. The second inner front-surface electrode 32P includes the second inner narrow portion 32A and the second inner inclined portion 32C. The second inner narrow portion 32A is located toward the second inner emitter 82A. The second inner inclined portion 32C is adjacent to the outer inclined portion 33C of the outer front-surface electrode 33P in the X-direction. The second inner inclined portion 32C is inclined toward the second inner emitter 82A as the second inner inclined portion 32C becomes closer to the center of the substrate front surface 21 in the X-direction. Some of the second inner wires 120P are joined to the second inner inclined portion 32C. This configuration increases the lengths of the second inner wires 120P, thereby reducing the resistance component resulting from the lengths of the second inner wires 120P.

(1-7) As viewed in the Y-direction, one or more of the outer wires 130P partially overlap the second inner wires 120P.

With this configuration, the outer wires 130P may be located toward the center of the substrate front surface 21 in the X-direction. Accordingly, the substrate-side bonding points 132 of the outer wires 130P may be located toward the outer element electrode 83P in the X-direction. This decreases the lengths of the outer wires 130P, thereby reducing the resistance component resulting from the lengths of the outer wires 130P.

(1-8) The emitters 80A include the end emitter 84A located at an end of the edge-emitting element 70 in the X-direction. The end emitter 84A includes the end element electrode 84P. The front-surface electrodes 30 include the end front-surface electrode 34P arranged on an end of the substrate front surface 21 in the X-direction. The wires 100 include the end wires 140P electrically connecting the end element electrode 84P to the end front-surface electrode 34P. The end front-surface electrode 34P includes the end wide portion 34B and the end narrow portion 34A. The end wires 140P are bonded to the end narrow portion 34A.

With this configuration, the end wires 140P are bonded to the relatively narrow portion of the end front-surface electrode 34P, thereby increasing the resistance component at the bonding portion. This reduces the difference in the resistance components of the end wires 140P and the outer wires 130P.

(1-9) The end front-surface electrode 34P is located closer to the end of the substrate front surface 21 than the edge-emitting element 70 is in the X-direction. As viewed in the X-direction, the end front-surface electrode 34P overlaps the end element electrode 84P. The outer front-surface electrode 33P includes a part located closer to the center of the substrate front surface 21 than the end front-surface electrode 34P is in the X-direction.

With this configuration, the outer front-surface electrode 33P is located toward the outer element electrode 83P of the edge-emitting element 70 in the X-direction. This reduces the resistance component of the conductive path between the outer front-surface electrode 33P and the outer element electrode 83P.

(1-10) The second inner wires 120P include second inner wires having different lengths.

With this configuration, the resistance component resulting from the lengths of the second inner wires 120P may be readily adjusted.

(1-11) The outer wires 130P include outer wires having different lengths.

With this configuration, the resistance component resulting from the lengths of the outer wires 130P may be readily adjusted.

(1-12) In plan view, the wires 100 are symmetric with respect to the imaginary center line CL. The imaginary center line CL is parallel to the Y-direction and extends through the center of the substrate front surface 21 with respect to the X-direction.

With this configuration, the resistance components of the wires 100 may be readily set at a design stage.

(1-13) In plan view, the front-surface electrodes 30 are symmetric with respect to the imaginary center line CL. The imaginary center line CL is parallel to the Y-direction and extends through the center of the substrate front surface 21 with respect to the X-direction.

With this configuration, the resistance components of the front-surface electrodes 30 may be readily set at a design stage.

### Second Embodiment

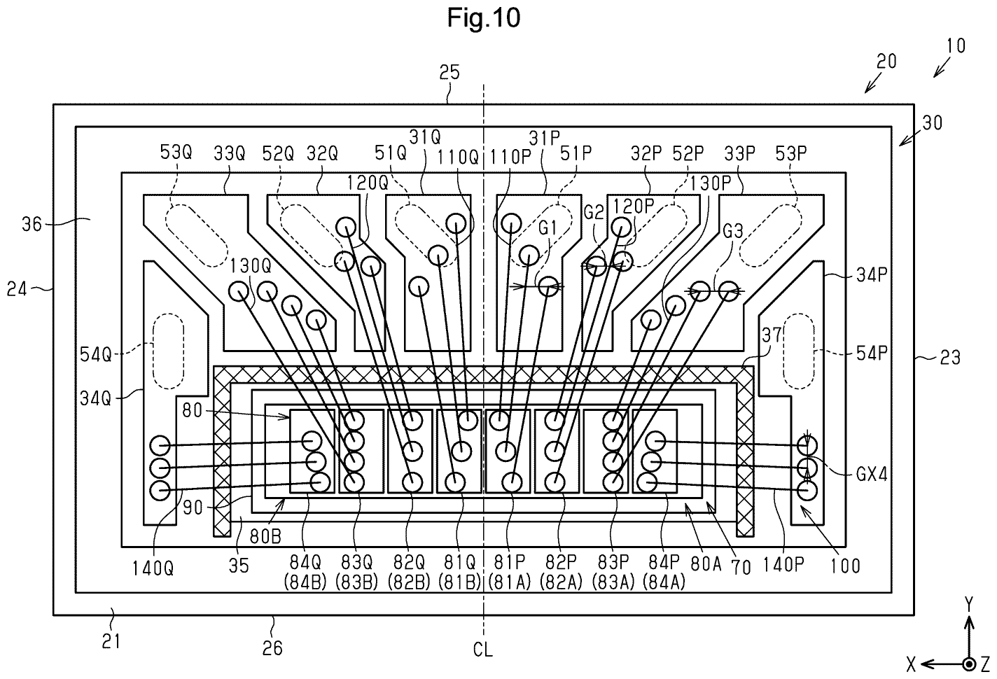

A semiconductor light emitting device 10 in accordance with a second embodiment will now be described with reference to FIG. 10. The semiconductor light emitting device 10 of the second embodiment differs from the semiconductor light emitting device 10 of the first embodiment in the number of wires. The description hereafter will focus on the differences from the first embodiment. The same reference characters are given to those components that are the same as the corresponding components of the first embodiment, and such components will not be described in detail.

In the second embodiment, the numbers of first inner wires 110P and 110Q, second inner wires 120P and 120Q, outer wires 130P and 130Q, and end wires 140P and 140Q are set separately in order to reduce variation in the resistance components of the first inner wires 110P and 110Q, the second inner wires 120P and 120Q, the outer wires 130P and 130Q, and the end wires 140P and 140Q. In other words, the numbers of first inner wires 110P and 110Q, second inner wires 120P and 120Q, outer wires 130P and 130Q, and end wires 140P and 140Q are changed in order to adjust the resistance components of the first inner wires 110P and 110Q, the second inner wires 120P and 120Q, the outer wires 130P and 130Q, and the end wires 140P and 140Q.

In an example, as shown in FIG. 10, the first inner wires 110P and 110Q, the second inner wires 120P and 120Q, and the end wires 140P and 140Q are less in number than the outer wires 130P and 130Q. The numbers of first inner wires 110P and 110Q, second inner wires 120P and 120Q, and end wires 140P and 140Q differ from the number of outer wires 130P and 130Q by one. In the second embodiment, the numbers of first inner wires 110P and 110Q, the number of second inner wires 120P and 120Q, and the number of end wires 140P and 140Q are three, and the number of outer wires 130P and 130Q is four.

In the second embodiment, the first inner wires 110P and 110Q correspond to “first wires”, and the outer wires 130P and 130Q correspond to “second wires”. Accordingly, in the second embodiment, as shown in FIG. 10, the first wires are less in number than the second wires. Also, the end wires are less in number than the second wires. The second inner wires 120P and 120Q may correspond to “first wires”.

The element-side bonding points 111 of the first inner wires 110P are spaced apart from each other. The element-side bonding points 111 are arranged in the same direction as that of the first embodiment. The distance between adjacent ones of the element-side bonding points 111 is greater than that of the first embodiment.

The substrate-side bonding points 112 are spaced apart from each other. The substrate-side bonding points 112 are arranged in the same direction as that of the first embodiment. The distance between adjacent ones of the substrate-side bonding points 112 is greater than that of the first embodiment. Thus, in plan view, the largest distance G1 between adjacent ones of the first inner wires 110P in the X-direction is greater than that of the first embodiment. In the second embodiment, in plan view, the first inner wires 110P have the same length. The lengths of the first inner wires 110P in plan view may be changed.

The element-side bonding points 121 of the second inner wires 120P are spaced apart from each other in the Y-direction in a state aligned in the same position in the X-direction. The distance between adjacent ones of the element-side bonding points 121 is greater than that of the first embodiment.

Two of the substrate-side bonding points 122 located at outermost positions in the X-direction are arranged on the second inner inclined portion 32C of the second inner front-surface electrode 32P. The positions of the two substrate-side bonding points 122 arranged on the second inner inclined portion 32C are the same as those of the first embodiment. The substrate-side bonding point 122 of one of the second inner wires 120P located between the remaining two of the second inner wires 120P in the X-direction is arranged on the second inner wide portion 32B. The two second inner wires 120P include the two substrate-side bonding points 122 arranged on the second inner inclined portion 32C. The substrate-side bonding point 122 arranged on the second inner wide portion 32B is at an end of second inner wide portion 32B located toward the first inner front-surface electrode 31P in the X-direction. In the second embodiment, in plan view, the second inner wires 120P have different lengths. The lengths of the second inner wires 120P in plan view may be changed.

The element-side bonding points 141 of the end wires 140P are arranged on the end element electrode 84P at a position shifted toward the fourth substrate side surface 26. The element-side bonding points 141 are arranged in the same direction as that of the first embodiment. The arrangement direction and arrangement position of the substrate-side bonding points 142 are the same as those of the first embodiment.

The outer wires 130P are the same as those of the first embodiment. In the second embodiment, the largest distance G3 between adjacent ones of the outer wires 130P in the X-direction is greater than the largest distance G1 between adjacent ones of the first inner wires 110P in the X-direction. The largest distance G3 is greater than the largest distance G2 between adjacent ones of the second inner wires 120P in the X-direction. The largest distance G3 is greater than the largest distance G4 between adjacent ones of the end wires 140P in the Y-direction.

In plan view, the outer wires 130P do not overlap the element-side bonding points 141 of the end wires 140P. In other words, in plan view, the element-side bonding point 141 of the end wires 140P do not overlap the outer wires 130P. In the example shown in FIG. 10, the average length of the outer wires 130P in plan view is less than the average length of the first inner wires 110P in plan view. The average length of the outer wires 130P in plan view is less than the average length of the second inner wires 120P in plan view. The average length of the outer wires 130P in plan view is greater than the average length of the end wires 140P in plan view. Thus, the average length of the end wires 140P in plan view is less than the average length of the first inner wires 110P in plan view or the average length of the second inner wires 120P in plan view.

The first inner wires 110Q, the second inner wires 120Q, the outer wires 130Q, and the end wires 140Q are symmetric to the first inner wires 110P, the second inner wires 120P, the outer wires 130P, and the end wires 140P with respect to the imaginary center line CL. Thus, these components will not be described in detail.

### Advantages

The semiconductor light emitting device 10 of the present embodiment has the following advantages.

(2-1) The semiconductor light emitting device 10 includes the substrate 20, the edge-emitting element 70, the front-surface electrodes 30, and the wires 100. The substrate 20 includes the substrate front surface 21 and the substrate back surface 22. The edge-emitting element 70 is disposed on the substrate 20 and includes the emitters 80A arranged next to each other in the X-direction (first direction) in plan view. The X-direction intersects the Z-direction, which is the thickness-wise direction of the substrate 20. The front-surface electrodes 30 are formed on the substrate front surface 21 and are spaced apart from each other. The wires 100 electrically connect the emitters 80A to the front-surface electrodes 30. The emitters 80A include the first inner emitter 81A including the first inner element electrode 81P, and the outer emitter 83A including the outer element electrode 83P. The first inner emitter 81A serves as “first emitter”. The outer emitter 83A serves as “second emitter”. The front-surface electrodes 30 include the first inner front-surface electrode 31P electrically connected to the first inner element electrode 81P, and the outer front-surface electrode 33P electrically connected to the outer element electrode 83P. The wires 100 include the first inner wires 110P electrically connecting the first inner element electrode 81P to the first inner front-surface electrode 31P, and the outer wires 130P electrically connecting the outer element electrode 83P to the outer front-surface electrode 33P. The first inner wires 110P are less in number than the outer wires 130P.

This configuration decreases the number of first inner wires 110P, thereby increasing the resistance component resulting from the first inner wires 110P. As a result, the difference in the resistance components of the first inner wires 110P and the outer wires 130P is reduced. In this manner, the difference in the resistance components of the first inner wires 110P and the outer wires 130P may be adjusted by the number of first inner wires 110P and the number of outer wires 130P. Specifically, the number of first inner wires 110P and the number of outer wires 130P may be set separately so that the difference in the resistance components of the first inner wires 110P and the outer wires 130P is within a predetermined range.

(2-2) The semiconductor light emitting device 10 includes the substrate 20, the edge-emitting element 70, the front-surface electrodes 30, and the wires 100. The substrate 20 includes the substrate front surface 21 and the substrate back surface 22. The edge-emitting element 70 is disposed on the substrate 20 and includes the emitters 80A arranged next to each other in the X-direction (first direction) in plan view. The X-direction intersects the Z-direction, which is the thickness-wise direction of the substrate 20. The front-surface electrodes 30 are formed on the substrate front surface 21 and are spaced apart from each other. The wires 100 electrically connect the emitters 80A to the front-surface electrodes 30. The emitters 80A include the second inner emitter 82A including the second inner element electrode 82P, and the outer emitter 83A including the outer element electrode 83P. The second inner emitter 82A serves as “first emitter”. The outer emitter 83A serves as “second emitter”. The front-surface electrodes 30 include the second inner front-surface electrode 32P electrically connected to the second inner element electrode 82P, and the outer front-surface electrode 33P electrically connected to the outer element electrode 83P. The wires 100 include the second inner wires 120P electrically connecting the second inner element electrode 82P to the second inner front-surface electrode 32P, and the outer wires 130P electrically connecting the outer element electrode 83P to the outer front-surface electrode 33P. The second inner wires 120P are less in number than the outer wires 130P. This configuration also obtains the above-described advantage (2-1).

### Third Embodiment

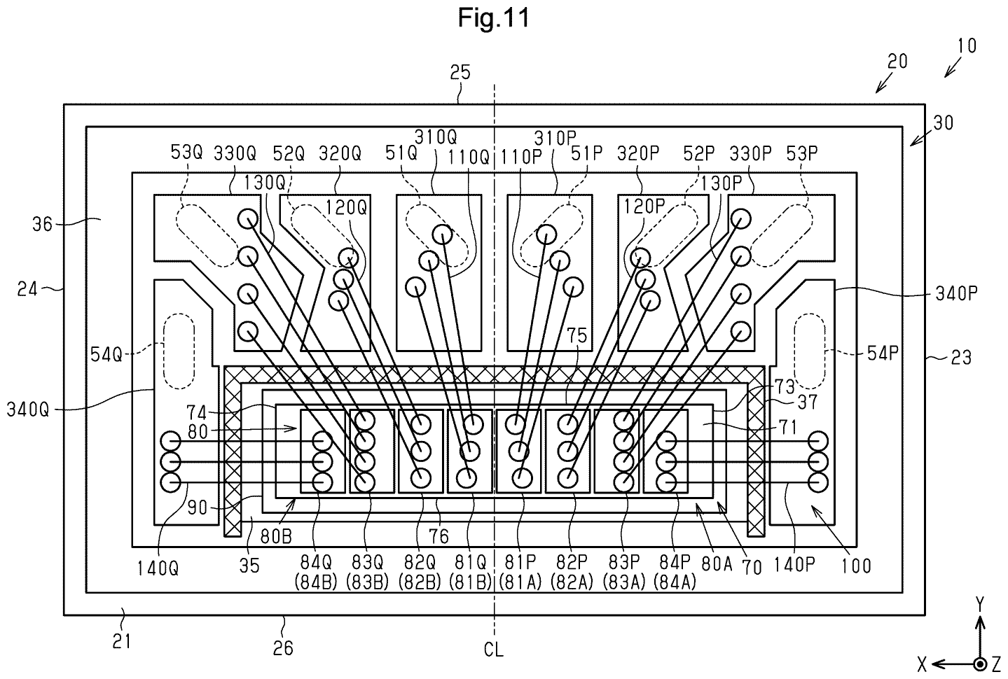

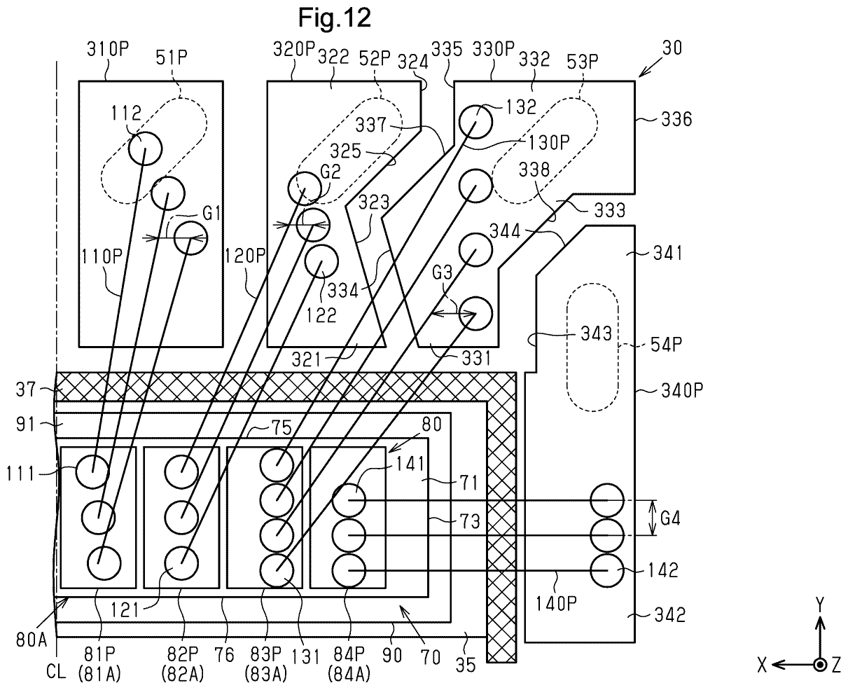

A semiconductor light emitting device 10 in accordance with a third embodiment will now be described with reference to FIGS. 11 and 12. The semiconductor light emitting device 10 of the third embodiment mainly differs from the semiconductor light emitting device 10 of the first embodiment in the shapes of the front-surface electrodes 30 and the number of wires. The description hereafter will focus on the differences from the first embodiment. The same reference characters are given to those components that are the same as the corresponding components of the first embodiment, and such components will not be described in detail.

As shown in FIG. 11, the front-surface electrodes 30 include first inner front-surface electrodes 310P and 310Q, second inner front-surface electrodes 320P and 320Q, outer front-surface electrodes 330P and 330Q, and end front-surface electrodes 340P and 340Q.

The first inner front-surface electrode 310P is electrically connected to the first inner emitter 81A of the edge-emitting element 70. The first inner front-surface electrode 310Q is electrically connected to the first inner emitter 81B. The second inner front-surface electrode 320P is electrically connected to the second inner emitter 82A of the edge-emitting element 70. The second inner front-surface electrode 320Q is electrically connected to the second inner emitter 82B. The outer front-surface electrode 330P is electrically connected to the outer emitter 83A of the edge-emitting element 70. The outer front-surface electrode 330Q is electrically connected to the outer emitter 83B. The end front-surface electrode 340P is electrically connected to the end emitter 84A of the edge-emitting element 70. The end front-surface electrode 340Q is electrically connected to the end emitter 84B.

The first inner front-surface electrode 310P, the second inner front-surface electrode 320P, the outer front-surface electrode 330P, and the end front-surface electrode 340P are formed in a region of the substrate front surface 21 located closer to the first substrate side surface 23 than the imaginary center line CL is. The imaginary center line CL is parallel to the Y-direction and extends through the center of the substrate 20 with respect to the X-direction. The first inner front-surface electrode 310Q, the second inner front-surface electrode 320Q, the outer front-surface electrode 330Q, and the end front-surface electrode 340Q are formed in a region of the substrate front surface 21 located closer to the second substrate side surface 24 than the imaginary center line CL is. In plan view, the first inner front-surface electrode 310P, the second inner front-surface electrode 320P, the outer front-surface electrode 330P, and the end front-surface electrode 340P are symmetric to the first inner front-surface electrode 310Q, the second inner front-surface electrode 320Q, the outer front-surface electrode 330Q, and the end front-surface electrode 340Q with respect to the imaginary center line CL.

The first inner front-surface electrode 310P, the second inner front-surface electrode 320P, and the outer front-surface electrode 330P are spaced apart from each other in the X-direction in a state aligned in the same position in the Y-direction. The first inner front-surface electrode 310P is located closer to the imaginary center line CL (center of substrate 20 in X-direction) than the second inner front-surface electrode 320P and the outer front-surface electrode 330P are. The outer front-surface electrode 330P is located closer to the first substrate side surface 23 than the first inner front-surface electrode 310P and the second inner front-surface electrode 320P are.

In plan view, the end front-surface electrode 340P is located closer to the first substrate side surface 23 than the edge-emitting element 70 is. The end front-surface electrode 340P is separated from the first inner front-surface electrode 310P, the second inner front-surface electrode 320P, and the outer front-surface electrode 330P toward the fourth substrate side surface 26. As viewed in the X-direction, the end front-surface electrode 340P includes a portion that overlaps the outer front-surface electrode 330P, and a portion that extends beyond the outer front-surface electrode 330P toward the fourth substrate side surface 26.

The first inner front-surface electrode 310Q, the second inner front-surface electrode 320Q, and the outer front-surface electrode 330Q are spaced apart from each other in the X-direction in a state aligned in the same position in the Y-direction. The first inner front-surface electrode 310Q is located closer to the imaginary center line CL (center of substrate 20 in X-direction) than the second inner front-surface electrode 320Q and the outer front-surface electrode 330Q are. The outer front-surface electrode 330Q is located closer to the second substrate side surface 24 than the first inner front-surface electrode 310Q and the second inner front-surface electrode 320Q are. The first inner front-surface electrodes 310P and 310Q are adjacent to each other at opposite sides of the imaginary center line CL.

In plan view, the distance from the outer front-surface electrode 330P to the outer emitter 83A (outer element electrode 83P) is greater than the distance from the first inner front-surface electrode 310P to the first inner emitter 81A (first inner element electrode 81P). The distance from the outer front-surface electrode 330P to the outer emitter 83A (outer element electrode 83P) is greater than the distance from the second inner front-surface electrode 320P to the second inner emitter 82A (second inner element electrode 82P). The outer front-surface electrode 330P and the outer emitter 83A are located relatively far from each other, such that the outer front-surface electrode 330P and the outer emitter 83A respectively correspond to “far emitter” and “far front-surface electrode”. Also, the first inner front-surface electrode 310P and the first inner emitter 81A are located relatively close to each other, such that the first inner front-surface electrode 310P and the first inner emitter 81A respectively correspond to “near emitter” and “near front-surface electrode”. In the same manner, the second inner front-surface electrode 320P and the second inner emitter 82A correspond to “near emitter” and “near front-surface electrode”. The same applies to the positional relationship of the first inner front-surface electrode 310Q and the first inner emitter 81B, the second inner front-surface electrode 320Q and the second inner emitter 82B, and the outer front-surface electrode 330Q and the outer emitter 83B.

In plan view, the end front-surface electrode 340Q is located closer to the second substrate side surface 24 than the edge-emitting element 70 is. The end front-surface electrode 340Q is separated from the first inner front-surface electrode 310Q, the second inner front-surface electrode 320Q, and the outer front-surface electrode 330Q toward the fourth substrate side surface 26. As viewed in the X-direction, the end front-surface electrode 340Q includes a portion that overlaps the outer front-surface electrode 330Q, and a portion that extends beyond the outer front-surface electrode 330Q toward the fourth substrate side surface 26.

As described above, in the direction in which the first inner front-surface electrodes 310P and 310Q, the second inner front-surface electrodes 320P and 320Q, and the outer front-surface electrodes 330P and 330Q are arranged (X-direction), “inner” means “toward the imaginary center line CL (center of substrate 20 in X-direction)”, and “outer” means “toward the first substrate side surface 23 or the second substrate side surface 24”.

The wires 100 include the first inner wires 110P and 110Q, the second inner wires 120P and 120Q, the outer wires 130P and 130Q, and the end wires 140P and 140Q, in the same manner as the first embodiment.

The first inner wires 110P electrically connect the first inner element electrode 81P of the edge-emitting element 70 to the first inner front-surface electrode 310P. The first inner wires 110Q electrically connect the first inner element electrode 81Q to the first inner front-surface electrode 310Q. The second inner wires 120P electrically connect the second inner element electrode 82P of the edge-emitting element 70 to the second inner front-surface electrode 320P. The second inner wires 120Q electrically connect the second inner element electrode 82Q to the second inner front-surface electrode 320Q. The outer wires 130P electrically connect the outer element electrode 83P of the edge-emitting element 70 to the outer front-surface electrode 330P. The outer wires 130Q electrically connect the outer element electrode 83Q to the outer front-surface electrode 330Q. The end wires 140P electrically connect the end element electrode 84P of the edge-emitting element 70 to the end front-surface electrode 340P. The end wires 140Q electrically connect the end element electrode 84Q to the end front-surface electrode 340Q. The first inner wires 110P and 110Q electrically connect the first inner front-surface electrodes 310P and 310Q, which are “near front-surface electrodes” to the first inner element electrodes 81P and 81Q, which are “near element electrodes”. Therefore, the first inner wires 110P and 110Q correspond to “near wires”. The second inner wires 120P and 120Q electrically connect the second inner front-surface electrodes 320P and 320Q, which are “near front-surface electrodes, to the second inner element electrodes 82P and 82Q, which are “near element electrodes”. Therefore, the second inner wires 120P and 120Q correspond to “near wires”. The outer wires 130P and 130Q electrically connect the outer front-surface electrodes 330P and 330Q, which are “far front-surface electrodes” to the outer element electrodes 83P and 83Q, which are “far element electrodes”. Therefore, the outer wires 130P and 130Q correspond to “far wires”.

The shapes and the positional relationship of the first inner front-surface electrodes 310P and 310Q, the second inner front-surface electrodes 320P and 320Q, the outer front-surface electrodes 330P and 330Q, and the end front-surface electrodes 340P and 340Q will now be described in detail. FIG. 12 is an enlarged plan view of the first inner front-surface electrode 310P, the second inner front-surface electrode 320P, the outer front-surface electrode 330P, and the end front-surface electrode 340P. As described above, the first inner front-surface electrode 310Q, the second inner front-surface electrode 320Q, the outer front-surface electrode 330Q, and the end front-surface electrode 340Q are symmetric to the first inner front-surface electrode 310P, the second inner front-surface electrode 320P, the outer front-surface electrode 330P, and the end front-surface electrode 340P with respect to the imaginary center line CL. Thus, these components will not be described in detail.

As shown in FIG. 12, the first inner front-surface electrode 310P is rectangular, with long sides extending in the Y-direction and short sides extending in the X-direction. In plan view, the first inner front-surface electrode 310P opposes both the first inner element electrode 81P and the second inner element electrode 82P of the edge-emitting element 70 in the Y-direction.

In plan view, the second inner front-surface electrode 320P is located closer to the first substrate side surface 23 (refer to FIG. 11) than the second inner element electrode 82P of the edge-emitting element 70 is. In plan view, the second inner front-surface electrode 320P opposes both the outer element electrode 83P and the end element electrode 84P of the edge-emitting element 70 in the Y-direction. In plan view, the shortest distance from the second inner front-surface electrode 320P to the second inner element electrode 82P is greater than the shortest distance from the first inner front-surface electrode 310P to the first inner element electrode 81P.

The second inner front-surface electrode 320P includes a first portion 321 located toward the edge-emitting element 70, and a second portion 322 located away from the edge-emitting element 70. In an example, the first portion 321 is located closer to the edge-emitting element 70 than the center of the second inner front-surface electrode 320P is in the Y-direction. The second portion 322 is located closer to the third substrate side surface 25 (refer to FIG. 11) than the center of the second inner front-surface electrode 320P is in the Y-direction.

The width (dimension in X-direction) of the first portion 321 is decreased from an end of the second inner front-surface electrode 320P located toward the edge-emitting element 70 to the center of the second inner front-surface electrode 320P. More specifically, the first portion 321 includes an inclined side 323. The inclined side 323 extends toward the center of the second inner front-surface electrode 320P in the Y-direction from one of two opposite edges of the second inner front-surface electrode 320P in the Y-direction located closer to the edge-emitting element 70. The inclined side 323 is inclined toward the imaginary center line CL (center of substrate front surface 21 in X-direction) as the inclined side 323 becomes closer to the center of the second inner front-surface electrode 320P in the Y-direction. The inclined side 323 is one of two opposite sides of the second inner front-surface electrode 320P in the X-direction located closer to the outer front-surface electrode 330P. The other one of the two opposite sides of the second inner front-surface electrode 320P in the X-direction is located closer to the first inner front-surface electrode 310P and extends in the Y-direction.

The width (dimension in X-direction) of the second portion 322 is increased from the center of the second inner front-surface electrode 320P in the Y-direction toward an end of the second inner front-surface electrode 320P located toward the third substrate side surface 25. The second portion 322 includes an end side 324 and an inclined side 325. The end side 324 extends in the Y-direction. The inclined side 325 is inclined toward the imaginary center line CL (center of substrate front surface 21 in X-direction) as the inclined side 325 extends from the end side 324 toward the edge-emitting element 70. In an example, the largest width of the second portion 322 is greater than the largest width of the first portion 321. The second inner through-interconnect 52P overlaps the second portion 322.

In plan view, the outer front-surface electrode 330P is located closer to the first substrate side surface 23 than the outer element electrode 83P of the edge-emitting element 70 is. In plan view, the outer front-surface electrode 330P is located closer to the first substrate side surface 23 than the end element electrode 84P of the edge-emitting element 70 is.

The outer front-surface electrode 330P includes an outer narrow portion 331, an outer wide portion 332, and an outer inclined portion 333.

The outer narrow portion 331 is a part of the outer front-surface electrode 330P located toward the edge-emitting element 70. The outer narrow portion 331 is adjacent to the first portion 321 of the second inner front-surface electrode 320P in the X-direction. The width (dimension in X-direction) of the outer narrow portion 331 is increased as the outer narrow portion 331 becomes farther away from the edge-emitting element 70 in the Y-direction. The outer narrow portion 331 includes an inclined side 334. The inclined side 334 extends toward the third substrate side surface 25 from one of two opposite edges of the outer front-surface electrode 330P in the Y-direction located closer to the edge-emitting element 70. The inclined side 334 is inclined toward the imaginary center line CL (center of substrate front surface 21 in X-direction) as the inclined side 334 becomes closer to the third substrate side surface 25; that is, as the inclined side 334 extends away from the edge-emitting element 70. The inclined side 334 is one of two opposite sides of the outer narrow portion 331 in the X-direction located closer to the second inner front-surface electrode 320P. The other one of the two opposite sides of the outer narrow portion 331 in the X-direction extends in the Y-direction. The inclined side 334 is adjacent to the inclined side 323 of the second inner front-surface electrode 320P in the X-direction.

The outer wide portion 332 is a part of the outer front-surface electrode 330P located farther from the edge-emitting element 70. The outer wide portion 332 includes an end of the outer front-surface electrode 330P located toward the third substrate side surface 25 and an end of the outer front-surface electrode 330P located toward the first substrate side surface 23.

The outer wide portion 332 includes end sides 335 and 336 each extending in the Y-direction in plan view. The end side 335 is an end side of the outer wide portion 332 located toward the second inner front-surface electrode 320P. The end side 336 is an end side of the outer wide portion 332 located toward the first substrate side surface 23. The end side 335 is located closer to the first substrate side surface 23 than the edge-emitting element 70 is. That is, the outer wide portion 332 is located closer to the first substrate side surface 23 than the edge-emitting element 70 is. The end side 335 is located closer to the first substrate side surface 23 than the sub-mount substrate 90 is. That is, the outer wide portion 332 is located closer to the first substrate side surface 23 than the edge-emitting element 70 is. The end side 335 is located closer to the first substrate side surface 23 than the inclined side 334 of the outer narrow portion 331 is. The width (dimension in X-direction) of the outer wide portion 332 is greater than the largest width of the second portion 322 of the second inner front-surface electrode 320P.

In plan view, the outer inclined portion 333 includes an inclined side 337 located toward the second inner front-surface electrode 320P, and an inclined side 338 located toward the first substrate side surface 23.

The inclined side 337 is adjacent to the inclined side 325 of the second inner front-surface electrode 320P in the X-direction. The inclined side 337 is inclined toward the outer emitter 83A of the edge-emitting element 70 as the inclined side 337 extends from the end side 335 of the outer wide portion 332 toward the center of the substrate front surface 21 in the X-direction. The inclined side 337 is inclined in the same direction as the inclined side 325. In plan view, the inclined side 337 is parallel to the inclined side 325.

The inclined side 338 is inclined toward the outer emitter 83A as the inclined side 338 extends from the end side 336 toward the center of the substrate front surface 21 in the X-direction. The inclined side 338 is inclined in the same direction as the inclined side 337. The inclined side 338 is parallel to the inclined side 337.

As described above, the outer inclined portion 333 is formed as an inclined region including the inclined side 337, which extends from the end side 335 toward the central part of the substrate front surface 21, and the inclined side 338, which extends from the end side 336 toward the central part of the substrate front surface 21.

The outer through-interconnect 53P overlaps both the outer wide portion 332 and the outer inclined portion 333. In an example, the longitudinal direction of the elliptic outer through-interconnect 53P is parallel to the direction in which the outer inclined portion 333 extends.

In plan view, the end front-surface electrode 340P extends in the Y-direction. As viewed in the Y-direction, the end front-surface electrode 340P overlaps the outer inclined portion 333 and the outer wide portion 332 of the outer front-surface electrode 330P. In an example, the end front-surface electrode 340P includes an end narrow portion 341, and an end wide portion 342 having a greater width (dimension in X-direction) than the end narrow portion 341.

As viewed in the X-direction, the end narrow portion 341 overlaps the outer narrow portion 331 and the outer inclined portion 333 of the outer front-surface electrode 330P. The end narrow portion 341 includes an end side 343 and an inclined side 344. The end side 343 is adjacent to the outer narrow portion 331 of the outer front-surface electrode 330P in the X-direction. The end side 343 extends in the Y-direction. The inclined side 344 is inclined toward the first substrate side surface 23 as the inclined side 344 extends from the end side 343 toward the third substrate side surface 25. The inclined side 344 is adjacent to the inclined side 338 in the X-direction. The inclined side 344 is inclined in the same direction as the inclined side 338. In an example, the inclined side 344 is parallel to the inclined side 338.

In plan view, the end wide portion 342 opposes the edge-emitting element 70 in the X-direction. The end wide portion 342 has a constant width and extends in the Y-direction. The end through-interconnect 54P overlaps both the end narrow portion 341 and the end wide portion 342.

In the third embodiment, the first inner wires 110P and 110Q, the second inner wires 120P and 120Q, and the end wires 140P and 140Q are less in number than the outer wires 130P and 130Q. The numbers of first inner wires 110P and 110Q, second inner wires 120P and 120Q, and end wires 140P and 140Q differ from the number of outer wires 130P and 130Q by one. In the third embodiment, the numbers of first inner wires 110P and 110Q, the number of second inner wires 120P and 120Q, and the number of end wires 140P and 140Q are three, and the number of outer wires 130P and 130Q is four.

In the third embodiment, the first inner wires 110P and 110Q correspond to “first wires”, and the outer wires 130P and 130Q correspond to “second wires”. Accordingly, in the second embodiment, as shown in FIG. 11, the first wires are less in number than the second wires. Also, the end wires are less in number than the second wires. The second inner wires 120P and 120Q may correspond to “first wires”.

The connection configuration between the first inner front-surface electrodes 310P and 310Q and the first inner wires 110P and 110Q, the second inner front-surface electrodes 320P and 320Q and the second inner wires 120P and 120Q, the outer front-surface electrodes 330P and 330Q and the outer wires 130P and 130Q, and the end front-surface electrodes 340P and 340Q and the ends wires 140P and 140Q will now be described in detail. FIG. 12 is an enlarged plan view of the first inner wires 110P, the second inner wires 120P, the outer wires 130P, and the end wires 140P. The first inner wires 110Q, the second inner wires 120Q, the outer wires 130Q, and the end wires 140Q are symmetric to the first inner wires 110P, the second inner wires 120P, the outer wires 130P, and the end wires 140P with respect to the imaginary center line CL. Thus, these components will not be described in detail.

A plurality of (in the third embodiment, three) element-side bonding points 111 of the first inner wires 110P are arranged on the first inner element electrode 81P in the Y-direction. The element-side bonding points 111 of the third embodiment are arranged in the same manner as the element-side bonding points 111 of the first embodiment. However, in the third embodiment, the distance between adjacent ones of the element-side bonding points 111 is greater than that of the first embodiment.

A plurality of (in the third embodiment, three) substrate-side bonding points 112 are arranged on the first inner front-surface electrode 31P in a direction intersecting both the X-direction and the Y-direction in plan view. The substrate-side bonding points 112 are inclined away from the edge-emitting element 70 as the substrate-side bonding points 112 become closer to the imaginary center line CL (center of substrate front surface 21 in X-direction). As viewed in the Y-direction, two adjacent ones of the substrate-side bonding points 112 partially overlap each other. In plan view, a distance between adjacent ones of the first inner wires 110P in the X-direction increases as the first inner wires 110P become farther away from the first inner element electrode 81P. The distance between adjacent ones of the first inner wires 110P in the X-direction may be defined by an interval between adjacent ones of the first inner wires 110P in the X-direction.

The first inner wires 110P have the same length. It is considered that the first inner wires 110P have the same length as long as a difference in length between the first inner wires 110P is, for example, within 10% of the length of a predetermined first inner wire 110P.

Two of the substrate-side bonding points 112 located toward the imaginary center line CL (center of substrate front surface 21 in X-direction) are located closer to the third substrate side surface 25 (farther from edge-emitting element 70) than the center of the first inner front-surface electrode 310P in the Y-direction is. One of the substrate-side bonding points 112 located closest to the second inner front-surface electrode 320P is located closer to the edge-emitting element 70 than the center of the first inner front-surface electrode 310P in the Y-direction is.

A plurality of (in the third embodiment, three) element-side bonding points 121 of the second inner wire 120P are arranged in the same manner as the element-side bonding points 111.

A plurality of (in the third embodiment, three) substrate-side bonding points 122 are arranged on the first inner front-surface electrode 31P in a direction intersecting both the X-direction and the Y-direction in plan view. The substrate-side bonding points 122 are arranged in the same direction as the element-side bonding points 121. One of the substrate-side bonding points 122 located closest to the imaginary center line CL (first inner front-surface electrode 310P) is arranged on the second portion 322 of the second inner front-surface electrode 320P. More specifically, one of the substrate-side bonding points 122 located closest to the imaginary center line CL (first inner front-surface electrode 310P) is arranged on one of two opposite ends of the second portion 322 in the Y-direction located closer to the first portion 321. Two of the substrate-side bonding points 122 located toward the outer front-surface electrode 330P are arranged on the first portion 321 of the second inner front-surface electrode 320P. More specifically, two of the substrate-side bonding points 122 located toward the outer front-surface electrodes 330P are arranged on one of two opposite ends of the first portion 321 in the Y-direction located closer to the second portion 322. Two of the substrate-side bonding points 122 located toward the outer front-surface electrode 330P are located toward the inclined side 323 in the X-direction.

In plan view, the second inner wires 120P are parallel to each other. An angle at which the second inner wires 120P are inclined with respect to the Y-direction is greater than that of the first inner wires 110P with respect to the Y-direction.

In plan view, the second inner wires 120P have the same length. It is considered that the second inner wires 120P have the same length in plan view as long as a difference in length between the second inner wires 120P is, for example, within 10% of the length of a predetermined second inner wire 120P in plan view. In an example, the total length of the second inner wires 120P in plan view is equal to the total length of the first inner wires 110P in plan view.

A plurality of (in the third embodiment, four) element-side bonding points 131 of the outer wires 130P are arranged in the same manner as that of the element-side bonding points 131 of the first embodiment.

A plurality of (in the third embodiment, four) substrate-side bonding points 132 are spaced apart from each other in the Y-direction in a state aligned in the same position in the X-direction. The distance between two adjacent ones of the substrate-side bonding points 132 in the Y-direction is greater than the distance between two adjacent ones of the substrate-side bonding points 122 in the direction in which the substrate-side bonding points 122 are arranged. The distance between two adjacent ones of the substrate-side bonding points 132 in the Y-direction is greater than the distance between two adjacent ones of the substrate-side bonding points 132 in the direction in which the substrate-side bonding points 132 are arranged.

One of the substrate-side bonding points 132 located closest to the edge-emitting element 70 is arranged on the outer narrow portion 331 of the outer front-surface electrode 330P. More specifically, one of the substrate-side bonding points 132 located closest to the edge-emitting element 70 is arranged on an end of the outer narrow portion 331 located toward the edge-emitting element 70 and the first substrate side surface 23. One of the substrate-side bonding points 132 located second closest to the edge-emitting element 70 is arranged on a boundary of the outer narrow portion 331 and the outer inclined portion 333. One of the substrate-side bonding points 132 located third closest to the edge-emitting element 70 is arranged on the outer inclined portion 333. More specifically, one of the substrate-side bonding points 132 located third closest to the edge-emitting element 70 is arranged on a part of the outer inclined portion 333 located toward the outer wide portion 332. One of the substrate-side bonding points 132 located farthest from the edge-emitting element 70 is arranged on the outer wide portion 332. More specifically, one of the substrate-side bonding points 132 located farthest from the edge-emitting element 70 is arranged on an end of the outer wide portion 332 located toward the second inner front-surface electrode 320P.

In plan view, the outer wires 130P include wires having different lengths. In plan view, the shortest one of the outer wires 130P has the same length as the first inner wire 110P. The shortest one of the outer wires 130P has the same length as the second inner wire 120P. The second shortest one of the outer wires 130P is longer than the first inner wire 110P or the second inner wire 120P. Accordingly, the third shortest one and the longest one of the outer wires 130P are both longer than the first inner wire 110P or the second inner wire 120P.

In plan view, the distance between adjacent ones of the outer wires 130P in the X-direction increases from the element-side bonding points 131 toward the substrate-side bonding points 132. The distance between adjacent ones of the outer wires 130P in the X-direction may be defined by a shortest distance between adjacent ones of the outer wires 130P in the X-direction.

A plurality of (in the third embodiment, three) element-side bonding points 141 of the end wires 140P are arranged next to each other in the Y-direction in a state aligned in the same position in the X-direction. The element-side bonding points 141 are arranged on the end element electrode 84P at a position shifted toward the fourth substrate side surface 26 in the Y-direction. The element-side bonding points 141 are arranged on the end element electrode 84P at a position shifted toward the first substrate side surface 23 in the X-direction. In this manner, in plan view, the element-side bonding points 141 do not overlap the outer wires 130P.

A plurality of (in the third embodiment, three) substrate-side bonding points 142 are arranged on the end wide portion 342 of the end front-surface electrode 340P. The substrate-side bonding points 142 are arranged next to each other in the Y-direction in a state aligned in the same position in the X-direction. The substrate-side bonding points 142 are arranged on the end wide portion 342 at a position shifted toward the first substrate side surface 23.

The end wires 140P are spaced apart from each other in the Y-direction. The end wires 140P are parallel to each other. The end wires 140P have the same length. It is considered that the end wires 140P have the same length as long as a difference in length between the end wires 140P is, for example, within 10% of the length of a predetermined end wire 140P. The total length of the end wires 140P is less than the total length of the outer wires 130P. The total length of the end wires 140P is less than the total length of the first inner wires 110P. The total length of the end wires 140P is less than the total length of the second inner wires 120P.

The lengths of the first inner wires 110P, the second inner wires 120P, the outer wires 130P, and the end wires 140P may be changed. In an example, the first inner wires 110P may include wires having different lengths. The second inner wires 120P may include wires having different lengths. The end wires 140P may include wires having different lengths. The total length of the first inner wires 110P may differ from the total length of the second inner wires 120P.

In plan view, the largest distance G3 between adjacent ones of the outer wires 130P in the X-direction is greater than the largest distance G1 between adjacent ones of the first inner wires 110P in the X-direction. In plan view, the largest distance G3 is greater than the largest distance G2 between adjacent ones of the second inner wires 120P in the X-direction. In plan view, the largest distance G3 is greater than the largest distance G4 between adjacent ones of the end wires 140P in the Y-direction.

The largest distance G3 may be defined by a largest value of a distance between two adjacent ones of the outer wires 130P in the X-direction. In the example shown in FIG. 12, in plan view, the largest distance G3 is the distance between the centers of the substrate-side bonding points 132 of two of the outer wires 130P located toward the first substrate side surface 23.

The largest distance G1 may be defined by a largest value of a distance between two adjacent ones of the first inner wires 110P in the X-direction. In the example shown in FIG. 12, in plan view, the largest distance G1 is the largest value of the distance between two of the second inner wires 120P located toward the first substrate side surface 23 in the X-direction.

The largest distance G2 may be defined by a largest value of a distance between two adjacent ones of the second inner wires 120P in the X-direction. In the example shown in FIG. 12, in plan view, the largest distance G2 is the largest value of the distance between the two middle ones of the second inner wires 120P in the X-direction.

The largest distance G4 may be defined by a largest value of a distance between two adjacent ones of the end wires 140P in the Y-direction. In the example shown in FIG. 12, the distance between two adjacent ones of the end wires 140P in the Y-direction is uniform. Therefore, the largest distance G4 may be the distance between any two adjacent ones of the end wires 140P in the Y-direction.

In the third embodiment, a largest distance in the Y-direction between two adjacent ones of the outer wires 130P in the X-direction is greater than the largest distance G3. In an example, the largest distance in the Y-direction between two adjacent ones of the outer wires 130P in the X-direction may be defined by a distance between the centers of the substrate-side bonding points 132 of the two adjacent outer wires 130P in the X-direction.

### Operation

The operation of the semiconductor light emitting device 10 in accordance with the third embodiment will now be described.

When the first inner wires 110P, the second inner wires 120P, and the end wires 140P are reduced in number, the resistance components (inductance) of the first inner conductive path, the second inner conductive path, and the end conductive path of the third embodiment are likely to be relatively large. That is, the resistance components of the first inner conductive path, the second inner conductive path, and the end conductive path of the third embodiment become close to the resistance component of the outer conductive path. This reduces the difference in the resistance components of the first inner conductive path, the second inner conductive path, the outer conductive path, and the end conductive path of the second embodiment.

An example of simulated resistance components of the conductive paths will now be described. In this simulation example, the semiconductor light emitting device 10 of the third embodiment was driven at 10 MHz and 100 MHz. Also, a comparative example of simulated resistance components of the conductive paths will be described. In this comparative simulation example, the numbers of first inner wires 110P, second inner wires 120P, and end wires 140P were equal to the number of outer wires 130P. Such a semiconductor light emitting device 10 was driven at 10 MHz and 100 MHz.

In a case in which the resistance component of the comparative outer conductive path when the semiconductor light emitting device of the comparative example was driven at 10 MHz is defined as 100%, the resistance component of the comparative first inner conductive path was 89%, the resistance component of the comparative second inner conductive path was 91%, and the resistance component of the comparative end conductive path was 83%. When the semiconductor light emitting device of the comparative example was driven at 100 MHz, the resistance components of the conductive paths were the same as those when the semiconductor light emitting device of the comparative example was driven at 10 MHz. That is, in the semiconductor light emitting device of the comparative example, the difference in the resistance components of the comparative first inner conductive path, the comparative second inner conductive path, the comparative outer conductive path, and the end comparative conductive path was 17%, at most.

In a case in which the resistance component of the outer conductive path of the third embodiment when the semiconductor light emitting device 10 of the third embodiment was driven at 10 MHz is defined as 100%, the resistance component of the first inner conductive path of the first embodiment was 95%, the resistance component of the second inner conductive path of the third embodiment was 99%, and the resistance component of the end conductive path of the third embodiment was 92%. In a case in which the resistance component of the outer conductive path of the third embodiment when the semiconductor light emitting device 10 of the third embodiment was driven at 100 MHz is defined as 100%, the resistance component of the first inner conductive path of the first embodiment was 94%, the resistance component of the second inner conductive path of the third embodiment was 98%, and the resistance component of the end conductive path of the third embodiment was 91%. In this manner, the difference in the resistance components of the outer conductive path, the first inner conductive path, the second inner conductive path, and the end conductive path of the third embodiment may be less than 10%. The semiconductor light emitting device 10 of the third embodiment obtains the above-described advantages (1-1) and (1-2) of the first embodiment, and the above-described advantages (2-1) and (2-2) of the second embodiment.

### Modified Examples

The above embodiments may be modified as described below. The modified examples described below may be combined as long as there is no technical contradiction. The technical aspects of the above embodiments may be combined as long as combined modifications remain technically consistent with each other.

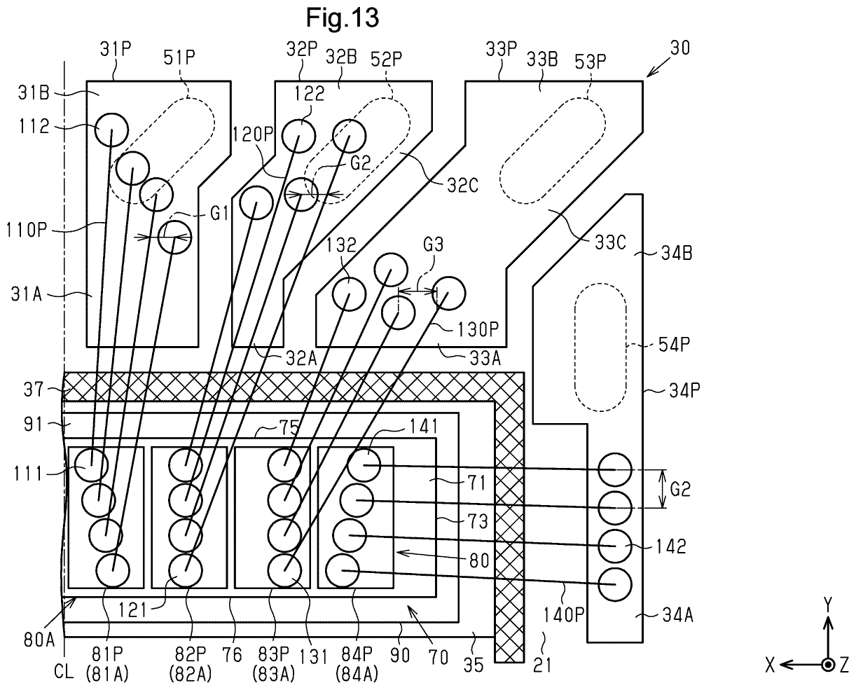

In the first and second embodiments, the positions of the substrate-side bonding points 132 of the outer wires 130P on the outer front-surface electrode 33P may be changed. In an example, as shown in FIG. 13, every one of the substrate-side bonding points 132 may be arranged on the first outer end portion 33A of the outer front-surface electrode 33P. This configuration decreases the lengths of the outer wires 130P, thereby reducing the resistance component of the conductive path between the outer element electrode 83P of the edge-emitting element 70 and the outer through-interconnect 53P.

In the first and second embodiments, the arrangement of the element-side bonding points 121 of the second inner wires 120P may be changed. In an example, the element-side bonding points 121 may be arranged on the second inner element electrode 82P at a position shifted toward the outer element electrode 83P in the X-direction. In another example, in plan view, the element-side bonding points 121 may be arranged in the same direction as the element-side bonding points 111 of the first inner wires 110P.

In the first and second embodiments, the arrangement of the element-side bonding points 141 of the end wires 140P may be changed. In an example, the element-side bonding points 141 may be arranged next to each other in the Y-direction in a state aligned in the same position in the X-direction. In this case, the element-side bonding points 141 may be located on the end element electrode 84P at any position in the X-direction.

In the first and second embodiments, the planar shapes of the end front-surface electrodes 34P and 34Q may be changed. In an example, the end narrow portion 34A may be omitted from the end front-surface electrodes 34P and 34Q. In this case, for example, the portion corresponding to the end narrow portion 34A may have the same width (dimension in X-direction) as the end wide portion 34B.

In the second embodiment, the number of first inner wires 110P or the number of second inner wires 120P may be equal to the number of outer wires 130P.

In the second embodiment, the number of end wires 140P may be equal to the number of outer wires 130P.

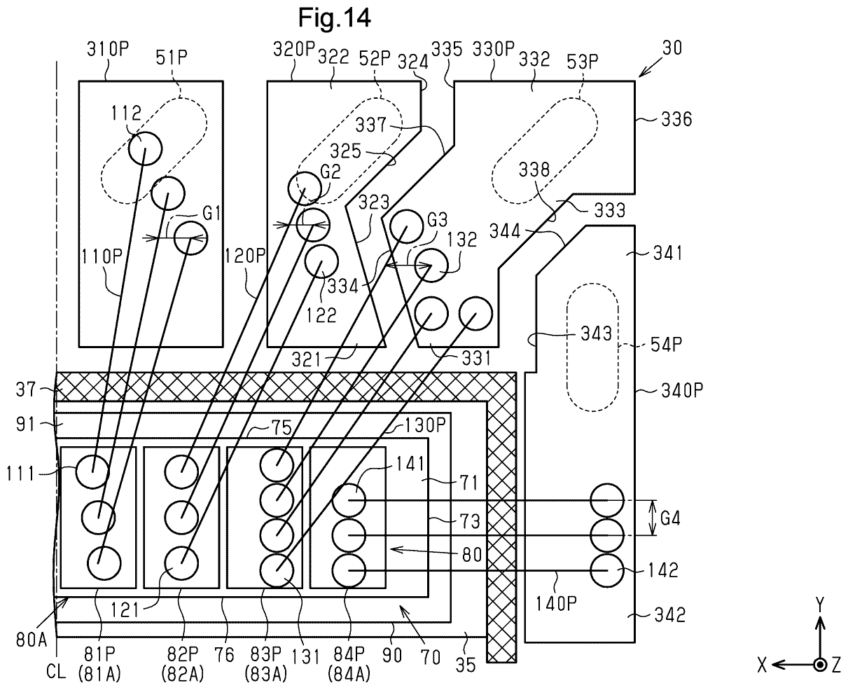

In the third embodiment, the largest distance G3 between adjacent ones of the outer wires 130P in the X-direction may be less than or equal to the largest distance G1 between adjacent ones of the first inner wires 110P in the X-direction. In an example, as shown in FIG. 14, the substrate-side bonding points 132 of three of the outer wires 130P located toward the third substrate side surface 25 in the Y-direction are located closer to the inclined side 334, as compared to the substrate-side bonding points 132 of the third embodiment. Thus, in plan view, these three outer wires 130P are shorter than those of the third embodiment. In the example shown in FIG. 14, in plan view, these three outer wires 130P have the same length. In plan view, these three outer wires 130P are shorter than the shortest one of the first inner wires 110P. Also, in plan view, these three outer wires 130P are shorter than the shortest one of the second inner wires 120P.

In the example shown in FIG. 14, the largest distance G3 may be defined by a largest value of a distance in the X-direction between one of the outer wires 130P located closest to the third substrate side surface 25 and one of the outer wires 130P located second closest to the third substrate side surface 25. The largest distance G3 is greater than the largest distance G1 of the first inner wires 110P or the largest distance G2 of the second inner wires 120P.

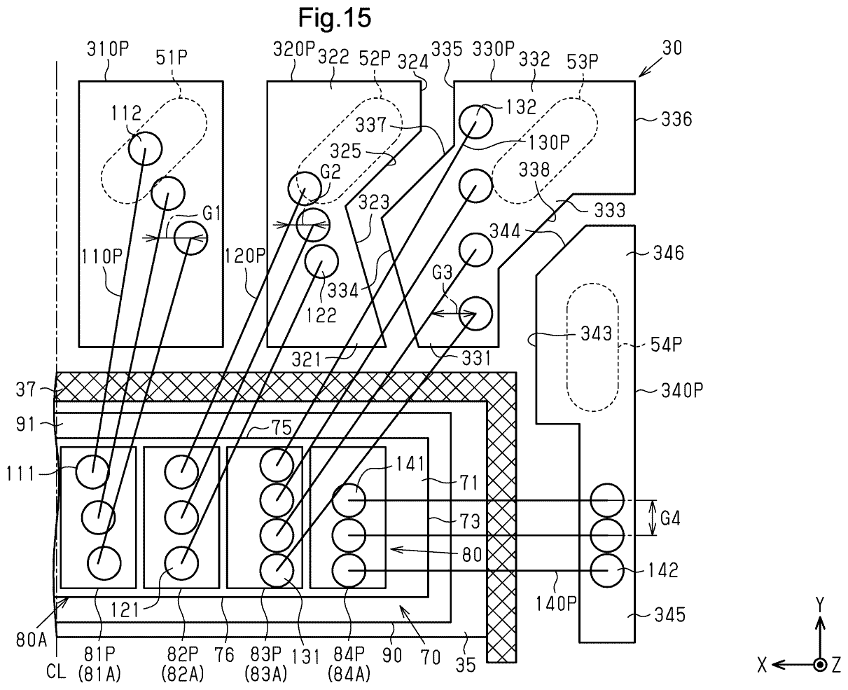

As shown in FIG. 15, the end front-surface electrode 340P of the third embodiment may include an end narrow portion 345 and an end wide portion 346, instead of the end narrow portion 341 and the end wide portion 342 shown in FIG. 12. In plan view, the end wide portion 346 has the same shape as the end narrow portion 341 shown in FIG. 12. Accordingly, the end wide portion 346 includes the end side 343 and the inclined side 344. The end narrow portion 345 has a smaller width (dimension in X-direction) than the end wide portion 346. The substrate-side bonding points 142 of the end wires 140P may be arranged on the end narrow portion 345.

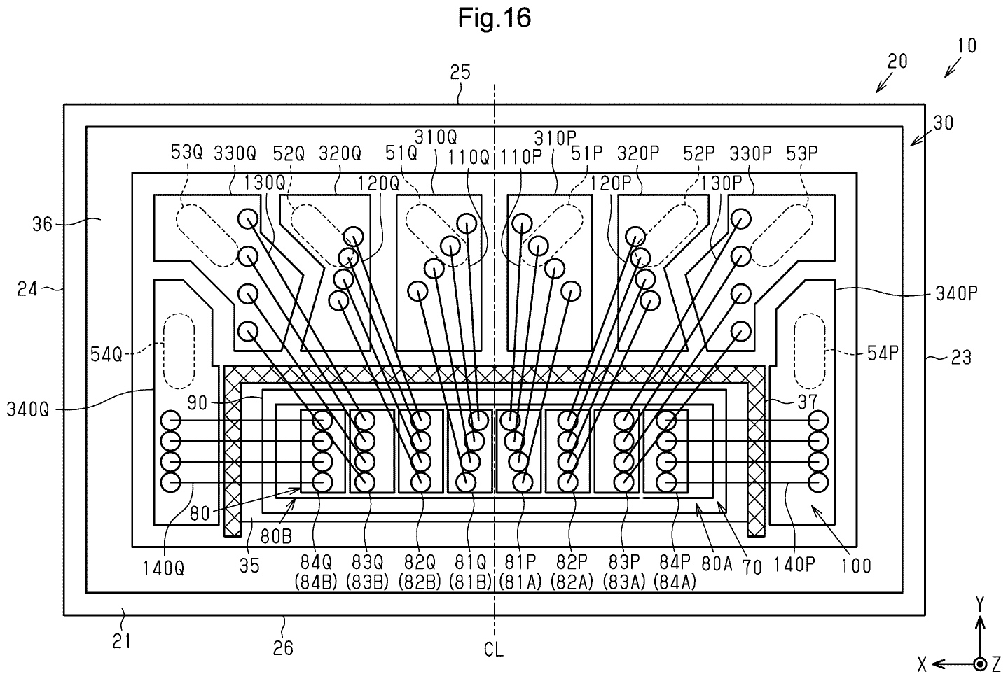

As shown in FIG. 16, the numbers of first inner wires 110P, second inner wires 120P, and end wires 140P of the third embodiment may be the same as the number of outer wires 130P. In this modified example, one or two of the numbers of first inner wires 110P, second inner wires 120P, and end wires 140P may be less than the number of outer wires 130P. In an example, the first inner wires 110P and the second inner wires 120P may be equal in number to the outer wires 130P, and the end wires 140P may be less in number than the outer wires 130P. The above relationship of the numbers of wires may also apply to the first inner wires 110Q, the second inner wires 120Q, the outer wires 130Q, and the end wires 140Q.

In the example shown in FIG. 16, the average length of the outer wires 130P in plan view is greater than the average length of the first inner wires 110P in plan view. The average length of the outer wires 130P in plan view is greater than the average length of the second inner wires 120P in plan view. The average length of the outer wires 130P in plan view is greater than the average length of the end wires 140P in plan view. Further, the average length of the end wires 140P in plan view is less than the average length of the first inner wires 110P in plan view or the average length of the second inner wires 120P in plan view. The above relationship of the average lengths of the wires may also apply to the first inner wires 110Q, the second inner wires 120Q, the outer wires 130Q, and the end wires 140Q.

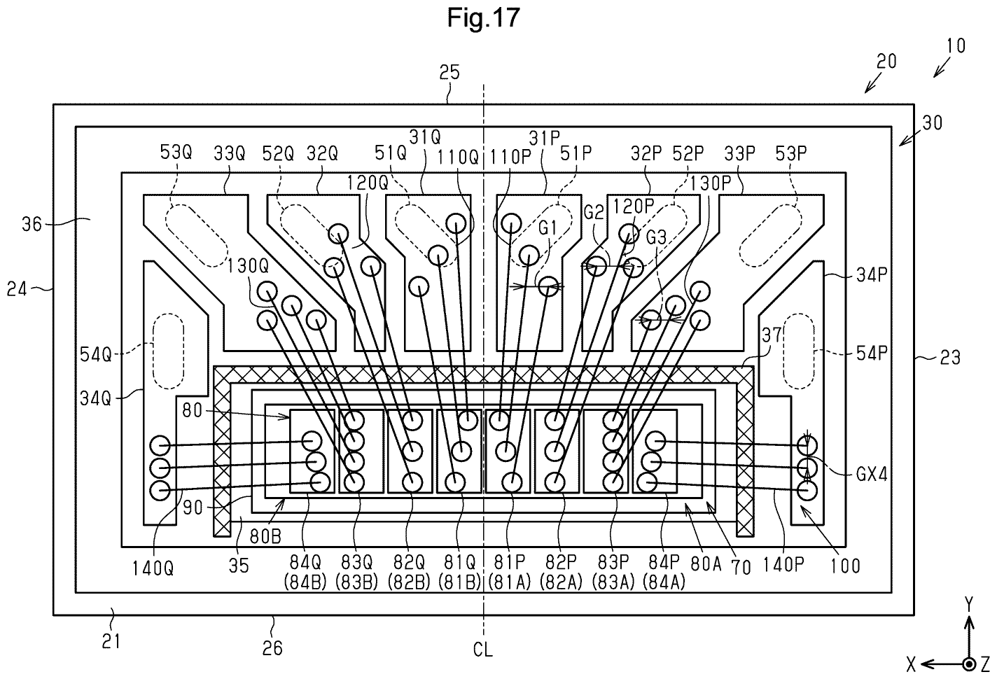

As shown in FIG. 17, when the number of first inner wires 110P is less than the number of the outer wires 130P in the second embodiment, in plan view, the largest distance G3 between adjacent ones of the outer wires 130P in the X-direction may be less than or equal to the largest distance G1 between adjacent ones of the first inner wires 110P in the X-direction. In this case, the substrate-side bonding point 132 of one of the outer wires 130P located closest to the first substrate side surface 23 is arranged on the first outer end portion 33A of the outer front-surface electrode 33P. Accordingly, one of the outer wires 130P located closest to the first substrate side surface 23 is shorter than that of the second embodiment.

In the example shown in FIG. 17, in plan view, the largest distance G3 may be defined as the largest value of the distance in the X-direction between one of the outer wires 130P located closest to the center of the substrate front surface 21 and one of the outer wires 130P located second closest to the center of the substrate front surface 21 in the X-direction. In plan view, the largest distance G1 may be defined as the largest value of the distance in the X-direction between one of the first inner wires 110P located closest to the first substrate side surface 23 and one of the first inner wires 110P located second closest to the first substrate side surface 23.

Further, when the number of second inner wires 120P is less than the number of the outer wires 130P, in plan view, the largest distance G3 between adjacent ones of the outer wires 130P in the X-direction may be less than or equal to the largest distance G2 between the adjacent ones of the second inner wires 120P in the X-direction. In the example shown in FIG. 17, in plan view, the largest distance G2 may be defined as the largest value of the distance in the X-direction between one of the second inner wires 120P located closest to the center of the substrate front surface 21 and one of the second inner wires 120P located second closest to the center of the substrate front surface 21 in the X-direction.

Furthermore, the number of end wires 140P may be less than the number of outer wires 130P. In the example shown in FIG. 17, in plan view, the largest distance G3 between adjacent ones of the outer wires 130P in the X-direction may be less than or equal to the largest distance G4 between adjacent ones of the end wires 140P in the Y-direction. In plan view, the largest distance G4 may be defined as the largest value of the distance in the Y-direction between one of the end wires 140P located closest to the third substrate side surface 25 and one of the end wires 140P located second closest to the third substrate side surface 25 in the Y-direction. The above relationship of the numbers of wires and the largest distances between the wires may also apply to the first inner wires 110Q, the second inner wires 120Q, the outer wires 130Q, and the end wires 140Q.

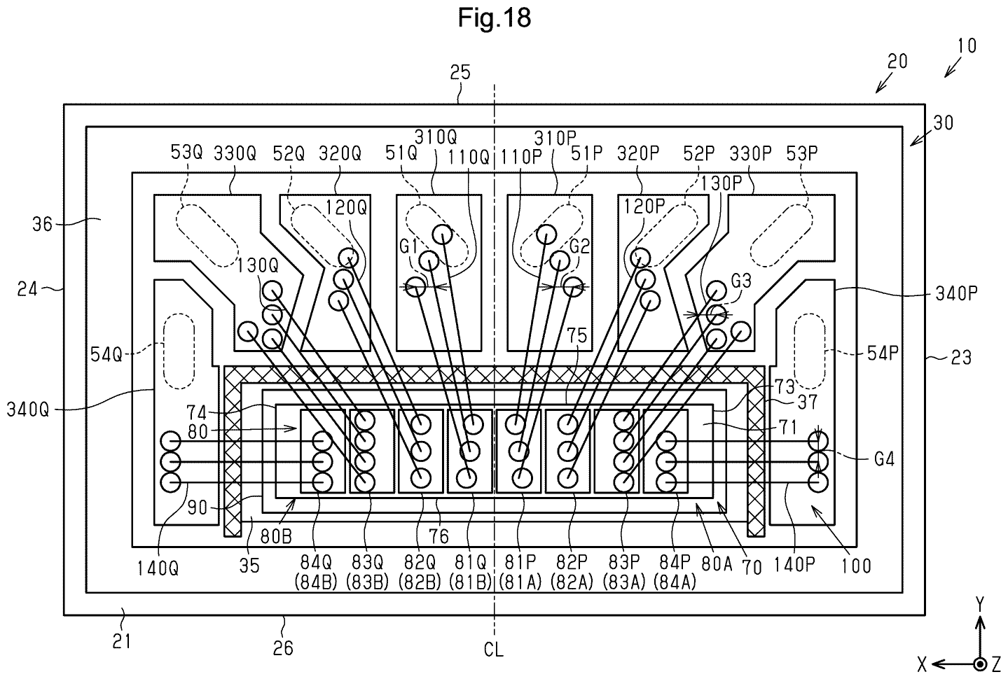

As shown in FIG. 18, when the number of first inner wires 110P is less than the number of the outer wires 130P in the third embodiment, in plan view, the largest distance G3 between adjacent ones of the outer wires 130P in the X-direction may be less than or equal to the largest distance G1 between adjacent ones of the first inner wires 110P in the X-direction. In this case, the substrate-side bonding point 132 of one of the outer wires 130P located closest to the first substrate side surface 23 is arranged on the first outer end portion 33A of the outer front-surface electrode 33P. In this case, in plan view, the largest distance G3 may be defined as the largest value of the distance in the X-direction between one of the outer wires 130P located closest to the center of the substrate front surface 21 and one of the outer wires 130P located second closest to the center of the substrate front surface 21 in the X-direction.

Further, when the number of second inner wires 120P is less than the number of the outer wires 130P, in plan view, the largest distance G3 between adjacent ones of the outer wires 130P in the X-direction may be less than or equal to the largest distance G2 between the adjacent ones of the second inner wires 120P in the X-direction. In the example shown in FIG. 18, in plan view, the largest distance G2 may be defined as the largest value of the distance in the X-direction between one of the second inner wires 120P located closest to the first substrate side surface 23 and one of the second inner wires 120P located second closest to the first substrate side surface 23 in the X-direction.

Furthermore, the number of end wires 140P may be less than the number of outer wires 130P. In the example shown in FIG. 18, in plan view, the largest distance G3 between adjacent ones of the outer wires 130P in the X-direction may be less than or equal to the largest distance G4 between adjacent ones of the end wires 140P in the X-direction. In plan view, the largest distance G4 may be defined as the largest value of the distance in the Y-direction between one of the end wires 140P located closest to the third substrate side surface 25 and one of the end wires 140P located second closest to the third substrate side surface 25 in the Y-direction. The above relationship of the numbers of wires and the largest distances between the wires may also apply to the first inner wires 110Q, the second inner wires 120Q, the outer wires 130Q, and the end wires 140Q.

In the above embodiments, the planar shapes of the first inner through-interconnects 51P and 51Q, the second inner through-interconnects 52P and 52Q, the outer through-interconnects 53P and 53Q, and the end through-interconnects 54P and 54Q may be changed. In an example, in plan view, the first inner through-interconnects 51P and 51Q, the second inner through-interconnects 52P and 52Q, the outer through-interconnects 53P and 53Q, and the end through-interconnects 54P and 54Q may be circular, polygonal, or oval.

In the above embodiments, the adhering pattern 36 may be omitted.

In the above embodiments, the sub-mount substrate 90 may be omitted.

In the above embodiments, the first inner wires 110P, the second inner wires 120P, the outer wires 130P, and the end wires 140P have the same wire height. However, there is no limit to such a configuration. At least one of the wire heights of the first inner wires 110P, the second inner wires 120P, the outer wires 130P, and the end wires 140P may differ from the other ones of the wire heights. The wire heights of the first inner wires 110Q, the second inner wires 120Q, the outer wires 130Q, and the end wires 140Q may be changed in the same manner.

In the above embodiments, the first inner wires 110P may include first inner wires 110P having different wire heights. The first inner wires 110Q may be changed in the same manner.

In the above embodiments, the second inner wires 120P may include second inner wires 120P having different wire heights. The second inner wires 120Q may be changed in the same manner.

In the above embodiments, the outer wires 130P may include outer wires 130P having different wire heights. The outer wires 130Q may be changed in the same manner.

In the above embodiments, the end wires 140P may include end wires 140P having different wire heights. The end wires 140Q may be changed in the same manner.

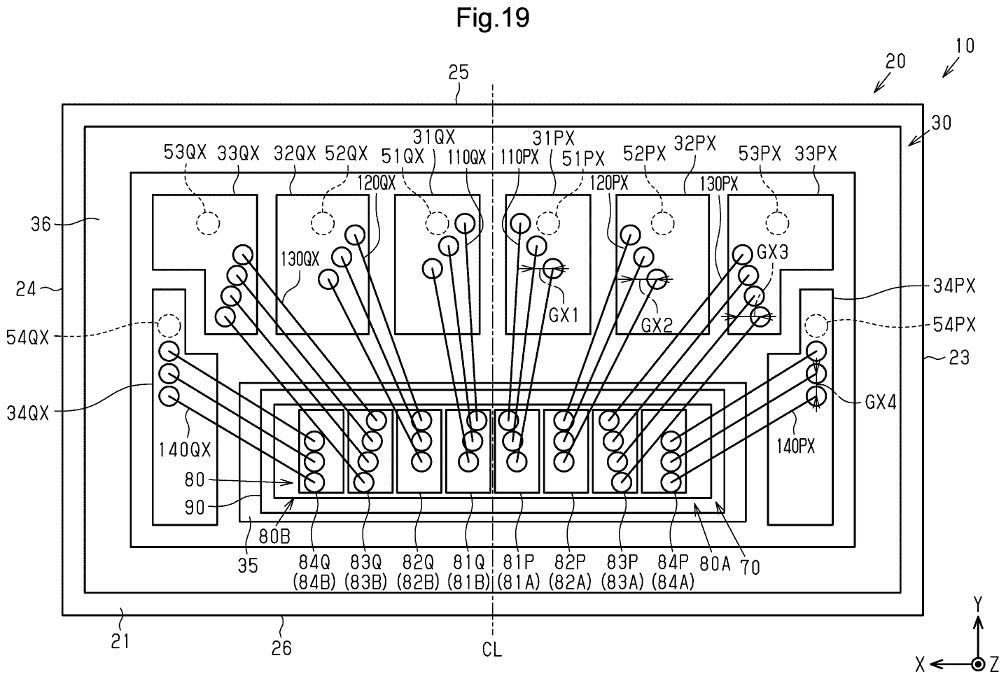

As shown in FIG. 19, the numbers of first inner wires 110PX and 110QX, second inner wires 120PX and 120QX, and end wires 140PX and 140QX may be less than the number of outer wires 130PX and 130QX. In the semiconductor light emitting device 10 shown in FIG. 19, the distance from the outer front-surface electrode 33PX to the outer emitter 83A of the edge-emitting element 70 is greater than the distance from the first inner front-surface electrode 31PX to the first inner emitter 81A of the edge-emitting element 70. Also, the distance from the outer front-surface electrode 33PX to the outer emitter 83A is greater than the distance from the second inner front-surface electrode 32PX to the second inner emitter 82A of the edge-emitting element 70. This configuration obtains the above-described advantages (2-1) and (2-2) of the second embodiment.

In the above embodiments, the number of element electrodes 80 of the edge-emitting element 70 may be changed. In an example, the number of element electrodes 80 may be six. In this case, one of the sets of the first inner front-surface electrodes 31P and 31Q, the second inner front-surface electrodes 32P and 32Q, and the end front-surface electrodes 34P and 34Q is omitted from the front-surface electrode 30. In another example, the number of element electrodes 80 may be four. In this case, two of the sets of the first inner front-surface electrodes 31P and 31Q, the second inner front-surface electrodes 32P and 32Q, and the end front-surface electrodes 34P and 34Q are omitted from the front-surface electrode 30.

Various examples described in this specification may be combined as long as there is no technical contradiction.

In this specification, “at least one of A and B” should be understood to mean “only A, or only B, or both A and B.”

In the present disclosure, the term “on” includes the meaning of “above” in addition to the meaning of “on” unless otherwise clearly described in the context. Accordingly, for example, the phrase such as “first element mounted on second element” may mean that the first element is directly located on the second element in one embodiment and that the first element is located above the second element without contacting the second element in another embodiment. Thus, the term “on” does not exclude a structure in which another component is formed between the first element and the second element.

The Z-axis direction as referred to in this specification does not necessarily have to be the vertical direction and does not necessarily have to fully coincide with the vertical direction. Accordingly, in the structures of the present disclosure, “up” and “down” in the Z-direction as referred to in this specification are not limited to “up” and “down” in the vertical direction. For example, the X-direction may be the vertical direction. Alternatively, the Y-direction may be the vertical direction.

### Clauses

Technical concepts that can be understood from the above embodiments and modified examples will now be described. The reference characters of elements of the embodiments are shown in parenthesis for the corresponding elements of the clauses described below. The reference characters are used as examples to aid understanding, and are not intended to limit elements to the elements denoted by the reference characters.

### Clause A1

A semiconductor light emitting device (10), including:
a substrate (20) including a substrate front surface (21) and a substrate back surface (22);
an edge-emitting element (70) disposed on the substrate (20), the edge-emitting element (70) including emitters (80A, 80B) arranged next to each other in a first direction (X-direction) intersecting a thickness-wise direction (Z-direction) of the substrate (20) in plan view;
front-surface electrodes (30) formed on the substrate front surface (21) and spaced apart from each other; and
wires (100) electrically connecting the emitters (80A, 80B) to the front-surface electrodes (30), in which
the emitters (80A) include:
   a first emitter (81A, 82A) including a first element electrode (81P/82P); and
   a second emitter (83A) including a second element electrode (83P),
the front-surface electrodes (30) include:
   a first front-surface electrode (31P/32P) electrically connected to the first element electrode (81P/82P); and
   a second front-surface electrode (33P) electrically connected to the second element electrode (83P),
the wires (100) include:
   first wires (110P/120P) electrically connecting the first element electrode (81P/82P) to the first front-surface electrode (31P/32P); and
   second wires (130P) electrically connecting the second element electrode (83P) to the second front-surface electrode (33P), and
in plan view, a largest distance (G3) between adjacent ones of the second wires (130P) in the first direction (X-direction) is greater than a largest distance (G1/G2) between adjacent ones of the first wires (110P/120P) in the first direction (X-direction).

### Clause A2

The semiconductor light emitting device according to clause A1, in which the first wires (110P/120P) are less in number than the second wires (130P).

### Clause A3

The semiconductor light emitting device according to clause A1 or A2, in which
the second front-surface electrode (33P) is located closer to an end of the substrate front surface (21) than the first front-surface electrode (31P/32P) is in the first direction (X-direction), and
a distance from the second front-surface electrode (33P) to the second emitter (83A) is greater than a distance from the first front-surface electrode (31P/32P) to the first emitter (81A, 82A).

### Clause A4

The semiconductor light emitting device according to any one of clauses A1 to A3, in which
the second front-surface electrode (33P) includes:
   an end side (33F, 33G) extending in a second direction (Y-direction) orthogonal to the first direction (X-direction) in plan view;
   an inclined side (33D, 33E) inclined toward the second emitter (83A) as the inclined side (33D, 33E) extends from the end side (33F, 33G) toward a center of the substrate front surface (21) in the first direction (X-direction); and
   a second inclined portion (33C) including the inclined side (33D, 33E) and extending from the end side (33F, 33G) toward the center of the substrate front surface (21), and
the second wires (130P) are bonded to the second inclined portion (33C).

### Clause A5

The semiconductor light emitting device according to clause A4, in which
the first wires (110P/120P) are bonded to a part of the first front-surface electrode (31P/32P) located farther from the first emitter (81A, 82A) than a center of the first front-surface electrode (31P/32P) in the second direction (Y-direction) is, and
the second wires (130P) are bonded to a part of the second front-surface electrode (33P) located closer to the second emitter (83A) than a center of the second front-surface electrode (33P) in the second direction (Y-direction) is.

### Clause A6

The semiconductor light emitting device according to clause A5, in which the second wires (130P) are bonded to a part of the second inclined portion (33C) located toward the second emitter (83A).

### Clause A7

The semiconductor light emitting device according to clause A5 or A6, in which
the second front-surface electrode (33P) includes a second wide portion (33A) having a greater width than the second inclined portion (33C) in the first direction (X-direction), the second wide portion (33A) being an end of the second front-surface electrode (33P) located closer to the second emitter (83A) than the second inclined portion (33C) is, and one or more of the second wires (130P) are bonded to the second wide portion (33A).

### Clause A8

The semiconductor light emitting device according to any one of clauses A5 to A7, in which
the second front-surface electrode (33P) is located closer to an end of the substrate front surface (21) than the first front-surface electrode (31P/32P) is in the first direction (X-direction), and
the first front-surface electrode (32P) includes:
   a first narrow portion (32A) located toward the first emitter (82A); and
   a first inclined portion (32C) adjacent to the second inclined portion (33C) in the first direction (X-direction), the first inclined portion (32C) being inclined toward the first emitter (82A) as the first inclined portion (32C) becomes closer to the center of the substrate front surface (21) in the first direction (X-direction), and
at least one of the first wires (120P) is bonded to the first inclined portion (32C).

### Clause A9

The semiconductor light emitting device according to any one of clauses A5 to A8, in which, as viewed in the second direction (Y-direction), one or more of the second wires (130P) partially overlap the first wires (120P).

### Clause A10

The semiconductor light emitting device according to any one of clauses A1 to A9, in which the first wires (110P/120P) and the second wires (130P) are equal in number.

### Clause A11

The semiconductor light emitting device according to any one of clauses A1 to A10, in which
the emitters (80A) include an end emitter (84A) located at an end of the edge-emitting element (70) in the first direction (X-direction), the end emitter (84A) including an end element electrode (84P),
the front-surface electrodes (30) include an end front-surface electrode (34P) arranged on an end of the substrate front surface (21) in the first direction (X-direction), and
the wires (100) include an end wire (140P) electrically connecting the end element electrode (84P) to the end front-surface electrode (34P).

### Clause A12

The semiconductor light emitting device according to clause A11, in which
the end front-surface electrode (34P) includes an end wide portion (34B) and an end narrow portion (34A), and
the end wire (140P) is bonded to the end narrow portion (34A).

### Clause A13

The semiconductor light emitting device according to clause A12, in which
the end wire (140P) is one of end wires (140P),
the end narrow portion (34A) extends in a second direction (Y-direction) orthogonal to the first direction (X-direction) in plan view, and
bonding points (142) of the end wires (140P) on the end narrow portion (34A) are spaced apart from each other in the second direction (Y-direction) in a state aligned in a same position in the first direction (X-direction).

### Clause A14

The semiconductor light emitting device according to any one of clauses A11 to A13, in which
the end wires (140P) and the second wires (130P) are equal in number, and
a total length of the end wires (140P) is less than a total length of the second wires (130P).

### Clause A15

The semiconductor light emitting device according to any one of clauses A11 to A14, in which
the end front-surface electrode (34P) is located closer to the end of the substrate front surface (21) than the edge-emitting element (70) is in the first direction (X-direction), the end front-surface electrode (34P) opposing the end element electrode (84P) in the first direction (X-direction) in plan view, and
the second front-surface electrode (33P) includes a part located closer to a center of the substrate front surface (21) than the end front-surface electrode (34P) is in the first direction (X-direction).

### Clause A16

The semiconductor light emitting device according to any one of clauses A1 to A15, the first wires (120P) include first wires having different lengths.

### Clause A17

The semiconductor light emitting device according to any one of clauses A1 to A16, in which lengths of the second wires (130P) include second wires having different lengths.

### Clause A18

The semiconductor light emitting device according to any one of clauses A1 to A17, in which
a direction orthogonal to the first direction (X-direction) in plan view is a second direction (Y-direction), and
in plan view, the wires (100) are symmetric with respect to an imaginary line (CL) parallel to the second direction (Y-direction), the second direction (Y-direction) extending through a center of the substrate front surface (21) with respect to the first direction (X-direction).

### Clause A19

The semiconductor light emitting device according to any one of clauses A1 to A18, in which
a direction orthogonal to the first direction (X-direction) in plan view is a second direction (Y-direction), and
in plan view, the front-surface electrodes (30) are symmetric with respect to an imaginary line (CL) parallel to the second direction (Y-direction), the imaginary line (CL) extending through a center of the substrate front surface (21) with respect to the first direction (X-direction).

### Clause A20

The semiconductor light emitting device according to any one of clauses A1 to A19, in which
a direction orthogonal to the first direction (X-direction) in plan view is a second direction (Y-direction), and
the semiconductor light emitting device further includes a case (200) connected to the substrate front surface (21) and covering the edge-emitting element (70), the front-surface electrodes (30), and the wires (100), the case (200) being transparent at least at a part corresponding to an emission direction of the edge-emitting element (70) in the second direction (Y-direction).

### Clause A21

The semiconductor light emitting device according to any one of clauses A1 to A20, further including:
through-interconnects (50) extending through the substrate (20) in a thickness-wise direction (Z-direction) and connected to the front-surface electrodes (30),
in which a distance from the second emitter (83P) to one of the through-interconnects (53P) connected to the second front-surface electrode (33P) is greater than a distance from the first emitter (81A, 82A) to one of the through-interconnects (51P/52P) connected to the first front-surface electrode (31P/32P).

### Clause A22

The semiconductor light emitting device according to clause A21, in which the through-interconnects (50) are each elliptic in plan view.

### Clause A23

The semiconductor light emitting device according to clause A22, in which
a direction orthogonal to the first direction (X-direction) in plan view is a second direction (Y-direction), and
in plan view, the through-interconnects (50) are each inclined with respect to both the first direction (X-direction) and the second direction (Y-direction).

### Clause A24

The semiconductor light emitting device according to any one of clauses A1 to A23, in which a wire height of the first wires (110P/120P) differs from a wire height of the second wires (130P).

### Clause A25

The semiconductor light emitting device according to any one of clauses A1 to A23, in which a wire height of the first wires (110P/120P) is equal to a wire height of the second wires (130P).

### Clause A26

The semiconductor light emitting device according to any one of clauses A1 to A23, in which the first wires (110P/120P) include first wires having different wire heights.

### Clause A27

The semiconductor light emitting device according to any one of clauses A1 to A23, in which the second wires (130P) include second wires having different wire heights.

### Clause A28

The semiconductor light emitting device according to any one of clauses A11 to A15, in which the end wires (140P) are less in number than the second wires (130P).

### Clause A29

The semiconductor light emitting device according to any one of clauses A11 to A15, in which the end wires (140P) and the second wires (130P) are equal in number.

### Clause A30

The semiconductor light emitting device according to any one of clauses A11 to A15, in which the end wires (140P) and the first wires (110P/120P) are equal in number.

### Clause A31

The semiconductor light emitting device according to any one of clauses A11 to A15, in which the end wires (140P) extend in the first direction (X-direction) in plan view.

### Clause A32

The semiconductor light emitting device according to clause A19, in which
an adhering pattern (36) is formed on the substrate front surface (21) to surround the edge-emitting element (70), the front-surface electrodes (30), and the wires (100) in plan view, and
the case (200) is adhered to the adhering pattern (36) by an adhesive.

### Clause A33

The semiconductor light emitting device according to clause A32, in which the case (200) is formed from a glass material.

### Clause A34

A semiconductor light emitting device (10), including:
a substrate (20) including a substrate front surface (21) and a substrate back surface (22);
an edge-emitting element (70) disposed on the substrate (20), the edge-emitting element (70) including emitters (80A) arranged next to each other in a first direction (X-direction) intersecting a thickness-wise direction (Z-direction) of the substrate (20) in plan view;
front-surface electrodes (30) formed on the substrate front surface (21) and spaced apart from each other; and
wires (100) electrically connecting the emitters (80A) to the front-surface electrodes (30), in which
the emitters (80A) include a near emitter (81A, 82A) and a far emitter (83A),
the front-surface electrodes (30) include:
   a near front-surface electrode (310P/320P) electrically connected to the near emitter (81A, 82A); and
   a far front-surface electrode (330P) electrically connected to the far emitter (83A),
in plan view, a distance from the near emitter (81A, 82A) to the near front-surface electrode (310P/320P) is less than a distance from the far emitter (83A) to the far front-surface electrode (330P),
the wires (100) include:
   near wires (110P/120P) connecting the near emitter (81A, 82A) to the near front-surface electrode (310P/320P); and
   far wires (130P) connecting the far emitter (83A) to the far front-surface electrode (330P), and
in plan view, a largest distance (G3) between adjacent ones of the far wires (130P) in the first direction (X-direction) is greater than a largest distance (G1/G2) between adjacent ones of the near wires (110P/120P) in the first direction (X-direction).

### Clause B1

A semiconductor light emitting device (10), including:
a substrate (20) including a substrate front surface (21) and a substrate back surface (22);
an edge-emitting element (70) disposed on the substrate (20), the edge-emitting element (70) including emitters (80A, 80B) arranged next to each other in a first direction (X-direction) intersecting a thickness-wise direction (Z-direction) of the substrate (20) in plan view;
front-surface electrodes (30) formed on the substrate front surface (21) and spaced apart from each other; and
wires (100) electrically connecting the emitters (80A, 80B) to the front-surface electrodes (30), in which
the emitters (80A) include:
   a first emitter (81A, 82A) including a first element electrode (81P/82P); and
   a second emitter (83A) including a second element electrode (83P),
the front-surface electrodes (30) include:
   a first front-surface electrode (31P/32P) electrically connected to the first element electrode (81P/82P); and
   a second front-surface electrode (33P) electrically connected to the second element electrode (83P),
the wires (100) include:
   first wires (110P/120P) electrically connecting the first element electrode (81P/82P) to the first front-surface electrode (31P/32P); and
   second wires (130P) electrically connecting the second element electrode (83P) to the second front-surface electrode (33P), and
the first wires (110P/120P) are less in number than the second wires (130P).

### Clause B2

The semiconductor light emitting device according to clause B1, in which
the edge-emitting element (70) is arranged at a center of the substrate front surface (21) in the first direction (X-direction),
the first element electrode (81P/82P) is arranged on the edge-emitting element (70) at a position located toward a center of the edge-emitting element (70) in the first direction (X-direction),
the second element electrode (83P) is arranged on the edge-emitting element (70) at a position located toward an end of the edge-emitting element (70) in the first direction (X-direction),
the first front-surface electrode (31P/32P) is arranged on the substrate front surface (21) at a position located toward the center of the substrate front surface (21) in the first direction (X-direction), and
the second front-surface electrode (33P) is arranged on the substrate front surface (21) at a position located toward an end of the substrate front surface (21) in the first direction (X-direction).

### Clause B3

The semiconductor light emitting device according to clause B2, in which a distance from the second front-surface electrode (33P) to the second emitter (83A) is greater than a distance from the first front-surface electrode (31P/32P) to the first emitter (81A, 82A).

### Clause B4

The semiconductor light emitting device according to clause B2 or B3, in which
the second front-surface electrode (33P) includes:
   an end side (33F, 33G) extending in a second direction (Y-direction) orthogonal to the first direction (X-direction) in plan view;
   an inclined side (33D, 33E) inclined toward the second emitter (83A) as the inclined side (33D, 33E) extends from the end side (33F, 33G) toward the center of the substrate front surface (21) in the first direction (X-direction); and
   a second inclined portion (33C) including the inclined side (33D, 33E) and extending from the end side (33F, 33G) toward the center of the substrate front surface (21), and
the second wires (130P) are bonded to the second inclined portion (33C).

### Clause B5

The semiconductor light emitting device according to clause B4, in which
the first wires (110P/120P) are bonded to a part of the first front-surface electrode (31P/32P) located farther from the first emitter (81A, 82A) than a center of the first front-surface electrode (31P/32P) in the second direction (Y-direction) is, and
the second wires (130P) are bonded to a part of the second front-surface electrode (33P) located closer to the second emitter (83A) than a center of the second front-surface electrode (33P) in the second direction (Y-direction) is.

### Clause B6

The semiconductor light emitting device according to clause B5, in which
the second front-surface electrode (33P) includes a second wide portion (33A) having a greater width than the second inclined portion (33C) in the first direction (X-direction), the second wide portion (33A) being an end of the second front-surface electrode (33P) located closer to the second emitter (83A) than the second inclined portion (33C) is, and
one or more of the second wires (130P) are bonded to the second wide portion (33A).

### Clause B7

The semiconductor light emitting device according to clause B5, in which
the first front-surface electrode (32P) includes:
   a first narrow portion (32A) located toward the first emitter (82A); and
   a first inclined portion (32C) adjacent to the second inclined portion (33C) in the first direction (X-direction), the first inclined portion (32C) being inclined toward the first emitter (82A) as the first inclined portion (32C) becomes closer to the center of the substrate front surface (21) in the first direction (X-direction), and
at least one of the first wires (120P) is bonded to the first inclined portion (32C).

### Clause B8

The semiconductor light emitting device according to clause B5, in which, as viewed in the second direction (Y-direction), one or more of the second wires (130P) partially overlap the first wires (120P).

### Clause B9

The semiconductor light emitting device according to any one of clauses B1 to B8, in which
the emitters (80A) include an end emitter (84A) located at an end of the edge-emitting element (70) in the first direction (X-direction), the end emitter (84A) including an end element electrode (84P),
the front-surface electrodes (30) include an end front-surface electrode (34P) arranged on an end of the substrate front surface (21) in the first direction (X-direction), and
the wires (100) include an end wire (140P) electrically connecting the end element electrode (84P) to the end front-surface electrode (34P).

### Clause B10

The semiconductor light emitting device according to clause B9, in which the end wire (140P) is one of one or more end wires, and the one or more end wires are less in number than the second wires (130P).

### Clause B11

The semiconductor light emitting device according to clause B9 or B10, in which
the end front-surface electrode (34P) includes an end wide portion (34B) and an end narrow portion (34A), and
the end wire (140P) is bonded to the end narrow portion (34A).

### Clause B12

The semiconductor light emitting device according to clause B11, in which
the end wire (140P) is one of end wires (140P),
the end narrow portion (34A) extends in a second direction (Y-direction) orthogonal to the first direction (X-direction) in plan view, and
bonding points (142) of the end wires (140P) on the end narrow portion (34A) are spaced apart from each other in the second direction (Y-direction) in a state aligned in a same position in the first direction (X-direction).

### Clause B13

The semiconductor light emitting device according to any one of clauses B9 to B12, in which an average length of the end wires (140P) is less than an average length of the second wires (130P).

### Clause B14

The semiconductor light emitting device according to any one of clauses B9 to B13, in which
the end front-surface electrode (34P) is located closer to the end of the substrate front surface (21) than the edge-emitting element (70) is in the first direction (X-direction), the end front-surface electrode (34P) opposing the end element electrode (84P) in the first direction (X-direction) in plan view, and
the second front-surface electrode (33P) includes a part located closer to a center of the substrate front surface (21) than the end front-surface electrode (84P) is in the first direction (X-direction).

### Clause B15

The semiconductor light emitting device according to any one of clauses B1 to B14, in which the first wires (110P/120P) include first wires having different lengths.

### Clause B16

The semiconductor light emitting device according to any one of clauses B1 to B15, in which the second wires (130P) include second wires having different lengths.

### Clause B17

The semiconductor light emitting device according to any one of clauses B1 to B16, in which
a direction orthogonal to the first direction (X-direction) in plan view is a second direction (Y-direction), and
in plan view, the wires (100) are symmetric with respect to an imaginary line (CL) parallel to the second direction (Y-direction), the second direction (Y-direction) extending through a center of the substrate front surface (21) with respect to the first direction (X-direction).

### Clause B18

The semiconductor light emitting device according to any one of clauses B1 to B17, in which
a direction orthogonal to the first direction (X-direction) in plan view is a second direction (Y-direction), and
in plan view, the front-surface electrodes (30) are symmetric with respect to an imaginary line (CL) parallel to the second direction (Y-direction), the imaginary line (CL) extending through a center of the substrate front surface (21) with respect to the first direction (X-direction).

### Clause B19

The semiconductor light emitting device according to any one of clauses B1 to B18, in which
a direction orthogonal to the first direction (X-direction) in plan view is a second direction (Y-direction), and
the semiconductor light emitting device further includes a case (200) connected to the substrate front surface (21) and covering the edge-emitting element (70), the front-surface electrodes (30), and the wires (100), the case (200) being transparent at least at a part corresponding to an emission direction of the edge-emitting element (70) in the second direction (Y-direction).

### Clause B20

The semiconductor light emitting device according to any one of clauses B1 to B19, further including:
through-interconnects (50) extending through the substrate (20) in a thickness-wise direction (Z-direction) and separately connected to the front-surface electrodes (30),
in which a distance from the second emitter (83A) to one of the through-interconnects (53P) connected to the second front-surface electrode (33P) is greater than a distance from the first emitter (81A, 82A) to one of the through-interconnects (51P/52P) connected to the first front-surface electrode (31P/32P).

### Clause B21

The semiconductor light emitting device according to clause B20, in which the through-interconnects (50) are each elliptic in plan view.

### Clause B22

The semiconductor light emitting device according to clause B21, in which
a direction orthogonal to the first direction (X-direction) in plan view is a second direction (Y-direction), and
in plan view, the through-interconnects (50) are each inclined with respect to both the first direction (X-direction) and the second direction (Y-direction).

### Clause B23

The semiconductor light emitting device according to any one of clauses B1 to B22, in which a wire height of the first wires (110P/120P) differs from a wire height of the second wires (130P)

### Clause B24

The semiconductor light emitting device according to any one of clauses B1 to B22, in which a wire height of the first wires (110P/120P) is equal to a wire height of the second wires (130P).

### Clause B25

The semiconductor light emitting device according to any one of clauses B1 to B22, in which the first wires (110P/120P) include first wires having different wire heights.

### Clause B26

The semiconductor light emitting device according to any one of clauses B1 to B22, in which the second wires (130P) include second wires having different wire heights.

### Clause B27

The semiconductor light emitting device according to any one of clauses B9 to B14, in which the end wires (140P) and the second wires (130P) are equal in number.

### Clause B28

The semiconductor light emitting device according to any one of clauses B9 to B14, in which the end wires (140P) and the first wires (110P/120P) are equal in number.

### Clause B29

The semiconductor light emitting device according to any one of clauses B9 to B14, in which the end wires (140P) extend in the first direction (X-direction) in plan view.

### Clause B30

The semiconductor light emitting device according to clause B19, in which
an adhering pattern (36) is formed on the substrate front surface (21) to surround the edge-emitting element (70), the front-surface electrodes (30), and the wires (100) in plan view, and
the case (200) is adhered to the adhering pattern (36) by an adhesive.

### Clause B31

The semiconductor light emitting device according to clause B30, in which the case (200) is formed from a glass material.

### Clause B32

A semiconductor light emitting device (10), including:
a substrate (20) including a substrate front surface (21) and a substrate back surface (22);
an edge-emitting element (70) disposed on the substrate (20), the edge-emitting element (70) including emitters (80A, 80B) arranged next to each other in a first direction (X-direction) intersecting a thickness-wise direction (Z-direction) of the substrate (20) in plan view;
front-surface electrodes (30) formed on the substrate front surface (21) and spaced apart from each other; and
wires (100) electrically connecting the emitters (80A, 80B) to the front-surface electrodes (30), in which
the emitters (80A) include:
   a near emitter (81A, 82A) including a near element electrode (81P/82P); and
   a far emitter (83A) including a far element electrode (83P),
the front-surface electrodes (30) include:
   a near front-surface electrode (31P/32P) electrically connected to the near element electrode (81P/82P); and
   a far front-surface electrode (33P) electrically connected to the far element electrode (83P),
the wires (100) include:
   one or more near wires (110P/120P) electrically connecting the near element electrode (81P/82P) to the near front-surface electrode (31P/32P); and
   far wires (130P) electrically connecting the far element electrode (83P) and the far front-surface electrode (33P), and
the one or more near wires (110P/120P) are less in number than the far wires (130P).

### Clause B33

The semiconductor light emitting device according to clause B32, in which
the emitters (80A) include an end emitter (84A) located at an end of the edge-emitting element (70) in the first direction (X-direction), the end emitter (84A) including an end element electrode (84P),
the front-surface electrodes (30) include an end front-surface electrode (34P) arranged on an end of the substrate front surface (21) in the first direction (X-direction),
the wires (100) include one or more end wires (140P) electrically connecting the end element electrode (84P) to the end front-surface electrode (34P), and
the one or more end wires (140P) are less in number than the far wires (130P).

The above descriptions are merely exemplary. One skilled in the art may recognize further potential combinations and replacements of the elements and methods (manufacturing processes) in addition to those illustrated to describe the techniques of the present disclosure. All replacements, modifications, and variations within the scope of the claims are intended to be encompassed in the present disclosure.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor light emitting device, comprising:
a substrate including a substrate front surface and a substrate back surface;
an edge-emitting element disposed on the substrate, the edge-emitting element including emitters arranged next to each other in a first direction intersecting a thickness-wise direction of the substrate in plan view;
front-surface electrodes formed on the substrate front surface and spaced apart from each other; and
wires electrically connecting the emitters to the front-surface electrodes, wherein
the emitters include:
a first emitter including a first element electrode; and
a second emitter including a second element electrode,
the front-surface electrodes include:
a first front-surface electrode electrically connected to the first element electrode; and
a second front-surface electrode electrically connected to the second element electrode,
the wires include:
first wires electrically connecting the first element electrode to the first front-surface electrode; and
second wires electrically connecting the second element electrode to the second front-surface electrode, and
in plan view, a largest distance between adjacent ones of the second wires in the first direction is greater than a largest distance between adjacent ones of the first wires in the first direction.

2. The semiconductor light emitting device according to claim 1, wherein the first wires are less in number than the second wires.

3. The semiconductor light emitting device according to claim 1, wherein
the second front-surface electrode is located closer to an end of the substrate front surface than the first front-surface electrode is in the first direction, and
a distance from the second front-surface electrode to the second emitter is greater than a distance from the first front-surface electrode to the first emitter.

4. The semiconductor light emitting device according to claim 1, wherein
the second front-surface electrode includes:
an end side extending in a second direction orthogonal to the first direction in plan view;
an inclined side inclined toward the second emitter as the inclined side extends from the end side toward a center of the substrate front surface in the first direction; and
a second inclined portion including the inclined side and extending from the end side toward the center of the substrate front surface, and
the second wires are bonded to the second inclined portion.

5. The semiconductor light emitting device according to claim 4, wherein
the first wires are bonded to a part of the first front-surface electrode located farther from the first emitter than a center of the first front-surface electrode in the second direction is, and
the second wires are bonded to a part of the second front-surface electrode located closer to the second emitter than a center of the second front-surface electrode in the second direction is.

6. The semiconductor light emitting device according to claim 5, wherein the second wires are bonded to a part of the second inclined portion located toward the second emitter.

7. The semiconductor light emitting device according to claim 5, wherein
the second front-surface electrode includes a second wide portion having a greater width than the second inclined portion in the first direction, the second wide portion being an end of the second front-surface electrode located closer to the second emitter than the second inclined portion is, and
one or more of the second wires are bonded to the second wide portion.

8. The semiconductor light emitting device according to claim 5, wherein
the second front-surface electrode is located closer to an end of the substrate front surface than the first front-surface electrode is in the first direction, and
the first front-surface electrode includes:
a first narrow portion located toward the first emitter; and
a first inclined portion adjacent to the second inclined portion in the first direction, the first inclined portion being inclined toward the first emitter as the first inclined portion becomes closer to the center of the substrate front surface in the first direction, and
at least one of the first wires is bonded to the first inclined portion.

9. The semiconductor light emitting device according to claim 5, wherein, as viewed in the second direction, one or more of the second wires partially overlap the first wires.

10. The semiconductor light emitting device according to claim 1, wherein the first wires and the second wires are equal in number.

11. The semiconductor light emitting device according to claim 1, wherein
the emitters include an end emitter located at an end of the edge-emitting element in the first direction, the end emitter including an end element electrode,
the front-surface electrodes include an end front-surface electrode arranged on an end of the substrate front surface in the first direction, and
the wires include an end wire electrically connecting the end element electrode to the end front-surface electrode.

12. The semiconductor light emitting device according to claim 11, wherein
the end front-surface electrode includes an end wide portion and an end narrow portion, and
the end wire is bonded to the end narrow portion.

13. The semiconductor light emitting device according to claim 12, wherein
the end wire is one of end wires,
the end narrow portion extends in a second direction orthogonal to the first direction in plan view, and
bonding points of the end wires on the end narrow portion are spaced apart from each other in the second direction in a state aligned in a same position in the first direction.

14. The semiconductor light emitting device according to claim 11, wherein
the end wires and the second wires are equal in number, and
a total length of the end wires is less than a total length of the second wires.

15. The semiconductor light emitting device according to claim 11, wherein
the end front-surface electrode is located closer to the end of the substrate front surface than the edge-emitting element is in the first direction, the end front-surface electrode opposing the end element electrode in the first direction in plan view, and
the second front-surface electrode includes a part located closer to a center of the substrate front surface than the end front-surface electrode is in the first direction.

16. The semiconductor light emitting device according to claim 1, wherein the first wires include first wires having different lengths.

17. The semiconductor light emitting device according to claim 1, wherein the second wires include second wires having different lengths.

18. The semiconductor light emitting device according to claim 1, wherein
a direction orthogonal to the first direction in plan view is a second direction, and
in plan view, the wires are symmetric with respect to an imaginary line parallel to the second direction, the imaginary line extending through a center of the substrate front surface with respect to the first direction.

19. The semiconductor light emitting device according to claim 1, wherein
a direction orthogonal to the first direction in plan view is a second direction, and
in plan view, the front-surface electrodes are symmetric with respect to an imaginary line parallel to the second direction, the imaginary line extending through a center of the substrate front surface with respect to the first direction.

20. The semiconductor light emitting device according to claim 1, wherein
a direction orthogonal to the first direction in plan view is a second direction, and
the semiconductor light emitting device further includes a case connected to the substrate front surface and covering the edge-emitting element, the front-surface electrodes, and the wires, the case being transparent at least at a part corresponding to an emission direction of the edge-emitting element in the second direction.
